(19) United States
(12) Patent Application Publication
(10) Pub. No.: US 2026/0299647 A1
(43) Pub. Date: Oct. 1, 2026

(54) DISPLAY MODULE AND ELECTRONIC DEVICE

(71) Applicant: SEMICONDUCTOR ENERGY LABORATORY CO., LTD., Atsugi-shi, Kanagawa-ken (JP)

(72) Inventors: Akio ENDO, Atsugi, Kanagawa (JP); Hisao IKEDA, Zama, Kanagawa (JP); Ryo HATSUMI, Hadano, Kanagawa (JP)

(21) Appl. No.: 19/477,622

(22) PCT Filed: Apr. 24, 2024
(86) PCT No.: PCT/IB2024/053973

§ 371 Date: Oct. 22, 2025

(30) Foreign Application Priority Data
May 2, 2023 (JP) 2023-075962

(51) Int. Cl. G06F 1/16

(52) U.S. Cl. CPC G06F 1/1656; G06F 1/1652

(57) ABSTRACT

A novel display module that is highly convenient, useful, or reliable is provided. The display module includes a first support, a second support, a first adhesive layer, a gap, a fluid layer, and a display apparatus. The first support overlaps with the second support. The first support has flexibility. The second support has higher elasticity than the first support. The first adhesive layer bonds the first support and the second support to each other. The first adhesive layer fomes the gap between the first support and the second support. The gap holds the fluid layer. The fluid layer has fluidity within the range of 0° C. to 80° C., and the difference in refractive index between the fluid layer and the first support is greater than 0 and less than or equal to 0.2. The display apparatus is sandwiched between the first support and the second support, has a function of performing display toward the first support, and includes a first display region, a second display region, and a third display region. The first display region is fixed between the first support and the first adhesive layer. The second display region is sandwiched between the first display region and the third display region, can be bent, and is positioned inside the gap. The third display region is positioned inside the gap and slides inside the gap in accordance with bending of the second display region.

### TECHNICAL FIELD

One embodiment of the present invention relates to a display module, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, more specific examples of the technical field of one embodiment of the present invention disclosed in this specification include a semiconductor device, a display apparatus, a light-emitting apparatus, a power storage device, a memory device, a driving method thereof, and a manufacturing method thereof.

### BACKGROUND ART

Electronic devices such as cellular phones, smartphones, tablet type computers, and laptop computers are manufactured with appropriate sizes depending on their functions, usability, design, portability, and the like. Meanwhile, it is inconvenient to carry a plurality of electronic devices with overlapping functions. Accordingly, a form in which functions of a plurality of electronic devices are integrated is desired. For example, Patent Document 1 discloses a tri-fold light-emitting panel. The use of the light-emitting panel enables integration of functions of a plurality of electronic devices and manufacture of an electronic device whose size is variable.

### REFERENCE

### Patent Document

[Patent Document 1] Japanese Published Patent Application No. 2015-130320

### SUMMARY OF THE INVENTION

### Problems to be Solved by the Invention

As described above, various inventions have been disclosed in the prior art documents but still have many issues with their convenience, usefulness, or reliability, and are not yet satisfactory. In view of the above, an object of one embodiment of the present invention is to provide a novel display module that is highly convenient, useful, or reliable. Another object is to provide a novel electronic device that is highly convenient, useful, or reliable. Another object is to provide a novel display module, a novel electronic device, or a novel semiconductor device.

Note that the description of these objects does not preclude the existence of other objects. One embodiment of the present invention does not necessarily achieve all these objects. Other objects will be apparent from the description of the specification, the drawings, the claims, and the like, and other objects can be derived from the description of the specification, the drawings, the claims, and the like.

### Means for Solving the Problems

(1) One embodiment of the present invention is a display module including a first support, a second support, a first adhesive layer, a gap, a fluid layer, and a display apparatus.

The first support overlaps with the second support, the first support has flexibility, and the second support has higher elasticity than the first support.

The first adhesive layer bonds the first support and the second support to each other, the first adhesive layer forms the gap between the first support and the second support, and the gap holds the fluid layer.

The fluid layer has fluidity within the range of 0° C. to 80° C., and the difference in refractive index between the fluid layer and the first support is greater than 0 and less than or equal to 0.2.

The display apparatus is sandwiched between the first support and the second support, the display apparatus has a function of performing display toward the first support, and the display apparatus includes a first display region, a second display region, and a third display region.

The first display region is fixed between the first support and the first adhesive layer, and the second display region is sandwiched between the first display region and the third display region.

The second display region can be bent, and the second display region is positioned inside the gap.

The third display region is positioned inside the gap, and the third display region slides inside the gap in accordance with bending of the second display region.

Thus, the display apparatus can slide inside the gap. The second display region and the third display region can slide inside the gap in accordance with bending making the first support face inward. In addition, stress concentration due to bending is unlikely to occur in the display apparatus. Since the second display region and the third display region are seen through the fluid layer with the difference in refractive index between the fluid layer and the first support suppressed, deterioration of display quality due to the gap is unlikely to occur. As a result, a novel display module that is highly convenient, useful, or reliable can be provided.

(2) Another embodiment of the present invention is the above display module including a second adhesive layer.

The second adhesive layer bonds the first support and the first display region to each other, and the difference in refractive index between the second adhesive layer and the first support is greater than 0 and less than or equal to 0.2.

Thus, while the first display region is fixed, for example, the second display region and the third display region can slide inside the gap. In addition, stress concentration due to bending is unlikely to occur in the display apparatus. Since the first display region is seen through the second adhesive layer with the difference in refractive index between the second adhesive layer and the first support suppressed, deterioration of display quality is unlikely to occur. As a result, a novel display module that is highly convenient, useful, or reliable can be provided.

(3) Another embodiment of the present invention is the above display module including a third support and a third adhesive layer.

The second support is sandwiched between the first support and the third support, and the third adhesive layer bonds the second support and the third support to each other.

The third support overlaps with the first display region and the second display region, the third support has flexibility, and the third support has lower elasticity than the second support.

Thus, the third support pulls the second support outward in accordance with bending making the first support face inward. The second support pulled by the third support is stretched, so that the gap between the second support and the first support is widened. When the gap is widened, the second display region and the third display region can easily slide inside the gap. In addition, stress concentration due to bending is unlikely to occur in the display apparatus. When the gap is widened, the fluid layer can easily flow. As a result, a novel display module that is highly convenient, useful, or reliable can be provided.

(4) Another embodiment of the present invention is the above display module including a fourth support, a fifth support, a fourth adhesive layer, and a fifth adhesive layer.

The third support is sandwiched between the second support and the fourth support, and the fourth adhesive layer bonds the third support and the fourth support to each other.

The fourth support overlaps with the first display region, and the fourth support has lower flexibility than the first support.

The second support is sandwiched between the first support and the fifth support, and the fifth adhesive layer bonds the second support and the fifth support to each other.

The fifth support overlaps with the third display region, and the fifth support has lower flexibility than the first support.

Thus, the second display region can be bent with the first support facing inward. The first display region and the third display region can be kept flat even when the second display region is bent with the first support facing inward. As a result, a novel display module that is highly convenient, useful, or reliable can be provided.

(5) Another embodiment of the present invention is the above display module in which the display apparatus includes a terminal adjacent to the first display region.

Thus, electrical connection between the display apparatus and a driving device can be facilitated. The terminal and the first support can be fixed. In addition, the reliability of electrical connection between the display apparatus and the driving device can be increased. As a result, a novel display module that is highly convenient, useful, or reliable can be provided.

(6) Another embodiment of the present invention is the above display module in which the display apparatus has arithmetic surface roughness greater than or equal to 0.5 nm and less than or equal to 20 nm.

(7) Another embodiment of the present invention is the above display module in which the display apparatus includes a layer containing polytetrafluoroethylene on a surface facing the second support.

(8) Another embodiment of the present invention is the above display module in which the fluid layer includes a glass bead.

The glass bead has a diameter greater than or equal to 1.0 μm and less than or equal to 50 μm, and the difference in refractive index between the glass bead and the first support is greater than 0 and less than or equal to 0.2.

Thus, while the first display region is fixed, for example, the second display region and the third display region can easily slide inside the gap. As a result, a novel display module that is highly convenient, useful, or reliable can be provided.

(9) Another embodiment of the present invention is an electronic device including the above display module and a housing. Note that the housing includes a hinge, and the housing is capable of bending the hinge with the second display region on the inner side.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

One embodiment of the present invention can provide a novel display module that is highly convenient, useful, or reliable. Another embodiment of the present invention can provide a novel electronic device that is highly convenient, useful, or reliable. A novel display module can be provided. A novel electronic device can be provided.

Note that the description of these effects does not preclude the existence of other effects. One embodiment of the present invention does not need to have all these effects. Other effects will be apparent from and can be derived from the description of the specification, the drawings, the claims, and the like.

### BRIEF DESCRIPTION OF THE DRAWINGS

FIG. 1A and FIG. 1B are diagrams illustrating a display module of an embodiment.

FIGS. 2A and 2B are diagrams illustrating display modules of an embodiment.

FIG. 3 is a diagram illustrating a display module of an embodiment.

FIG. 4A to FIG. 4C are diagrams illustrating a display module of an embodiment.

FIG. 5A and FIG. 5B are diagrams illustrating a display module of an embodiment.

FIG. 6A to FIG. 6D are diagrams illustrating pixel circuits of an embodiment.

FIG. 7A to FIG. 7D are diagrams illustrating pixel circuits of an embodiment.

FIG. 8A and FIG. 8B are diagrams illustrating pixel circuits of an embodiment.

FIG. 9A and FIG. 9B are diagrams illustrating pixel circuits of an embodiment.

FIG. 10A and FIG. 10B are diagrams illustrating driver circuits of an embodiment.

FIG. 11A to FIG. 11G are diagrams illustrating pixels of an embodiment.

FIG. 12A to FIG. 12K are diagrams each illustrating a pixel of an embodiment.

FIG. 13A to FIG. 13C are diagrams illustrating a shift register of an embodiment.

FIG. 14 is a diagram illustrating a signal output circuit of an embodiment.

FIG. 15 is a diagram illustrating a signal output circuit of an embodiment.

FIG. 16 is a diagram illustrating a signal output circuit of an embodiment.

FIG. 17A to FIG. 17D are diagrams illustrating a transistor of an embodiment.

FIG. 18A to FIG. 18F are diagrams illustrating the transistor of an embodiment.

FIG. 19A and FIG. 19B are diagrams illustrating the transistor of an embodiment.

FIG. 20A and FIG. 20B are diagrams illustrating the transistor of an embodiment.

FIG. 21A to FIG. 21D are diagrams illustrating transistors of an embodiment.

FIG. 22A to FIG. 22D are diagrams illustrating the transistors of an embodiment.

FIG. 23 is a diagram illustrating a signal output circuit of an embodiment.

FIG. 24A and FIG. 24B are diagrams illustrating the signal output circuit of an embodiment.

FIG. 25A and FIG. 25B are diagrams illustrating the signal output circuit of an embodiment.

FIG. 26 is a diagram illustrating the signal output circuit of an embodiment.

FIG. 27 is a diagram illustrating an operation of a signal output circuit of an embodiment.

FIG. 28 is a diagram illustrating the operation of the signal output circuit of an embodiment.

FIG. 29 is a diagram illustrating the operation of the signal output circuit of an embodiment.

FIG. 30 is a diagram illustrating the operation of the signal output circuit of an embodiment.

FIG. 31 is a diagram illustrating the operation of the signal output circuit of an embodiment.

FIG. 32 is a diagram illustrating the operation of the signal output circuit of an embodiment.

FIG. 33 is a diagram illustrating the operation of the signal output circuit of an embodiment.

FIG. 34 is a diagram illustrating the operation of the signal output circuit of an embodiment.

FIG. 35 is a diagram illustrating the signal output circuit of an embodiment.

FIG. 36 is a diagram showing an operation of the shift register of an embodiment.

FIG. 37A and FIG. 37B are diagrams illustrating an electronic device of an embodiment.

FIG. 38A to FIG. 38C are diagrams illustrating an electronic device of an embodiment.

### MODE FOR CARRYING OUT THE INVENTION

The display module of one embodiment of the present invention includes the first support, the second support, the first adhesive layer, the gap, the fluid layer, and the display apparatus; the first support overlaps with the second support; the first support has flexibility; the second support has higher elasticity than the first support; the first adhesive layer bonds the first support and the second support to each other; the first adhesive layer forms the gap between the first support and the second support; and the gap holds the fluid layer. The fluid layer has fluidity within the range of 0° C. to 80° C., and the difference in refractive index between the fluid layer and the first support is greater than 0 and less than or equal to 0.2. The display apparatus is sandwiched between the first support and the second support, the display apparatus has a function of performing display toward the first support, and the display apparatus includes the first display region, the second display region, and the third display region. The first display region is fixed between the first support and the first adhesive layer, the second display region is sandwiched between the first display region and the third display region, the second display region can be bent, and the second display region is positioned inside the gap. The third display region is positioned inside the gap, and the third display region slides inside the gap in accordance with bending of the second display region.

Thus, the display apparatus can slide inside the gap. The second display region and the third display region can slide inside the gap in accordance with bending making the first support face inward. In addition, stress concentration due to bending is unlikely to occur in the display apparatus. Since the second display region and the third display region are seen through the fluid layer with the difference in refractive index between the fluid layer and the first support suppressed, deterioration of display quality due to the gap is unlikely to occur. As a result, a novel display module that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

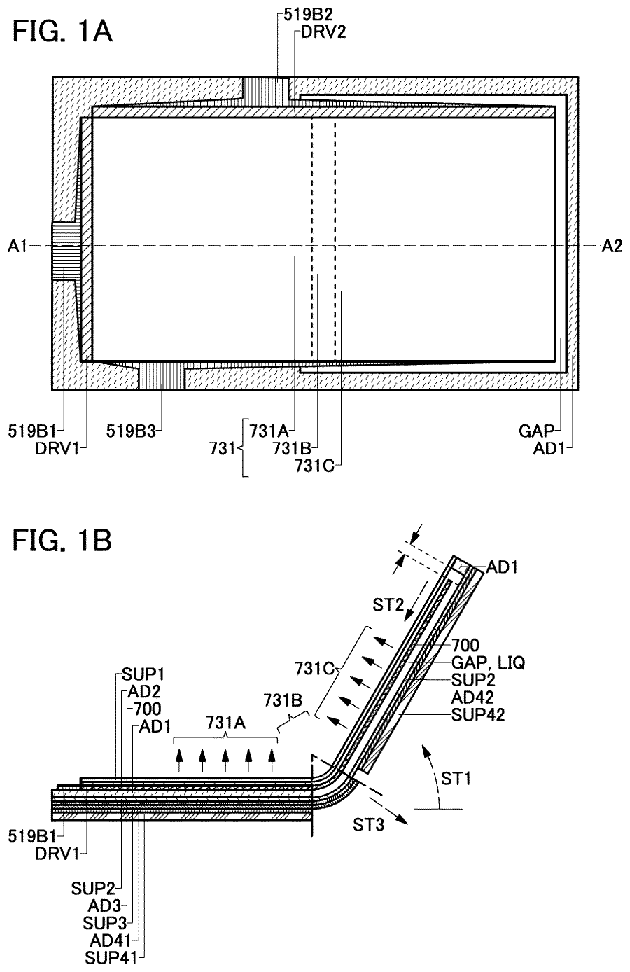

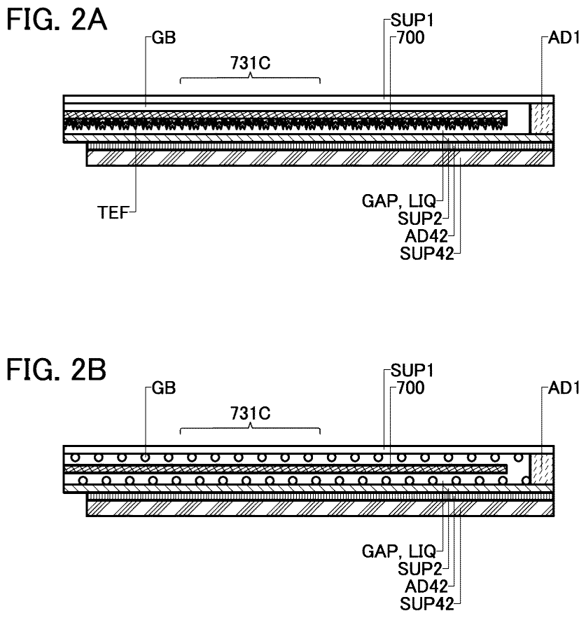

In this embodiment, a structure of a light-emitting device of one embodiment of the present invention will be described with reference to FIG. 1 and FIG. 2.

FIG. 1A is a front view illustrating a structure of a display module of one embodiment of the present invention, and FIG. 1B is a cross-sectional view illustrating a structure of the display module along cutting line A1-A2 illustrated in FIG. 1A.

FIG. 2A is a cross-sectional view illustrating details of part of the display module illustrated in FIG. 1B, and FIG. 2B is a cross-sectional view illustrating a structure different from the structure illustrated in FIG. 2A.

### Structure Example 1of Display Module

One embodiment of the present invention is a display module including a support SUP1, a support SUP2, an adhesive layer AD1, a gap GAP, a fluid layer LIQ (not illustrated), and a display apparatus 700 (see FIG. 1A and FIG. 1B).

### Structure Example of Support SUP1

The support SUP1 overlaps with the support SUP2 and has flexibility.

The support SUP1 contains silicon oxide. For example, glass having a thickness greater than or equal to 0.03 mm and less than or equal to 0.2 mm can be used for the support SUP1. Specifically, glass whose surface is provided with a compressive stress layer can be used for the support SUP1. For example, chemically strengthened glass can be used for the support SUP1. Glass whose surface is subjected to treatment for exchanging sodium ions and potassium ions can be used for the support SUP1.

For example, glass that can be bent repeatedly more than or equal to 10000 times, preferably approximately 200000 times with a radius of curvature greater than or equal to 2 mm and less than or equal to 5 mm can be used for the support SUP1.

### Structure Example 1 of Support SUP2

The support SUP2 has higher elasticity than the support SUP1. In other words, when the same tensile stress is applied to the support SUP1 and the support SUP2, the support SUP2 is more stretchable than the support SUP1, and the length of a line drawn on the support SUP2 is more changeable than the length of a line drawn on the support SUP1.

For example, a resin having a thickness greater than or equal to 0.1 mm and less than or equal to 0.5 mm can be used for the support SUP2.

For example, a silicone resin, an ethylene vinyl acetate (EVA) resin, a thermoplastic polyurethane elastomer (TPU), or the like can be used for the support SUP2. Thus, the support SUP2 can have higher elasticity than the support SUP1.

### Structure Example of Adhesive Layer AD1

The adhesive layer ADI bonds the support SUP1 and the support SUP2 to each other. The adhesive layer AD1 forms the gap GAP between the support SUPI and the support SUP2, and the gap GAP holds the fluid layer LIQ. In other words, the fluid layer LIQ fills the gap GAP.

For example, an organic material such as a reactive curable adhesive, a photocurable adhesive, a thermosetting adhesive, or/and an anaerobic adhesive can be used for the adhesive layer AD1.

Specifically, an adhesive containing an epoxy resin, an acrylic resin, a silicone resin, a phenol resin, polyimide, polyvinyl chloride (PVC), polyvinyl butyral (PVB), an ethylene vinyl acetate (EVA) resin, or the like can be used for the adhesive layer AD1.

### Structure Example 1 of Fluid Layer LIQ

The fluid layer LIQ has fluidity within the range of 0° C. to 80° C. The difference in refractive index between the fluid layer LIQ and the support SUP1 is greater than 0 and less than or equal to 0.2, preferably less than or equal to 0.1.

For example, glycerol, immersion oil, or the like can be used for the fluid layer LIQ.

### Structure Example 1 of Display Apparatus 700

The display apparatus 700 is sandwiched between the support SUPI and the support SUP2, and has a function of performing display toward the support SUP1.

The display apparatus 700 includes a display region 731. The display region 731 includes a display region 731A, a display region 731B, and a display region 731C.

### Display Region 731A

The display region 731A is fixed between the support SUP1 and the adhesive layer AD1.

### Display Region 731B

The display region 731B is sandwiched between the display region 731A and the display region 731C, and the display region 731B is positioned inside the gap GAP. The display region 731B can be bent.

### Display Region 731C

The display region 731C is positioned inside the gap GAP, and the display region 731C slides inside the gap GAP in accordance with bending of the display region 731B. In other words, the display region 731C moves while sliding inside the gap GAP. In addition, the display region 731C moves while sliding in the fluid layer.

Thus, the display apparatus 700 can slide inside the gap GAP (see FIG. 1B). When bending stress ST1 is applied to the display module and the display module is bent with the support SUPI facing inward, for example, tensile stress ST2 due to bending is generated in the display apparatus 700, so that the display region 731B and the display region 731C can slide inside the gap GAP. In the display apparatus 700, stress concentration due to bending is unlikely to occur. In addition, since the display region 731B and the display region 731C are seen through the fluid layer LIQ with the difference in refractive index between the fluid layer LIQ and the support SUP1 suppressed, deterioration of display quality due to the gap GAP is unlikely to occur. As a result, a novel display module that is highly convenient, useful, or reliable can be provided.

### Structure Example 2 of Display Module

The display module of one embodiment of the present invention includes an adhesive layer AD2.

### Adhesive Layer AD2

The adhesive layer AD2 bonds the support SUP1 and the display region 731A to each other, and the difference in refractive index between the adhesive layer AD2 and the support SUP1 is greater than 0 and less than or equal to 0.2, preferably less than or equal to 0.1. The adhesive layer AD2 has a visible-light-transmitting property.

For example, an organic material such as a reactive curable adhesive, a photocurable adhesive, a thermosetting adhesive, or/and an anaerobic adhesive can be used for the adhesive layer AD2.

Specifically, an adhesive containing an epoxy resin, an acrylic resin, a silicone resin, a phenol resin, polyimide polyvinyl chloride (PVC), polyvinyl butyral (PVB), and an ethylene vinyl acetate (EVA) resin, or the like can be used for the adhesive layer AD2.

Thus, while the display region 731A is fixed, for example, the display region 731B and the display region 731C can slide inside the gap GAP. In the display apparatus 700, stress concentration due to bending is unlikely to occur. In addition, since the display region 731A is seen through the adhesive layer AD2 with the difference in refractive index between the support SUP1 and the adhesive layer AD2 suppressed, deterioration of display quality is unlikely to occur. As a result, a novel display module that is highly convenient, useful, or reliable can be provided.

### Structure Example 3 of Display Module

The display module of one embodiment of the present invention includes a support SUP3 and an adhesive layer AD3.

### Structure Example of Support SUP3

The support SUP2 is sandwiched between the support SUP3 and the support SUP1, and the adhesive layer AD3 bonds the support SUP2 and the support SUP3 to each other.

For example, an organic material such as a reactive curable adhesive, a photocurable adhesive, a thermosetting adhesive, or/and an anaerobic adhesive can be used for the adhesive layer AD3.

Specifically, an adhesive containing an epoxy resin, an acrylic resin, a silicone resin, a phenol resin, polyimide, polyvinyl chloride (PVC), polyvinyl butyral (PVB), an ethylene vinyl acetate (EVA) resin, or the like can be used for the adhesive layer AD3.

The support SUP3 overlaps with the display region 731A and the display region 731B, and the support SUP3 has flexibility. The support SUP3 has lower elasticity than the support SUP2. In other words, when the shapes of the support SUP2 and the support SUP3 are changed such that the same displacement amount is generated, higher stress is generated in the support SUP3 than in the support SUP2.

For example, a resin having a thickness greater than or equal to 0.1 mm and less than or equal to 1 mm can be used for the support SUP3.

Specifically, a silicone resin, an EVA (ethylene vinyl acetate) resin, or the like can be used for the support SUP3.

Accordingly, stress ST3 that repels the bending stress is generated in accordance with bending making the support SUPI face inward, and the support SUP3 pulls the support SUP2 outward. In addition, the support SUP2 pulled by the support SUP3 is stretched, so that the gap between the support SUP2 and the support SUPI is widened. When the gap is widened, the display region 731B and the display region 731C can slide easily inside the gap GAP. In the display apparatus 700, stress concentration due to bending is unlikely to occur. When I the gap is widened, the fluid layer LIQ can easily flow. As a result, a novel display module that is highly convenient, useful, or reliable can be provided.

### Structure Example 4 of Display Module

The display module of one embodiment of the present invention includes a support SUP41, a support SUP42, an adhesive layer AD41, and an adhesive layer AD42.

For example, an organic material such as a reactive curable adhesive, a photocurable adhesive, a thermosetting adhesive, or/and an anaerobic adhesive can be used for the adhesive layer AD41 and the adhesive layer AD42.

Specifically, an adhesive containing an epoxy resin, an acrylic resin, a silicone resin, a phenol resin, polyimide, polyvinyl chloride (PVC), polyvinyl butyral (PVB), an ethylene vinyl acetate (EVA) resin, or the like can be used for the adhesive layer AD41 and the adhesive layer AD42.

### Support SUP41

The support SUP3 is sandwiched between the support SUP2 and the support SUP41, and the adhesive layer AD41 bonds the support SUP3 and the support SUP41 to each other.

The support SUP41 overlaps with the display region 731A and has lower flexibility than the support SUP1. In other words, when the same bending stress is applied to the support SUP1 and the support SUP41, the support SUP41 is less bendable than the support SUP1.

### Support SUP42

The support SUP2 is sandwiched between the support SUP1 and the support SUP42, and the adhesive layer AD42 bonds the support SUP2 and the support SUP42 to each other.

The support SUP42 overlaps with the display region 731C and has lower flexibility than the support SUP1. In other words, when the same bending stress is applied to the support SUP1 and the support SUP42, the support SUP42 is less bendable than the support SUP1.

For example, a resin or a metal having a thickness greater than or equal to 0.2 mm and less than or equal to 0.7 mm can be used for the support SUP3.

Thus, the display region 731B can be bent with the support SUP1 facing inward. The display region 731A and the display region 731C can be kept flat even when the display region 731B is bent with the support SUP1 facing inward. As a result, a novel display module that is highly convenient, useful, or reliable can be provided.

### Structure Example 2 of Display Apparatus 700

The display apparatus 700 includes a terminal 519B1. The terminal 519B1 is adjacent to the display region 731A.

The terminal 519B1, a terminal 519B2, or a terminal 519B3 can be electrically connected to a power supply line or a driving device, for example. Specifically, a driver circuit portion DRV1, a driver circuit portion DRV2, and a touch sensor provided in the display apparatus can be electrically connected to the driving device.

Thus, electrical connection between the display apparatus 700 and the driving device can be facilitated. In addition, the terminal 519B1 and the support SUP1 can be fixed. In addition, the reliability of electrical connection between the display apparatus 700 and the driving device can be increased. As a result, a novel display module that is highly convenient, useful, or reliable can be provided.

### Structure Example 3 of Display Apparatus 700

The display apparatus 700 has arithmetic surface roughness greater than or equal to 0.5 nm and less than or equal to 20 nm (see FIG. 2A). This facilitates entry of the fluid layer LIQ between the display region 731C and the support SUP2, for example. In addition, generation of a phenomenon in which the display region 731C adheres to the support SUP2 and does not easily move can be prevented.

### Structure Example 4 of Display Apparatus 700

The display apparatus 700 includes a layer TEF on a surface that faces the support SUP2, and the layer TEF contains polytetrafluoroethylene. Thus, friction generated between the display region 731C and the support SUP2 is low, for example. In addition, generation of a phenomenon in which the display region 731C adheres to the support SUP2 and does not easily move can be prevented.

### Structure Example 2 of Fluid Layer LIQ

The fluid layer LIQ contains a glass bead GB (see FIG. 2B).

The glass bead GB has a diameter greater than or equal to 1.0 μm and less than or equal to 50 μm, and the difference in refractive index between the glass bead GB and the support SUP1 is greater than 0 and less than or equal to 0.2, preferably less than or equal to 0.1. Thus, friction generated between the display region 731C and the support SUP2 is low, for example. In addition, generation of a phenomenon in which the display region 731C adheres to the support SUP2 and does not easily move can be prevented.

Thus, while the display region 731A is fixed, for example, the display region 731B and the display region 731C can easily slide inside the gap GAP. As a result, a novel display module that is highly convenient, useful, or reliable can be provided.

Note that this embodiment can be combined with any of the other embodiments described in this specification as appropriate.

### Embodiment 2

In this embodiment, a display apparatus that can be used for the display module of one embodiment of the present invention will be described.

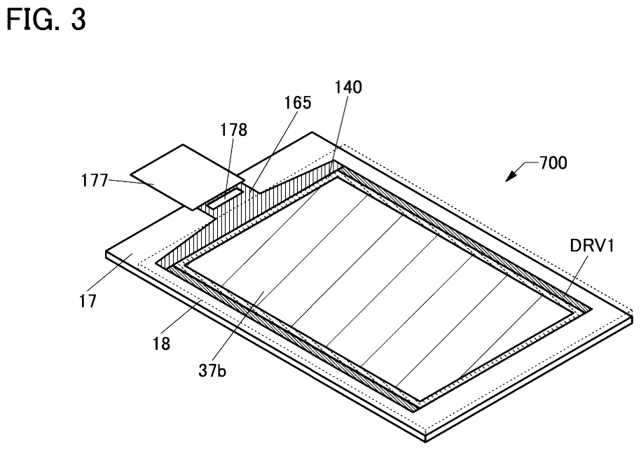

FIG. 3 is a perspective view illustrating a structure of a display module.

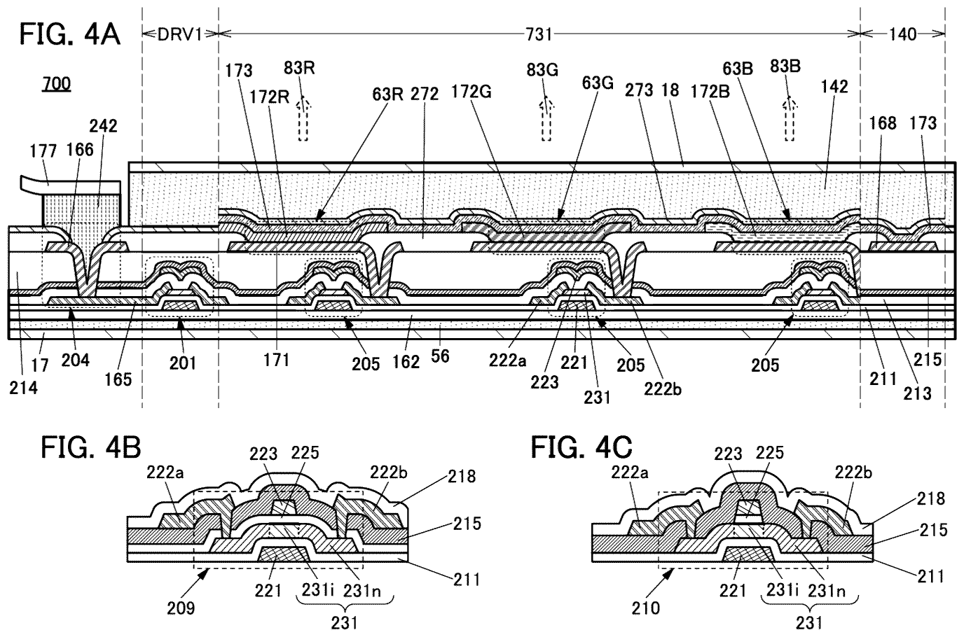

FIG. 4A is a cross-sectional view illustrating the structure of the display module. FIG. 4B and FIG. 4C are each a cross-sectional view illustrating a structure of a transistor that can be used in part of FIG. 4A.

The display module includes the display apparatus 700, an IC (integrated circuit), and an FPC (flexible printed circuit) or a connector (see FIG. 3).

The display apparatus 700 is electrically connected to an IC 178 and an FPC 177. The FPC 177 is supplied with a signal and electric power from the outside and supplies the signal and the electric power to the display apparatus 700. Note that a connector is a mechanical component for electrical connection through a conductor, and the conductor can electrically connect the display apparatus 700 to a component to be connected. For example, the FPC 177 can be used as the conductor. The connector can detach the display apparatus 700 from the connected component.

The display module includes the IC 178. For example, the IC 178 can be provided for a substrate 17 by a COG (Chip On Glass) method. Alternatively, the IC 178 can be provided for an FPC by a COF (Chip On Film) method, for example. Note that a gate driver circuit, a source driver circuit, or the like can be used as the IC 178.

### Display Apparatus 700

The display apparatus 700 includes a display portion 37b, a connection portion 140, the driver circuit portion DRV1, a wiring 165, and the like. The display apparatus 700 includes the substrate 17 and a substrate 18, and the substrate 18 and the substrate 17 are bonded to each other. Note that the substrate 17 and the substrate 18 both have flexibility.

The display apparatus 700 has flexibility. In other words, the display apparatus 700 is a flexible display.

The display apparatus 700 includes one or more connection portions 140. The connection portion(s) 140 can be provided outside the display portion 37b. For example, the connection portion 140 can be provided along one side of the display portion 37b. Alternatively, the connection portion(s) 140 can be provided along a plurality of sides, for example, can be provided to surround four sides. In the connection portion 140, a common electrode of a light-emitting device is electrically connected to a conductive layer, which supplies a predetermined potential to the common electrode.

The wiring 165 is supplied with a signal or electric power from the FPC 177 or the IC 178. The wiring 165 supplies a signal and electric power to the display portion 37b and the driver circuit portion DRV1.

For example, a gate driver circuit can be used as the driver circuit portion DRV1.

The display apparatus 700 includes a transistor 201, a transistor 205, a light-emitting device 63R, a light-emitting device 63G, a light-emitting device 63B, and the like (see FIG. 4A). For example, the light-emitting device 63R emits red light 83R, the light-emitting device 63G emits green light 83G, and the light-emitting device 63B emits blue light 83B. Note that a variety of optical members can be provided on the outer side of the substrate 18. For example, a polarizing plate, a retardation plate, a light diffusion layer (e.g., a diffusion film), an anti-reflection layer, a light-condensing film, or the like can be provided.

The light-emitting device includes a conductive layer 171, which functions as a pixel electrode. The conductive layer 171 includes a depressed portion, which overlaps with an opening portion provided in an insulating layer 214, an insulating layer 215, and an insulating layer 213. The transistor 205 includes a conductive layer 222b, which is electrically connected to the conductive layer 171.

The display apparatus 700 includes an insulating layer 272. The insulating layer 272 covers an end portion of the conductive layer 171 to fill the depressed portion of the conductive layer 171 (see FIG. 4A).

The display apparatus 700 includes a protective layer 273 and an adhesive layer 142. The protective layer 273 covers the light-emitting devices 63R, 63G, and 63B. The protective layer 273 and the substrate 18 are bonded to each other with the adhesive layer 142. The adhesive layer 142 fills a space between the substrate 18 and the protective layer 273. Note that the adhesive layer 142 may be formed in a frame shape so as not to overlap with the light-emitting devices and a region surrounded by the adhesive layer 142, the substrate 18, and the protective layer 273 may be filled with a resin different from that of the adhesive layer 142.

For example, an organic material such as a reactive curable adhesive, a photocurable adhesive, a thermosetting adhesive, or/and an anaerobic adhesive can be used for the adhesive layer 142.

Specifically, an adhesive containing an epoxy resin, an acrylic resin, a silicone resin, a phenol resin, polyimide, polyvinyl chloride (PVC), polyvinyl butyral (PVB), an ethylene vinyl acetate (EVA) resin, or the like can be used for the adhesive layer 142.

The display apparatus 700 includes the connection portion 140, which includes a conductive layer 168. Note that a power supply potential is supplied to the conductive layer 168. The light-emitting device includes a conductive layer 173. The conductive layer 168 is electrically connected to the conductive layer 173, to which a power supply potential is supplied. Note that the conductive layer 173 functions as a common electrode. For example, the conductive layer 171 and the conductive layer 168 can be formed by processing one conductive film.

The display apparatus 700 has a top-emission structure. The light-emitting device emits light to the substrate 18 side. The conductive layer 171 contains a material reflecting visible light, and the conductive layer 173 transmits visible light.

### Adhesive Layer 56, Insulating Layer 162, Insulating Layer 211, Insulating Layer 213, Insulating Layer 215, and Insulating Layer 214

The display apparatus 700 includes an adhesive layer 56 and an insulating layer 162. The insulating layer 162 and the substrate 17 are bonded to each other with the adhesive layer 56. For example, the material that can be used for the adhesive layer 142 can be used for the adhesive layer 56.

The insulating layer 162, an insulating layer 211, the insulating layer 213, the insulating layer 215, and the insulating layer 214 are provided in this order over the substrate 17. Note that the number of insulating layers is not limited and may be one or two or more. The transistor 201 and the transistor 205 are provided over the insulating layer 162.

For example, an inorganic insulating film can be used as each of the insulating layer 162, the insulating layer 211, the insulating layer 213, and the insulating layer 215. A silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layer 215 and the insulating layer 214 cover the transistors. The insulating layer 214 functions as a planarization layer. For example, a material in which impurities such as water and hydrogen are unlikely to diffuse is preferably used for the insulating layer 215 or the insulating layer 214. This can effectively inhibit impurities from being diffused to the transistors from the outside. Furthermore, the reliability of the display apparatus can be improved.

For example, an organic insulating layer can be suitably used as the insulating layer 214. Specifically, an acrylic resin, polyimide, an epoxy resin, polyamide, polyimide-amide, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, a phenomenon in which a depressed portion is formed in the insulating layer 214 in processing the conductive layer 171 into a predetermined shape can be inhibited.

### Transistor 201 and Transistor 205

The transistor 201 and the transistor 205 can be manufactured using the same materials in the same steps.

For example, the insulating layer 162 is formed over a formation substrate, and the transistors, the light-emitting devices, and the like are formed over the insulating layer 162. Then, the adhesive layer 142 is formed over the light-emitting devices, and the formation substrate and the substrate 18 are bonded to each other with the adhesive layer 142. After that, the formation substrate is separated from the insulating layer 162 and the surface of the insulating layer 162 is exposed. Then, the adhesive layer 56 is formed on the exposed surface of the insulating layer 162, and the insulating layer 162 and the substrate 17 are bonded to each other with the adhesive layer 56. In this manner, the components formed over the formation substrate can be transferred onto the substrate 17, whereby the display apparatus 700 can be manufactured.

Each of the transistor 201 and the transistor 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor layer of the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be suppressed.

The semiconductor layer of the transistor preferably contains a metal oxide. That is, an OS transistor is preferably used as the transistor included in the display apparatus of this embodiment.

### Semiconductor Layer

For example, indium oxide, gallium oxide, and zinc oxide can be used for the semiconductor layer. The metal oxide preferably contains two or three selected from indium, an element M, and zinc. Note that the element M is one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. Specifically, the element M is preferably one or more kinds selected from aluminum, gallium, tin, and yttrium.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the metal oxide used for the semiconductor layer is In—M—Zn oxide, the atomic ratio of In is preferably higher than or equal to the atomic ratio of M in the In—M—Zn oxide. Examples of the atomic ratio of the metal elements in such In—M—Zn oxide include In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or a composition in the neighborhood thereof. Note that a composition in the neighborhood includes the range of ±30 % of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked-layer structure of a first metal oxide layer having In:M:Zn =1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

Examples of an oxide semiconductor having crystallinity include a CAAC (c-axis-aligned crystalline)-OS and an nc (nanocrystalline)-OS.

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With the use of Si transistors such as LTPS transistors, a circuit required to be driven at a high frequency (e.g., a data driver circuit) can be formed on the same substrate as the display portion. This allows simplification of an external circuit mounted on the display apparatus and a reduction in costs of parts and mounting costs.

An OS transistor has much higher field-effect mobility than a transistor containing amorphous silicon. In addition, the OS transistor has an extremely low leakage current between a source and a drain in an off state (hereinafter also referred to as an off-state current), and charge accumulated in a capacitor that is connected in series to the transistor can be held for a long period. Furthermore, the power consumption of the display apparatus can be reduced with the OS transistor.

To increase the luminance of the light-emitting device included in the pixel circuit, the amount of a current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, a high voltage can be applied between the source and the drain of the OS transistor. Therefore, when an OS transistor is used as the driving transistor in the pixel circuit, the amount of a current flowing through the light-emitting device can be increased, so that the luminance of the light-emitting device can be increased.

When transistors are driven in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be minutely determined by controlling the gate-source voltage. Thus, the amount of a current flowing through the light-emitting device can be controlled. Consequently, the number of gray levels in the pixel circuit can be increased.

Regarding saturation characteristics of a current flowing when transistors are driven in the saturation region, even when the source-drain voltage of an OS transistor increases gradually, a more stable current (a saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the luminance of the light-emitting device can be stable.

As described above, by using the OS transistor as the driving transistor included in the pixel circuit, it is possible to inhibit black-level degradation, increase the emission luminance, increase the number of gray levels, and suppress variations in light-emitting devices, for example.

The transistors included in the driver circuit portion DRV1 and the transistors included in the display region 731 may have the same structure or different structures. One structure or two or more kinds of structures may be employed for a plurality of transistors included in the driver circuit portion DRV1. Similarly, one structure or two or more kinds of structures may be employed for a plurality of transistors included in the display region 731.

All transistors included in the display region 731 may be OS transistors, or all transistors included in the display region 731 may be Si transistors. Alternatively, some of the transistors included in the display region 731 may be OS transistors and the others may be Si transistors.

For example, when both an LTPS transistor and an OS transistor are used in the display region 731, the display apparatus can have low power consumption and high driving capability. A structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling a current.

For example, one transistor included in the display region 731 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of a current flowing through the light-emitting device can be increased.

Another transistor included in the display region 731 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. This structure can significantly reduce a leakage current that would flow through a transistor and a leakage current that would flow between adjacent light-emitting devices. Displaying images on the display apparatus having this structure can bring one or more of image crispness, image sharpness, high color saturation, and a high contrast ratio to the viewer. When a leakage current that would flow through the transistor and a lateral leakage current that would flow between light-emitting devices are extremely low, display with little leakage of light at the time of black display (black-level degradation), for example, can be achieved.

In particular, a current flowing between adjacent light-emitting devices having an MML structure can be significantly reduced.

Note that in this specification and the like, a device manufactured using a metal mask or an FMM (a fine metal mask, a high-resolution metal mask) may be referred to as a device having an MM (metal mask) structure. In addition, in this specification and the like, a device manufactured without using a metal mask or an FMM is sometimes referred to as a device having an MML (metal maskless) structure.

### Transistor 209 and Transistor 210

FIG. 4B and FIG. 4C are cross-sectional views each illustrating another example of a cross-sectional structure of a transistor that can be used for the display apparatus 700.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 23 In and the conductive layer 222b is electrically connected to the other of the pair of low-resistance regions 231n. The insulating layer 215 covers the conductive layer 223. An insulating layer 218 covers the transistor.

### Structure Example 1 of Insulating Layer 225

In the transistor 209, the insulating layer 225 covers the top surface and a side surface of the semiconductor layer 231 (see FIG. 4B). The insulating layer 225 and the insulating layer 215 have opening portions, through which the conductive layer 222a and the conductive layer 222b are electrically connected to the low-resistance regions 231n. One of the conductive layer 222a and the conductive layer 222b functions as a source, and the other functions as a drain.

### Structure Example 2 of Insulating Layer 225

In the transistor 210, the insulating layer 225 overlaps with the channel formation region 231i of the semiconductor layer 231 and does not overlap with the low-resistance regions 231n (see FIG. 4C). For example, the insulating layer 225 can be formed by processing into a predetermined shape with use of the conductive layer 223 as a mask. The insulating layer 215 covers the insulating layer 225 and the conductive layer 223. The insulating layer 215 has opening portions, and the conductive layer 222a and the conductive layer 222b are electrically connected to the low-resistance regions 231n.

### Connection Portion 204

A connection portion 204 is provided for the substrate 17. The connection portion 204 includes a conductive layer 166, which is electrically connected to the wiring 165. Note that the connection portion 204 does not overlap with the substrate 18, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

Note that this embodiment can be combined with any of the other embodiments described in this specification as appropriate.

### Embodiment 3

In this embodiment, a structure of the display apparatus 700 that can be used for the display module of one embodiment of the present invention will be described.

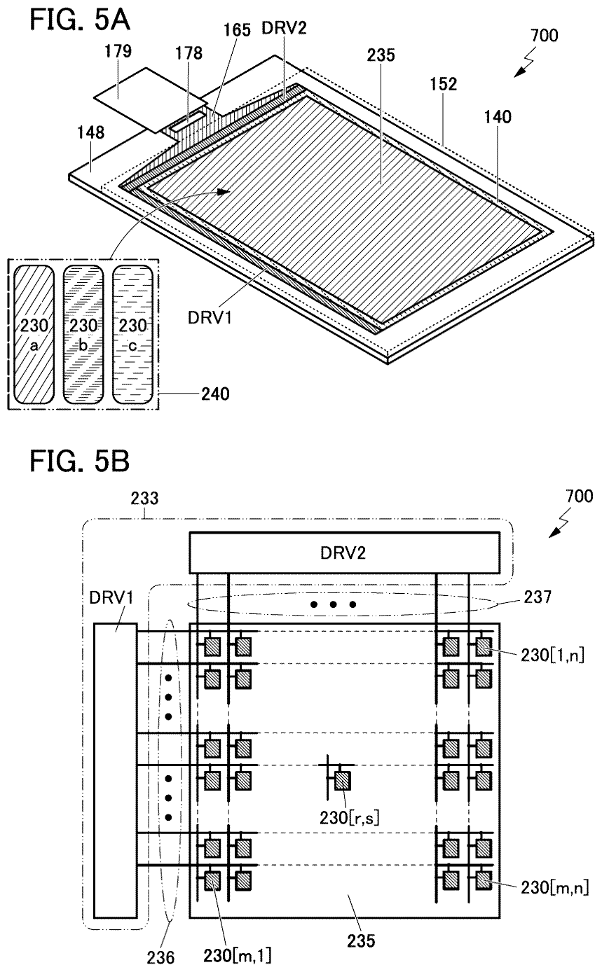

FIG. 5A illustrates a perspective view of the display apparatus 700. The display apparatus 700 has a structure in which the substrate 152 and the substrate 148 are bonded to each other. In FIG. 5A, the substrate 152 is denoted by a dashed line.

The display apparatus 700 includes a display portion 235, the connection portion 140, the driver circuit portion DRV1, the driver circuit portion DRV2, the wiring 165, and the like. FIG. 5A illustrates an example in which the IC 178 and an FPC 179 are mounted on the display apparatus 700. Thus, the structure illustrated in FIG. 5A can also be regarded as a display module including the display apparatus 700, the IC (integrated circuit), and the FPC.

The connection portion 140 is provided outside the display portion 235. The connection portion 140 can be provided along one or more sides of the display portion 235. The number of the connection portions 140 can be one or more. FIG. 5A illustrates an example in which the connection portion 140 is provided to surround the four sides of the display portion. A common electrode of a light-emitting device is electrically connected to a conductive layer in the connection portion 140, so that a potential can be supplied to the common electrode.

The wiring 165 has a function of supplying a signal and electric power to the display portion 235, the driver circuit portion DRV1, and the driver circuit portion DRV2. The signal and electric power are input to the wiring 165 from the outside through the FPC 179 or input to the wiring 165 from the IC 178.

FIG. 5A illustrates an example where the IC 178 is provided over the substrate 148 by a COG (Chip On Glass) method, a COF (Chip On Film) method, or the like. The IC 178 may include a scan line driver circuit or a signal line driver circuit, for example. Note that the display apparatus 700 and the display module are not necessarily provided with an IC. The IC may be mounted on the FPC by a COF method or the like.

The display portion 235 includes a plurality of pixels 230 arranged in a matrix of m rows (m is an integer greater than or equal to 1) and n columns (n is an integer greater than or equal to 1). The plurality of pixels 230 are classified into, for example, pixels 230a, pixels 230b, and pixels 230c. The pixel 230a, the pixel 230b, and the pixel 230c have a function of emitting light of different colors. For example, the pixel 230a may have a function of emitting red (R) light, the pixel 230b may have a function of emitting green (G) light, and the pixel 230c may have a function of emitting blue (B) light. Alternatively, for example, the pixel 230a may have a function of emitting yellow (Y) light, the pixel 230b may have a function of emitting cyan (C) light, and the pixel 230c may have a function of emitting magenta (M) light.

One pixel 230a, one pixel 230b, and one pixel 230c form one pixel 240, which achieves full-color display. Thus, the pixel 230 functions as a subpixel. The display apparatus 700 illustrated in FIG. 5A shows an example in which the pixels 230 each functioning as a subpixel are arranged in a stripe pattern. The number of subpixels for forming one pixel 240 is not limited to three, and may be four or more. For example, four subpixels which emit light of R, G, B, and white (W) may be included. Alternatively, four subpixels which emit light of four colors, R, G, B, and Y may be included.

FIG. 5B is a block diagram illustrating the display apparatus 700. The display apparatus 700 includes the display portion 235, the driver circuit portion DRV1, and the driver circuit portion DRV2. In FIG. 5B, the pixel 230 in the first row and the n-th column is denoted as a pixel 230[1,n], the pixel 230 in the m-th row and the first column is denoted as a pixel 230[m, 1], and the pixel 230 in the m-th row and the n-th column is denoted as a pixel 230[m,n]. A given pixel 230 included in the display portion 235 is denoted as a pixel 230[r,s] in some cases. Note that r is an integer greater than or equal to 1 and less than or equal to m, and s is an integer greater than or equal to 1 and less than or equal to n.

A circuit included in the driver circuit portion DRV1 functions as, for example, a scan line driver circuit. A circuit included in the driver circuit portion DRV2 functions as, for example, a signal line driver circuit. Note that some sort of circuit may be provided at a position facing the driver circuit portion DRV1 with the display portion 235 positioned therebetween. Some sort of circuit may be provided at a position facing the driver circuit portion DRV2 with the display portion 235 positioned therebetween. Note that circuits included in the driver circuit portion DRV1 and the driver circuit portion DRV2 are collectively referred to as a peripheral driver circuit 233.

The driver circuit portion DRV1 functioning as a scan line driver circuit has a function of selecting the pixels 230 row by row. A plurality of pixels 230 arranged in the first row to a plurality of pixels 230 arranged in the m-th row are sequentially selected by the driver circuit portion DRV1, and an image signal supplied from the driver circuit portion DRV2 is written to the selected pixels 230, whereby an image displayed on the display portion 235 can be rewritten.

A period from the selection of the pixels 230 in the first row to the selection of the pixels 230 in the m-th row by the driver circuit portion DRV1 is referred to as a “frame period”. Thus, a frame period is required for rewriting an image displayed on the display portion 235 once. The number of times of rewriting images per second is referred to as a “frame frequency”. The frame frequency corresponds to the reciprocal of the frame period. Note that “frame frequency” is sometimes referred to as “driving frequency”.

The frame frequency is preferably high in the case where a moving image is displayed on the display apparatus 700. Specifically, the frame frequency can be higher than or equal to 60 Hz, preferably higher than or equal to 120 Hz, further preferably higher than or equal to 240 Hz. Meanwhile, as the frame frequency increases, the power consumption of the display apparatus 700 increases.

Any of various circuits such as a shift register circuit, a level shifter circuit, an inverter circuit, a latch circuit, an analog switch circuit, a multiplexer circuit, a demultiplexer circuit, and a logic circuit can be used as the peripheral driver circuit 233.

In the peripheral driver circuit 233, a transistor 10 or the like of one embodiment of the present invention can be used. In the shift register circuit, a shift register 100, a signal output circuit 110, or the like of one embodiment of the present invention can be used. Note that structures of the transistor 10, the shift register 100, and the signal output circuit 110 will be described in detail in Embodiment 4. Transistors included in the peripheral driver circuit may be formed through the same process as the transistors included in the pixels 230. The use of the transistor 10 or the like of one embodiment of the present invention in the peripheral driver circuit 233 can reduce the area occupied by the peripheral driver circuit 233.

The display apparatus 700 includes m wirings 236 which are arranged approximately parallel to each other and whose potentials are controlled by the circuit included in the driver circuit portion DRV1, and n wirings 237 which are arranged approximately parallel to each other and whose potentials are controlled by the circuit included in the driver circuit portion DRV2.

Note that FIG. 5B illustrates an example in which the wirings 236 and the wirings 237 are connected to the pixels 230. Note that the wirings 236 and the wirings 237 are examples, and the wirings connected to the pixels 230 are not limited to the wirings 236 and the wirings 237.

### Display Element

The display apparatus 700 can employ various modes or include various display elements. Examples of display elements include an EL (electroluminescence) element (an organic EL element, an inorganic EL element, or an EL element containing organic and inorganic materials), an LED (e.g., a white LED, a red LED, a green LED, or a blue LED), a transistor (a transistor that emits light depending on a current), an electron emitter, a liquid crystal element, electronic ink, an electrophoretic element, a grating light valve (GLV), a display element using MEMS (micro electro mechanical systems), a digital micromirror device (DMD), a DMS (digital micro shutter), MIRASOL (registered trademark), an IMOD (interferometric modulation) element, a MEMS shutter display element, an optical-interference-type MEMS display element, an electrowetting element, a piezoelectric ceramic display, a display element using a carbon nanotube, and the like, which are elements including a display medium whose contrast, luminance, reflectance, transmittance, or the like is changed by an electrical or magnetic effect. Alternatively, quantum dots may be used as the display element.

Examples of display apparatuses using EL elements include an EL display. Examples of display apparatus using electron emitters include a field emission display (FED) and an SED-type flat panel display (SED: Surface-conduction Electron-emitter Display). Examples of display apparatuses using quantum dots include a quantum dot display. Examples of display apparatus using liquid crystal elements include a liquid crystal display (a transmissive liquid crystal display, a transflective liquid crystal display, a reflective liquid crystal display, a direct-view liquid crystal display, or a projection liquid crystal display). Examples of display apparatuses using electronic ink, Electronic Liquid Powder (registered trademark), or an electrophoretic element include electronic paper. The display apparatus may be a plasma display panel (PDP).

Note that for obtaining a transflective liquid crystal display or a reflective liquid crystal display, some or all of pixel electrodes can function as reflective electrodes. For example, some or all of pixel electrodes can contain aluminum, silver, or the like. Moreover, in such a case, a memory circuit such as an SRAM can be provided under the reflective electrodes. Thus, the power consumption can be further reduced.

Note that in the case where an LED is used, graphene or graphite may be provided under an electrode or a nitride semiconductor of the LED. Graphene or graphite may be a multilayer film in which a plurality of layers are stacked. Providing graphene or graphite as described above facilitates deposition of a nitride semiconductor, such as an n-type GaN semiconductor layer containing crystals, thereover. Furthermore, a p-type GaN semiconductor layer containing crystals or the like can be provided thereover to form the LED. Note that an AIN layer may be provided between graphene or graphite and the n-type GaN semiconductor layer containing crystals. The GaN semiconductor layer included in the LED may be deposited by MOCVD. Note that when graphene is provided, the GaN semiconductor layer included in the LED can be deposited by a sputtering method.

### Structural Example of Pixel Circuit

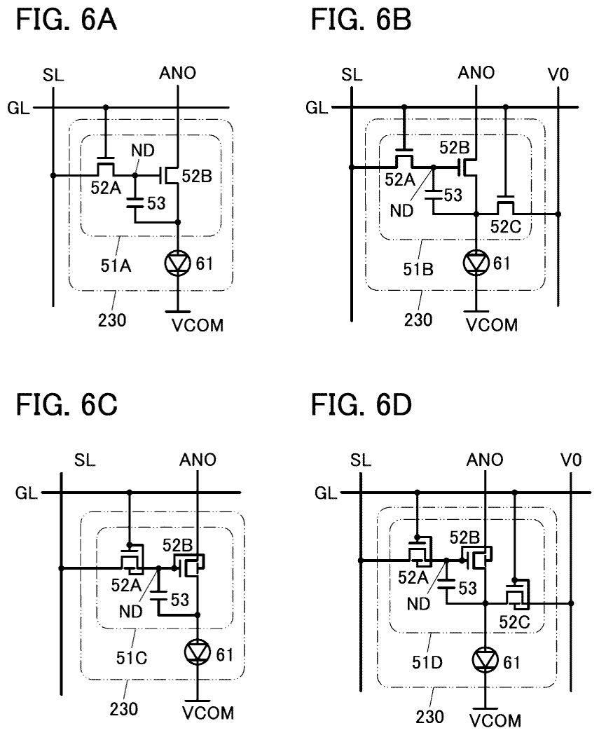

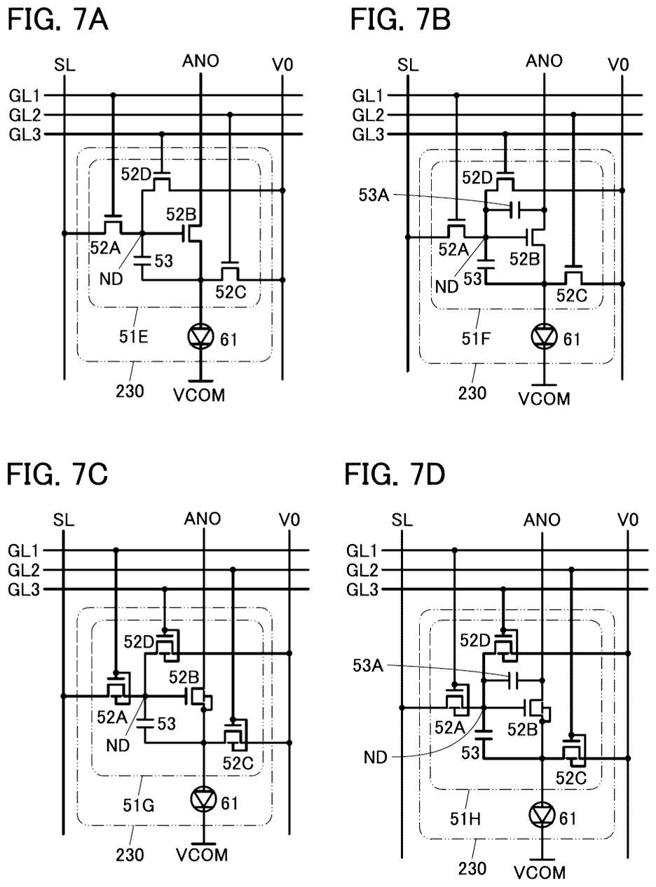

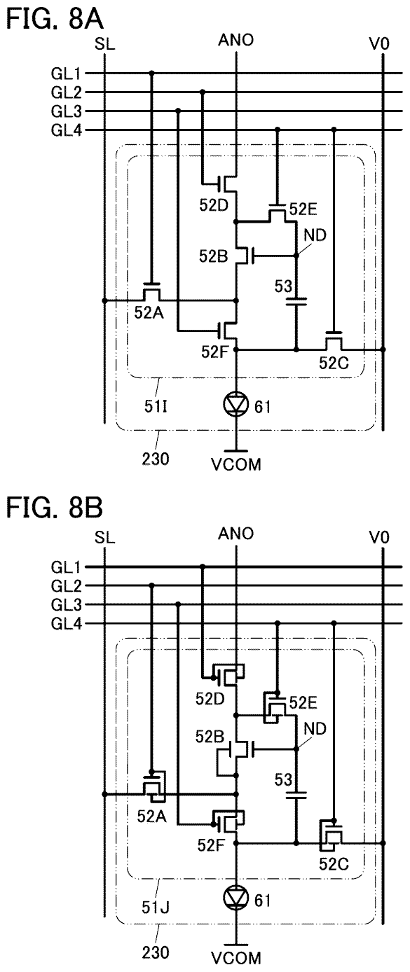

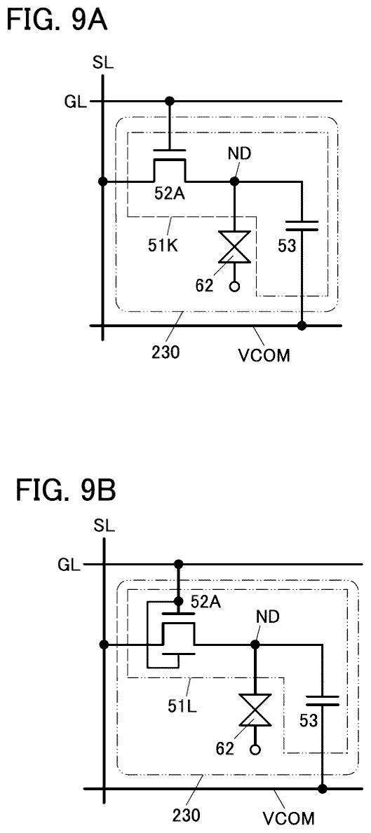

FIG. 6A to FIG. 6D, FIG. 7A to FIG. 7D, FIG. 8A, FIG. 8B, FIG. 9A, and FIG. 9B illustrate structural examples of the pixel 230. The pixel 230 includes a pixel circuit 51 (a pixel circuit 51A, a pixel circuit 51B, a pixel circuit 51C, a pixel circuit 51D, a pixel circuit 51E, a pixel circuit 51F, a pixel circuit 51G, a pixel circuit 51H, a pixel circuit 51I, a pixel circuit 51J, a pixel circuit 51K, or a pixel circuit 51L) and a light-emitting element 61 or a liquid crystal element 62.

The light-emitting element (also referred to as a light-emitting device) described in this embodiment and the like refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

The pixel circuit 51A illustrated in FIG. 6A is a 2Tr1C-type pixel circuit including a transistor 52A, a transistor 52B, and a capacitor 53.

One of a source and a drain of the transistor 52A is electrically connected to a wiring SL, and a gate of the transistor 52A is electrically connected to a wiring GL. The one of the source and the drain of the transistor 52A is electrically connected to a gate of the transistor 52B and one terminal of the capacitor 53. One of a source and a drain of the transistor 52B is electrically connected to a wiring ANO. The other of the source and the drain of the transistor 52B is electrically connected to the other terminal of the capacitor 53 and an anode of the light-emitting element 61. A cathode of the light-emitting element 61 is electrically connected to a wiring VCOM. A region where the other of the source and the drain of the transistor 52A, the gate of the transistor 52B, and the one terminal of the capacitor 53 are electrically connected to one another functions as a node ND.

The wiring GL corresponds to the wiring 236, and the wiring SL corresponds to the wiring 237. The wiring VCOM is a wiring for supplying a potential for supplying a current to the light-emitting element 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

When the transistor 52A is turned on, an image signal is supplied from the wiring SL to the node ND. After that, when the transistor 52A is turned off, the image signal is held in the node ND. In order to surely hold the image signal supplied to the node ND, a transistor with a low off-state current is preferably used as the transistor 52A. For example, an OS transistor is preferably used as the transistor 52A.

With the use of the OS transistor as the transistor 52A, displaying an image on the display portion 235 can be kept even when the frame frequency is extremely low (e.g., 1 Hz or less). For example, in the case of displaying a still image for which rewriting every frame is not required, displaying an image can be kept even when the operation of the peripheral driver circuit 233 is stopped. Such a driving method in which the operation of the peripheral driver circuit 233 is stopped during displaying a still image is also referred to as “idling stop driving”. The power consumption of a display apparatus can be reduced by performing idling stop driving.

The transistor 52B has a function of controlling the amount of a current flowing through the light-emitting element 61. The capacitor 53 has a function of holding a gate potential of the transistor 52B. The intensity of light emitted from the light-emitting element 61 is controlled in accordance with an image signal supplied to the gate of the transistor 52B (the node ND).

The pixel circuit 51B illustrated in FIG. 6B is a 3Tr1C-type pixel circuit including the transistor 52A, the transistor 52B, a transistor 52C, and the capacitor 53. The pixel circuit 51B illustrated in FIG. 6B has a structure in which the transistor 52C is added to the pixel circuit 51A illustrated in FIG. 6A.

One of a source and a drain of the transistor 52C is electrically connected to the other of the source and the drain of the transistor 52B. A gate of the transistor 52C is electrically connected to the wiring GL. The other of the source and the drain of the transistor 52C is electrically connected to a wiring V0. A reference potential is supplied to the wiring V0, for example.

The transistor 52C has a function of controlling electrical continuity between the wiring V0 and the other of the source and the drain of the transistor 52B in accordance with the potential of the wiring GL. The wiring V0 is a wiring for supplying a reference potential. In the case where an n-channel transistor is used as the transistor 52B, a variation in the gate-source potential of the transistor 52B can be reduced by the reference potential of the wiring V0 supplied through the transistor 52C.

A current value that can be used for setting pixel parameters can be obtained using the wiring V0. Specifically, the wiring V0 can function as a monitor line for outputting a current flowing through the transistor 52B or a current flowing through the light-emitting element 61 to the outside. A current output to the wiring V0 can be converted into a voltage by a source follower circuit or the like and can be output to the outside. Alternatively, the current can be converted into a digital signal by an A-D converter or the like and can be output to the outside.

The pixel circuit 51C illustrated in FIG. 6C is an example of the case where a transistor which includes a back gate and in which the back gate is electrically connected to a gate is used as each of the transistor 52A and the transistor 52B in the pixel circuit 51A. The pixel circuit 51D illustrated in FIG. 6D is an example of the case where such transistors are employed in the pixel circuit 51B. Thus, a current that can flow through the transistors can be increased. Although a transistor in which a gate and a back gate are electrically connected to each other is used as each of the transistors here, one embodiment of the present invention is not limited thereto. A transistor which includes a gate and a back gate and in which the gates are electrically connected to different wirings may be used. For example, with the use of a transistor in which one of a gate and a back gate is electrically connected to a source, the reliability can be increased.

The pixel circuit 51E illustrated in FIG. 7A has a structure in which a transistor 52D is added to the pixel circuit 51B illustrated in FIG. 6B. The pixel circuit 51E illustrated in FIG. 7A is a 4Tr1C-type pixel circuit including the transistor 52A, the transistor 52B, the transistor 52C, the transistor 52D, and the capacitor 53.

One of a source and a drain of the transistor 52D is electrically connected to the node ND, and the other is electrically connected to the wiring V0.

A wiring GL1, a wiring GL2, and a wiring GL3 are electrically connected to the pixel circuit 51E. The wiring GLI is electrically connected to the gate of the transistor 52A, the wiring GL2 is electrically connected to the gate of the transistor 52C, and the wiring GL3 is electrically connected to a gate of the transistor 52D. Note that in this embodiment and the like, the wiring GL1, the wiring GL2, and the wiring GL3 are sometimes collectively referred to as the wiring GL. Thus, the wiring GL may be one wiring or a plurality of wirings.

When the transistor 52C and the transistor 52D are turned on at the same time, the source and the gate of the transistor 52B have the same potential, so that the transistor 52B can be turned off. Thus, a current flowing to the light-emitting element 61 can be blocked forcibly. Such a pixel circuit is suitable for the case of using a display method in which a display period and a non-lighting period are alternately provided.

The pixel circuit 51F illustrated in FIG. 7B is an example of the case where a capacitor 53A is added to the pixel circuit 51E. The capacitor 53A functions as a storage capacitor. The pixel circuit 51E illustrated in FIG. 7A is a 4Tr1C-type pixel circuit. The pixel circuit 51F illustrated in FIG. 7B is a 4Tr2C-type pixel circuit.

The pixel circuit 51G illustrated in FIG. 7C and the pixel circuit 51H illustrated in FIG. 7D are each an example of the case where a transistor including a back gate is employed in the pixel circuit 51E or the pixel circuit 51F. A transistor in which a gate and a back gate are electrically connected to each other is used as each of the transistor 52A, the transistor 52C, and the transistor 52D, and a transistor in which one of a gate and a back gate is electrically connected to a source is used as the transistor 52B.

The pixel circuit 51I illustrated in FIG. 8A is a 6Tr1C-type pixel circuit including the transistor 52A, the transistor 52B, the transistor 52C, the transistor 52D, a transistor 52E, a transistor 52F, and the capacitor 53.

One of the source and the drain of the transistor 52A is electrically connected to the wiring SL, and the gate of the transistor 52A is electrically connected to the wiring GL1. One of the source and the drain of the transistor 52D is electrically connected to the wiring ANO, and the gate of the transistor 52D is electrically connected to the wiring GL2. The other of the source and the drain of the transistor 52D is electrically connected to one of the source and the drain of the transistor 52B. The other of the source and the drain of the transistor 52B is electrically connected to the other of the source and the drain of the transistor 52A and one of a source and a drain of the transistor 52F. A gate of the transistor 52F is electrically connected to the wiring GL3.

One of a source and a drain of the transistor 52E is electrically connected to the other of the source and the drain of the transistor 52D and the one of the source and the drain of the transistor 52B. The other of the source and the drain of the transistor 52E is electrically connected to the gate of the transistor 52B and one terminal of the capacitor 53. The other terminal of the capacitor 53 is electrically connected to the other of the source and the drain of the transistor 52F, the anode of the light-emitting element 61, and one of the source and the drain of the transistor 52C.

A gate of the transistor 52E and the gate of the transistor 52C are electrically connected to a wiring GL4. The other of the source and the drain of the transistor 52C is electrically connected to the wiring V0. A region where the other of the source and the drain of the transistor 52E, the gate of the transistor 52B, and the one terminal of the capacitor 53 are electrically connected to one another functions as the node ND. In the pixel circuit 51I, an OS transistor is preferably used particularly as the transistor 52E.

As illustrated in FIG. 8B, a transistor having a back gate may be used as the transistor included in the pixel circuit 51J. A transistor in which a gate and a back gate are electrically connected to each other is used as each of the transistor 52A, the transistor 52C, the transistor 52D, the transistor 52E, and the transistor 52F, and a transistor in which a back gate is electrically connected to the other of the source and the drain is used as the transistor 52B.

The transistor 10 of one embodiment of the present invention can be used as each of the transistor 52A, the transistor 52C, the transistor 52D, the transistor 52E, and the transistor 52F. The transistor 10 of one embodiment of the present invention may be used as the transistor 52B.

The pixel 230 illustrated in FIG. 9A includes the pixel circuit 51K and a liquid crystal element 62. The pixel circuit 51K includes the transistor 52A and the capacitor 53. In FIG. 9A, one of the source and the drain of the transistor 52A is electrically connected to the wiring SL, and the gate of the transistor 52A is electrically connected to the wiring GL. The other of the source and the drain of the transistor 52A is electrically connected to one terminal of the capacitor 53 and the liquid crystal element 62. The other terminal of the capacitor 53 is electrically connected to the wiring VCOM. A region where the other of the source and the drain of the transistor 52A, the one terminal of the capacitor 53, and the liquid crystal element 62 are electrically connected to one another functions as the node ND. The alignment state of the liquid crystal element 62 is set depending on data written to the node ND.

As a driving method of the display apparatus including the liquid crystal element 62, for example, a TN (Twisted Nematic) mode, an STN (Super Twisted Nematic) mode, a VA mode, an ASM (Axially Symmetric Aligned Micro-cell) mode, an OCB (Optically Compensated Birefringence) mode, an FLC (Ferroelectric Liquid Crystal) mode, an AFLC (AntiFerroelectric Liquid Crystal) mode, an MVA mode, a PVA (Patterned Vertical Alignment) mode, an IPS mode, an FFS mode, a TBA (Transverse Bend Alignment) mode, or the like may be used. Examples of driving methods of the display apparatus include, in addition to the above driving methods, an ECB (Electrically Controlled Birefringence) mode, a PDLC (Polymer Dispersed Liquid Crystal) mode, a PNLC (Polymer Network Liquid Crystal) mode, and a guest-host mode. However, without limitation to the above, a variety of liquid crystal elements and the driving methods thereof can be used.

When the liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

A liquid crystal exhibiting a blue phase for which an alignment film is not needed may be used. The blue phase is one of liquid crystal phases, which is generated just before a cholesteric phase changes into an isotropic phase while the temperature of a cholesteric liquid crystal is increased. Since the blue phase is only generated within a narrow temperature range, a liquid crystal composition that contains a chiral material at greater than or equal to 5 wt % is used for a liquid crystal layer in order to improve the temperature range. The liquid crystal composition that contains a liquid crystal exhibiting the blue phase and a chiral material has a short response time of 1 msec or less, and has optical isotropy, which makes the alignment process unneeded and the viewing angle dependence small. An alignment film does not need to be provided and rubbing treatment is thus not necessary; accordingly, electrostatic discharge damage caused by the rubbing treatment can be prevented and defects and damage of the liquid crystal display apparatus in the manufacturing process can be reduced. Thus, the productivity of the liquid crystal display apparatus can be increased.

Moreover, it is possible to use a method called domain multiplication or multi-domain design, in which a pixel (pixel) is divided into some regions (subpixels) and molecules are aligned in different directions in their respective regions.

The specific resistance of a liquid crystal material is greater than or equal to 1×10⁹ Ω·cm, preferably greater than or equal to 1×10¹¹ Ω·cm, further preferably greater than or equal to 1×10¹² Ω·cm. Note that the value of the specific resistance in this specification is a value measured at 20° C.

As illustrated in FIG. 9B, the pixel 230 may include the pixel circuit 51L instead of the pixel circuit 51K. The pixel circuit 51L includes the transistor 52A having a back gate. In the transistor 52A illustrated in FIG. 9B, the gate is electrically connected to the back gate. Thus, the gate and the back gate always have the same potential.

The use of the transistor 10 of one embodiment of the present invention in the pixel circuit of the display apparatus can reduce the area occupied by the pixel circuit. Thus, the resolution of the display apparatus can be improved. For example, a display apparatus with a resolution higher than or equal to 1000 ppi, preferably higher than or equal to 2000 ppi, further preferably higher than or equal to 3000 ppi, still further preferably higher than or equal to 4000 ppi, yet further preferably higher than or equal to 5000 ppi, yet still further preferably higher than or equal to 6000 ppi, and lower than or equal to 10000 ppi, lower than or equal to 9000 ppi, or lower than or equal to 8000 ppi can be obtained.

The reduction in the area occupied by the pixel circuit can increase the number of pixels of the display apparatus (can increase the definition). For example, a display apparatus with an extremely high definition of HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320) can be obtained.

Accordingly, the use of the transistor 10 of one embodiment of the present invention in the pixel circuit of the display apparatus can increase the display quality of the display apparatus. A bottom-emission display apparatus using an EL element can have a high aperture ratio of a pixel. A pixel with a high aperture ratio can have a lower current density than a pixel with a low aperture ratio when the pixel with a high aperture ratio and the pixel with a low aperture ratio emit light with the same luminance. Thus, the reliability of the display apparatus can be improved.

### Structural Example of Peripheral Circuit

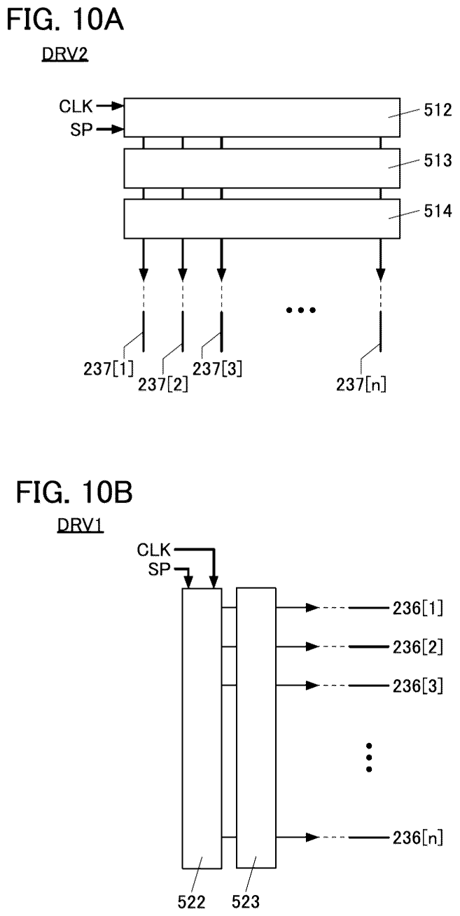

FIG. 10A illustrates a structural example of the driver circuit portion DRV2. The driver circuit portion DRV2 includes a shift register 512, a latch circuit 513, and a buffer 514. A wiring 237[1], a wiring 237[2], a wiring 237[3], and a wiring 237[n] are illustrated as the wirings 237. FIG. 10B illustrates a structural example of the driver circuit portion DRV1. The driver circuit portion DRV1 includes a shift register 522 and a buffer 523. A wiring 236[1], a wiring 236[2], a wiring 236[3], and a wiring 236[n] are illustrated as the wirings 236.

A start pulse SP, a clock signal CLK, and the like are input to the shift register 512 and the shift register 522. The shift register 100 described in the above embodiment can be used as each of the shift register 512 and the shift register 522.

### Pixel Layout

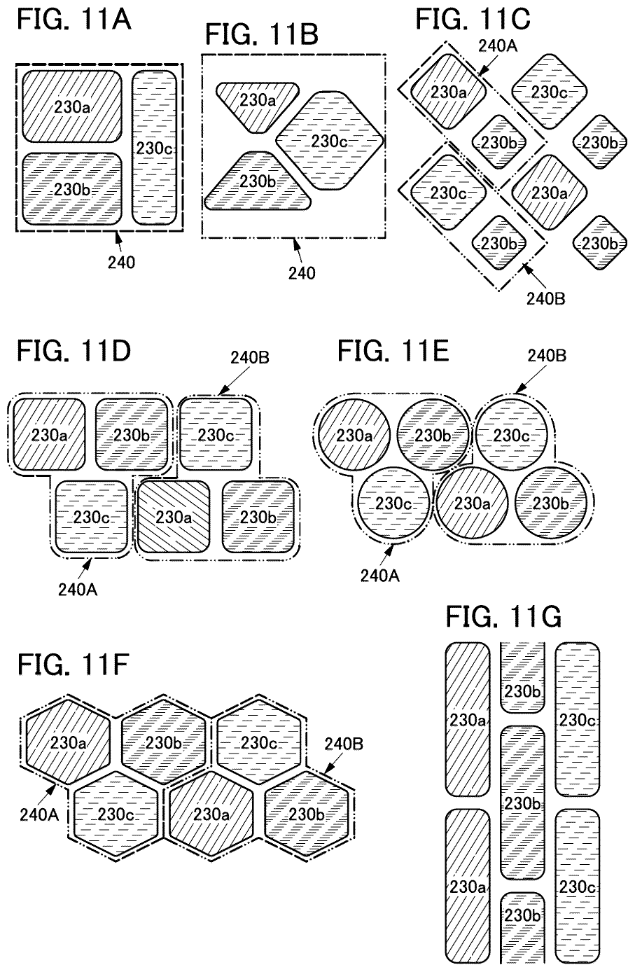

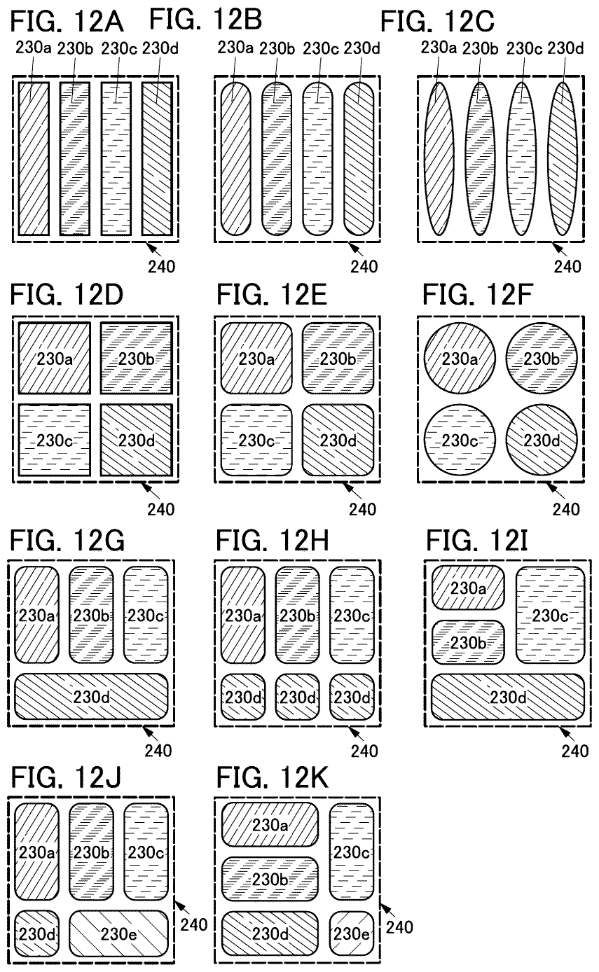

Pixel layouts different from that in FIG. 5A will be mainly described with reference to FIG. 11A to FIG. 11G and FIG. 12A to FIG. 12K. There is no particular limitation on the arrangement of subpixels, and a variety of pixel layouts can be employed. Examples of the arrangement of subpixels include stripe arrangement, S-stripe arrangement, matrix arrangement, delta arrangement, Bayer arrangement, and PenTile arrangement.

Note that the planar shapes of the subpixels illustrated in FIG. 5A, FIG. 11A to FIG. 11G, and FIG. 12A to FIG. 12K correspond to the planar shapes of light-emitting regions.

Examples of the planar shape of the subpixel include polygons such as a triangle, a tetragon (including a rectangle and a square), and a pentagon; polygons with rounded corners; an ellipse; and a circle.

The pixel circuit 51 included in the subpixel (the pixel 230) may be placed to overlap with a light-emitting region or may be placed outside the light-emitting region.

The pixel 240 illustrated in FIG. 11A employs S-stripe arrangement. The pixel 240 illustrated in FIG. 11A is composed of three types of subpixels that are the pixel 230a, the pixel 230b, and the pixel 230c.

The pixel 240 illustrated in FIG. 11B includes the pixel 230a having a rough trapezoidal planar shape with rounded corners, the pixel 230b having a rough triangle planar shape with rounded corners, and the pixel 230c having a rough tetragonal or rough hexagonal planar shape with rounded corners. The pixel 230c has a larger light-emitting area than the pixel 230b. In this manner, the shapes and sizes of the subpixels can be determined independently. For example, the size of a subpixel including a light-emitting device with higher reliability can be smaller.

A pixel 240A and a pixel 240B illustrated in FIG. 11C employ PenTile arrangement. FIG. 11C illustrates an example in which the pixels 240A including the pixel 230a and the pixel 230b and the pixels 240B including the pixel 230b and the pixel 230c are alternately arranged.

The pixel 240A and the pixel 240B illustrated in FIG. 11D to FIG. 11F employ delta arrangement. The pixel 240A includes two subpixels (the pixel 230a and the pixel 230b) in the upper row (first row) and one subpixel (the pixel 230c) in the lower row (second row). The pixel 240B includes one subpixel (the pixel 230c) in the upper row (first row) and two subpixels (the pixel 230a and the pixel 230b) in the lower row (second row).

FIG. 11D illustrates an example where each subpixel has a rough tetragonal planar shape with rounded corners, FIG. 11E illustrates an example where each subpixel has a circular planar shape, and FIG. 11F illustrates an example where each subpixel has a rough hexagonal planar shape.

In FIG. 11F, each subpixel is placed inside respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the pixel 230a, the pixel 230a is surrounded by three pixels 230b and three pixels 230c that are alternately arranged.

FIG. 11G illustrates an example in which subpixels of different colors are arranged in a zigzag manner. Specifically, the positions of the top sides of two subpixels arranged in the row direction (e.g., the pixel 230a and the pixel 230b or the pixel 230b and the pixel 230c) are not aligned in a plan view.

For example, in each pixel illustrated in FIG. 11A to FIG. 11G, it is preferable that the pixel 230a be a subpixel R emitting red light, the pixel 230b be a subpixel G emitting green light, and the pixel 230c be a subpixel B emitting blue light. Note that the structure of the subpixels is not limited to this, and the colors and arrangement order of the subpixels can be determined as appropriate. For example, the pixel 230b may be the subpixel R emitting red light and the pixel 230a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a subpixel sometimes has a polygonal planar shape with rounded corners, an elliptical planar shape, a circular planar shape, or the like.

In the case where the EL layer is processed into an island shape using a resist mask, a resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the EL layer may have a poly gonal planar shape with rounded corners, an elliptical planar shape, a circular planar shape, or the like. For example, when a resist mask having a square planar shape is intended to be formed, a resist mask having a circular planar shape may be formed, and the EL layer may have a circular planar shape.

Note that to obtain a desired planar shape of the EL layer, a technique of correcting a mask pattern in advance such that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 12A to FIG. 12I, the pixel can be configured to include four types of subpixels.

The pixels 240 illustrated in FIG. 12a to FIG. 12c employ stripe arrangement.

FIG. 12A illustrates an example where each subpixel has a rectangular planar shape, FIG. 12B illustrates an example where each subpixel has a planar shape formed by combining two half circles and a rectangle, and FIG. 12C illustrates an example where each subpixel has an elliptical planar shape.

The pixels 240 illustrated in FIG. 12D to FIG. 12F employ matrix arrangement.

FIG. 12D illustrates an example where each subpixel has a square planar shape, FIG. 12E illustrates an example where each subpixel has a substantially square planar shape with rounded corners, and FIG. 12F illustrates an example where each subpixel has a circular planar shape.

FIG. 12G and FIG. 12H each illustrate an example in which one pixel 240 is composed of subpixels arranged in two rows and three columns.

The pixel 240 illustrated in FIG. 12G includes three subpixels (the pixel 230a, the pixel 230b, and the pixel 230c) in the upper row (first row) of the pixel 240 and one subpixel (a pixel 230d) in the lower row (second row) thereof. In other words, the pixel 240 includes the pixel 230a in the left column (first column), the pixel 230b in the center column (second column), the pixel 230c in the right column (third column), and the pixel 230d across these three columns.

The pixel 240 illustrated in FIG. 12H includes three subpixels (the pixel 230a, the pixel 230b, and the pixel 230c) in the upper row (first row) and three pixels 230d in the lower row (second row). In other words, the pixel 240 includes the pixel 230a and the pixel 230d in the left column (first column) of the pixel 240, the pixel 230b and the pixel 230d in the center column (second column) thereof, and the pixel 230c and the pixel 230d in the right column (third column) thereof. Aligning the positions of the subpixels in the upper row and the lower row as illustrated in FIG. 12H enables dust and the like that would be produced in the manufacturing process to be removed efficiently. Thus, a display apparatus with high display quality can be provided.

FIG. 12I illustrates an example in which one pixel 240 is composed of subpixels arranged in three rows and two columns.

The pixel 240 illustrated in FIG. 12I includes the pixel 230a in the upper row (first row) of the pixel 240, the pixel 230b in the center row (second row) thereof, the pixel 230c across the first row and the second row, and one subpixel (the pixel 230d) in the lower row (third row) thereof. In other words, the pixel 240 includes the pixel 230a and the pixel 230b in the left column (first column) of the pixel 240, the pixel 230c in the right column (second column) thereof, and the pixel 230d across these two columns thereof.

The pixels 240 illustrated in FIG. 12A to FIG. 12I are each composed of four subpixels: the pixel 230a, the pixel 230b, the pixel 230c, and the pixel 230d.

The pixel 230a, the pixel 230b, the pixel 230c, and the pixel 230d can be configured to include light-emitting devices whose emission colors are different. The pixel 230a, the pixel 230b, the pixel 230c, and the pixel 230d can be subpixels of four colors of R, G, B, and white (W), subpixels of four colors of R, G, B, and Y, or subpixels of R, G, B, and infrared light (IR), for example.

In the pixels 240 illustrated in FIG. 12A to FIG. 12I, the pixel 230a may be the subpixel R emitting red light, the pixel 230b may be the subpixel G emitting green light, the pixel 230c may be the subpixel B emitting blue light, and the pixel 230d may be any of a subpixel W emitting white light, a subpixel emitting yellow light, and a subpixel emitting near-infrared light, for example. In the case of such a structure, stripe arrangement is employed as the layout of R, G, and B in the pixels 240 illustrated in FIG. 12G and FIG. 12H, leading to higher display quality. In addition, what is called S-stripe arrangement is employed as the layout of R, G, and B in the pixel 240 illustrated in FIG. 12I, leading to higher display quality.

Note that the pixel 240 may include a subpixel including a light-receiving element (also referred to as a light-receiving device).

In the pixels 240 illustrated in FIG. 12A to FIG. 12I, any one of the pixel 230a to the pixel 230d may be a subpixel including a light-receiving device.

In the pixels 240 illustrated in FIG. 12A to FIG. 121, the pixel 230a may be the subpixel R emitting red light, the pixel 230b may be the subpixel G emitting green light, the pixel 230c may be the subpixel B emitting blue light, and the pixel 230d may be a subpixel S including a light-receiving device, for example. In the case of such a structure, stripe arrangement is employed as the layout of R, G, and B in the pixels 240 illustrated in FIG. 12G and FIG. 12H, leading to higher display quality. In addition, what is called S-stripe arrangement is employed as the layout of R, G, and B in the pixel 240 illustrated in FIG. 12I, leading to higher display quality.

There is no particular limitation on the wavelength of light detected by the subpixel S including a light-receiving device. The subpixel S can be configured to detect one or both of visible light and infrared light.

As illustrated in FIG. 12J and FIG. 12K, one pixel 240 may be configured to include five types of subpixels.

FIG. 12J illustrates an example in which one pixel 240 is composed of subpixels arranged in two rows and three columns.

The pixel 240 illustrated in FIG. 12J includes three subpixels (the pixel 230a, the pixel 230b, and the pixel 230c) in the upper row (first row) of the pixel 240 and two subpixels (the pixel 230d and a pixel 230e) in the lower row (second row) thereof. In other words, the pixel 240 includes the pixel 230a and the pixel 230d in the left column (first column) of the pixel 240, the pixel 230b in the center column (second column) thereof, the pixel 230c in the right column (third column) thereof, and the pixel 230e across the second column and the third column thereof.

FIG. 12K illustrates an example in which one pixel 240 is composed of subpixels arranged in three rows and two columns.

The pixel 240 illustrated in FIG. 12K includes the pixel 230a in the upper row (first row) of the pixel 240, the pixel 230b in the center row (second row) thereof, the pixel 230c across the first row and the second row, and two subpixels (the pixel 230d and the pixel 230e) in the lower row (third row) thereof. In other words, the pixel 240 includes the pixel 230a, the pixel 230b, and the pixel 230d in the left column (first column) and the pixel 230c and the pixel 230e in the right column (second column).

In the pixels 240 illustrated in FIG. 12J and FIG. 12K, it is preferable that the pixel 230a be the subpixel R emitting red light, the pixel 230b be the subpixel G emitting green light, and the pixel 230c be the subpixel B emitting blue light, for example. In the case of such a structure, stripe arrangement is employed as the layout of subpixels in the pixels 240 illustrated in FIG. 12J, leading to higher display quality. In addition, what is called S-stripe arrangement is employed as the layout of subpixels in the pixel 240 illustrated in FIG. 12K, leading to higher display quality.

In the pixels 240 illustrated in FIG. 12J and FIG. 12K, for example, the subpixel S including a light-receiving device may be used as at least one of the pixel 230d and the pixel 230e. In the case where light-receiving devices are used in both the pixel 230d and the pixel 230e, the light-receiving devices may have different structures. For example, the wavelength ranges of detected light may be different at least partly. Specifically, one of the pixel 230d and the pixel 230e may include a light-receiving device mainly detecting visible light and the other may include a light-receiving device mainly detecting infrared light.

In the pixels 240 illustrated in FIG. 12J and FIG. 12K, for example, the subpixel S including a light-receiving device may be used as one of the pixel 230d and the pixel 230e and a subpixel including a light-emitting device that can be used as a light source may be used as the other. For example, one of the pixel 230d and the pixel 230e may be a subpixel IR (not illustrated) emitting infrared light and the other may be the subpixel S (not illustrated) including a light-receiving device detecting infrared light.

In a pixel including the subpixels R, G, B, IR, and S, while an image is displayed using the subpixels R, G, and B, reflected light of infrared light emitted from the subpixel IR that is used as a light source can be detected by the subpixel S.

As described above, in the display apparatus of one embodiment of the present invention, various layouts of the subpixels (the pixels 230) can be employed for the pixel 240. Furthermore, the pixel 240 may be configured to include both a light-emitting device and a light-receiving device. Also in this case, any of various layouts can be employed.

The structure described in this embodiment can be used in an appropriate combination with the structures described in the other embodiments.

### Embodiment 4

In this embodiment, examples of a signal output circuit, which is a kind of semiconductor device, and a shift register including the signal output circuit will be described with reference to drawings.

### Structure of Shift Register 100

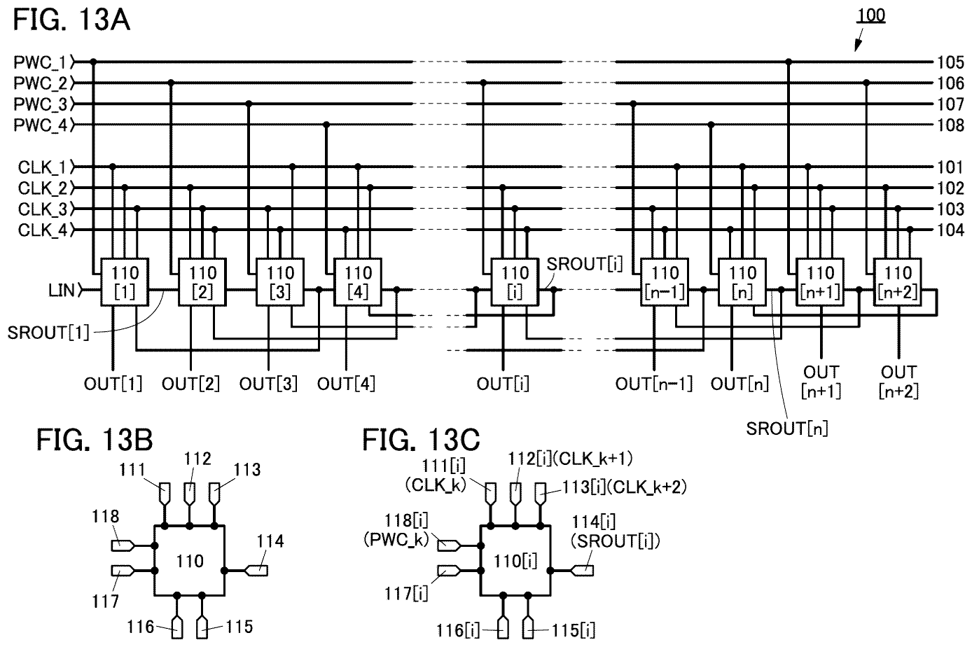

A shift register 100 illustrated in FIG. 13A includes n signal output circuits 110 (n is an integer greater than or equal to 1). In this specification and the like, the signal output circuit 110 in the first stage (the first signal output circuit 110) is referred to as a signal output circuit 110[1] in some cases, and the signal output circuit 110 in the n-th stage (the n-th signal output circuit 110) is referred to as a signal output circuit 110[n] in some cases.

The signal output circuit 110 in the i-th stage (i is an integer greater than or equal to 1 and less than or equal to n) is referred to as a signal output circuit 110[i] in some cases. Note that when a given stage is denoted by i+α and a is positive, i+α does not exceed n. In addition, when a given stage is denoted by i−α and a is positive, i−α does not become less than 1.

The shift register 100 includes two signal output circuits 110 (a signal output circuit 110[n+1] and a signal output circuit 110[n+2]) that are dummy circuits.

Note that a terminal, input and output signals, and the like of the signal output circuit 110 are denoted in a manner similar to the above in some cases. For example, a signal OUT of the signal output circuit 110[i] is referred to as a signal OUT[i] in some cases.

The shift register 100 includes a wiring 101 to a wiring 104 to which four signals CLK (a signal CLK_1 to a signal CLK_4) that are clock signals are supplied, and a wiring 105 to a wiring 108 to which four signals PWC (a signal PWC_1 to a signal PWC_4) are supplied. The signal CLK_1 is supplied to the wiring 101, the signal CLK_2 is supplied to the wiring 102, the signal CLK_3 is supplied to the wiring 103, and the signal CLK_4 is supplied to the wiring 104. The signal PWC_1 is supplied to the wiring 105, the signal PWC_2 is supplied to the wiring 106, the signal PWC_3 is supplied to the wiring 107, and the signal PWC_4 is supplied to the wiring 108.

The signal output circuits 110 each include a terminal 111 to a terminal 118 (see FIG. 13B). The terminal 111, the terminal 112, and the terminal 113 are individually electrically connected to different wirings among the wiring 101 to the wiring 104. For example, in FIG. 13A, the terminal 111 of the signal output circuit 110[1] in the first stage is electrically connected to the wiring 101, the terminal 112 thereof is electrically connected to the wiring 102, and the terminal 113 thereof is electrically connected to the wiring 103. That is, the signal CLK_1 is supplied to the terminal 111, the signal CLK_2 is supplied to the terminal 112, and the signal CLK_3 is supplied to the terminal 113.

The terminal 111 of the signal output circuit 110[2] in the second stage is electrically connected to the wiring 102, the terminal 112 thereof is electrically connected to the wiring 103, and the terminal 113 thereof is electrically connected to the wiring 104. That is, the signal CLK_2 is supplied to the terminal 111, the signal CLK_3 is supplied to the terminal 112, and the signal CLK_4 is supplied to the terminal 113.

That is, the signal CLK_k is supplied to the terminal 111[i] of the signal output circuit 110[i] (see FIG. 13C). Here, k is an integer greater than or equal to 1 and less than or equal to 4,k is equal to i when i is less than or equal to 4, and k is equal to i−4xg when i is greater than or equal to 5. Note that g is a quotient obtained by dividing i by 4.

The signal CLK_k+1 is supplied to the terminal 112[i] of the signal output circuit 110[i]. Here, k is an integer greater than or equal to 1 and less than or equal to 4, and k is 1 when k+1 is 5. When i is less than or equal to 3, k is equal to i, and when i is greater than or equal to 4, k is equal to i−4xg.

The signal CLK_k+2 is supplied to the terminal 113[i] of the signal output circuit 110[i]. Here, k+1 is an integer greater than or equal to 1 and less than or equal to 4; k+2 is 1 when k+2 is 5; and k+2 is 2 when k+2 is 6. When i is less than or equal to 2, k is equal to i, and when i is greater than or equal to 3, k is equal to i−4xg.

The terminal 114[i] is electrically connected to the terminal 117[i+1] (not illustrated) of the signal output circuit 110[i+1] (not illustrated) in the next stage. Thus, the terminal 117[i] is electrically connected to the terminal 114[i−1]. For example, the terminal 114 of the signal output circuit 110[1] is electrically connected to the terminal 117 of the signal output circuit 110[2]. A start pulse SP is supplied to the terminal 117 of the signal output circuit 110[1].

The terminal 115[i] is electrically connected to the terminal 114[i+2] (not illustrated) of the signal output circuit 110[i+2] (not illustrated) in the second subsequent stage. For example, the terminal 115 of the signal output circuit 110[1] is electrically connected to the terminal 114 of the signal output circuit 110[3], and the terminal 115 of the signal output circuit 110[2] is electrically connected to the terminal 114 of the signal output circuit 110[4]. Thus, the terminal 115 of the signal output circuit 110[n−1] is electrically connected to the terminal 114 of the signal output circuit 110[n+1], and the terminal 115 of the signal output circuit 110[n] is electrically connected to the terminal 114 of the signal output circuit 110[n+2]. Note that the signal output circuit 110[n+1] and the signal output circuit 110[n+2] do not necessarily include the terminal 115.

The terminal 118[i] is electrically connected to any of the wiring 105 to the wiring 108. For example, the terminal 118 of the signal output circuit 110[1] is electrically connected to the wiring 105, and the terminal 118 of the signal output circuit 110[2] is electrically connected to the wiring 106. In other words, the signal PWC_k is supplied to the terminal 118[i] of the signal output circuit 110[i]. Here, k is an integer greater than or equal to 1 and less than or equal to 4,k is equal to i when i is less than or equal to 4, and k is equal to i−4xg when i is greater than or equal to 5.

The signal OUT[i] is output from the terminal 116[i]. For example, the signal OUT[1] is output from the terminal 116 of the signal output circuit 110[1]. The signal OUT[n] is output from the terminal 116 of the signal output circuit 110[n] in the n-th stage. Note that “the signal OUT[i] is output from the terminal 116[i]” can be rephrased as “the signal OUT[i] is supplied to the terminal 116[i]”.

The signal SROUT[i] is supplied to the terminal 114[i]. In other words, the signal SROUT[i] is output from the terminal 114[i]. For example, the signal SROUT[1] is output from the terminal 114 of the signal output circuit 110[1]. The signal SROUT[n] is output from the terminal 114 of the signal output circuit 110[n] in the n-th stage. Note that “the signal SROUT[i] is output from the terminal 114[i]” can be rephrased as “the signal SROUT[i] is supplied to the terminal 114[i]”.

### Structural Example of Signal Output Circuit 110

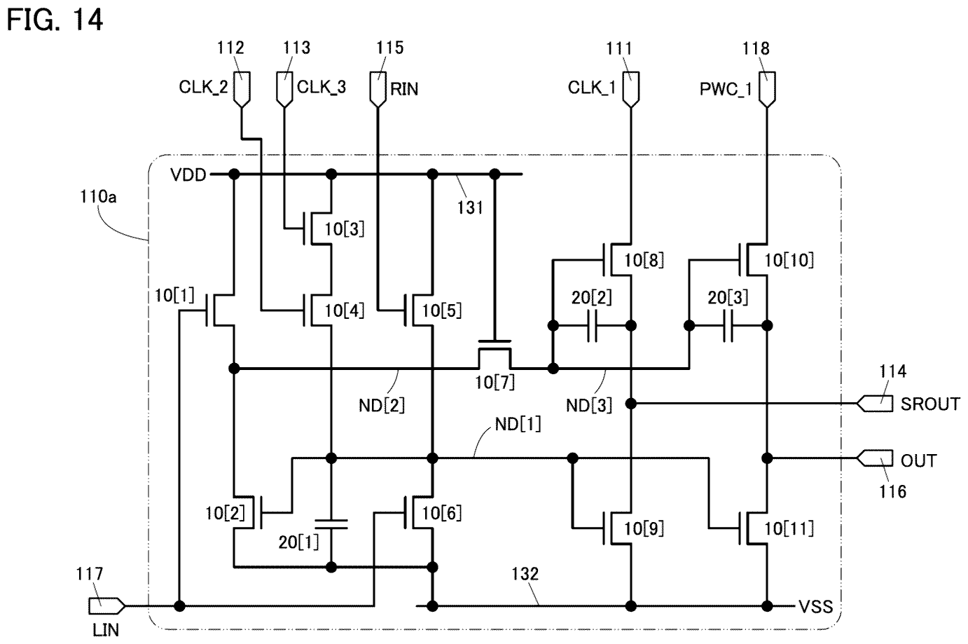

Next, a structure of a signal output circuit 110a, which can be used as the signal output circuit 110, will be described (see FIG. 14). The signal output circuit 110a includes a transistor 10[1] to a transistor 10[11] and a capacitor 20[1] to a capacitor 20[3].

A gate of the transistor 10[1] is electrically connected to the terminal 117 and a gate of the transistor 10[6]. A source of the transistor 10[1] is electrically connected to a drain of the transistor 10[2], and a drain of the transistor 10[1] is electrically connected to a wiring 131. A gate of the transistor 10[2] is electrically connected to one terminal of the capacitor 20[1]. A source of the transistor 10[2] is electrically connected to the other terminal of the capacitor 20[1], a source of the transistor 10[6], and a wiring 132.

A gate of the transistor 10[3] is electrically connected to the terminal 113, a drain of the transistor 10[3] is electrically connected to the wiring 131, and a source of the transistor 10[3] is electrically connected to a drain of the transistor 10[4]. A gate of the transistor 10[4] is electrically connected to the terminal 112, and the drain of the transistor 10[4] is electrically connected to the source of the transistor 10[3]. A source of the transistor 10[4] is electrically connected to the gate of the transistor 10[2], a gate of the transistor 10[9], and a gate of the transistor 10[11] and the one terminal of the capacitor 20[1].

Note that in this specification and the like, a region where the gates of the transistor 10[2], the transistor 10[9], and the transistor 10[11], the source of the transistor 10[4], and the one terminal of the capacitor 20[1] are electrically connected to each other is referred to as a node ND[1]. The capacitor 20[1] has a function of inhibiting a change in the potential of the node ND[1] at the time when the node ND[1] is brought into a floating state and maintaining the potential of the node ND[1].

A gate of the transistor 10[5] is electrically connected to the terminal 115, and a drain of the transistor 10[5] is electrically connected to the wiring 131. A source of the transistor 10[5] is electrically connected to the gate of the transistor 10[2], the gate of the transistor 10[9], the gate of the transistor 10[11], and a drain of the transistor 10[6].

A gate of the transistor 10[7] is electrically connected to the wiring 131, and one of a source and a drain of the transistor 10[7] is electrically connected to the source of the transistor 10[1] and the drain of the transistor 10[2]. The other of the source and the drain of the transistor 10[7] is electrically connected to a gate of the transistor 10[8], one terminal of the capacitor 20[2], a gate of the transistor 10[10], and one terminal of the capacitor 20[3].

Note that in this specification and the like, a region where the one of the source and the drain of the transistor 10[7], the source of the transistor 10[1], and the drain of the transistor 10[2] are electrically connected to each other is referred to as a node ND[2]. In this specification and the like, a region where the other of the source and the drain of the transistor 10[7], the gate of the transistor 10[8], the one terminal of the capacitor 20[2], the gate of the transistor 10[10], and the one terminal of the capacitor 20[3] are electrically connected to each other is referred to as a node ND[3].

A drain of the transistor 10[8] is electrically connected to the terminal 111. A source of the transistor 10[8] is electrically connected to the other terminal of the capacitor 20[2], the terminal 114, and a drain of the transistor 10[9]. A drain of the transistor 10[10] is electrically connected to the terminal 118. A source of the transistor 10[10] is electrically connected to the other terminal of the capacitor 20[3], the terminal 116, and a drain of the transistor 10[11].

A source of the transistor 10[9] and a source of the transistor 10[11] are electrically connected to the wiring 132.

Note that the drain of the transistor 10[1], the drain of the transistor 10[3], the drain of the transistor 10[5], and the gate of the transistor 10[7] may be individually electrically connected to different wirings. The source of the transistor 10[6], the source of the transistor 10[9], and the source of the transistor 10[11] may be individually electrically connected to different wirings.

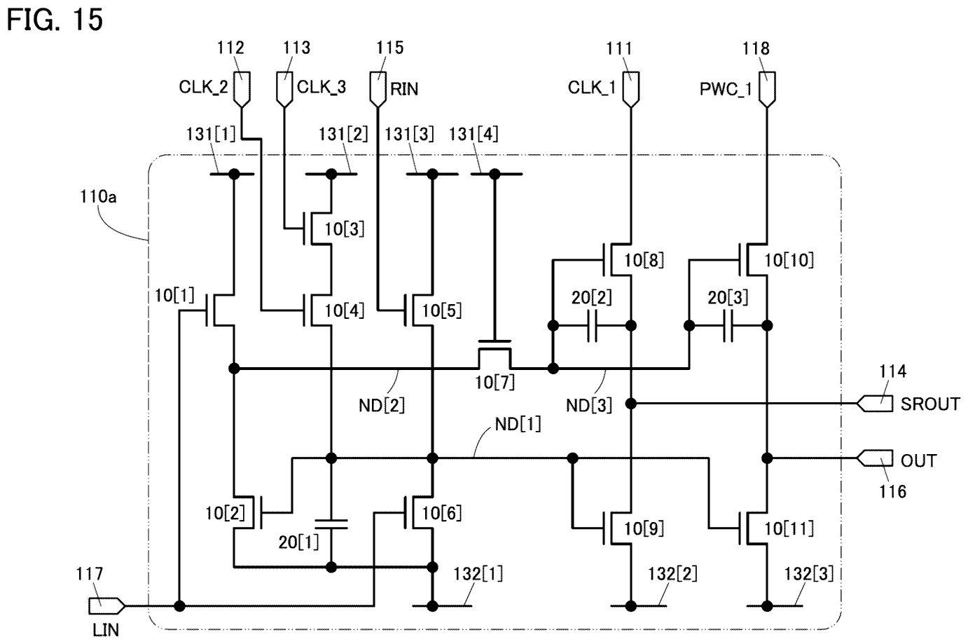

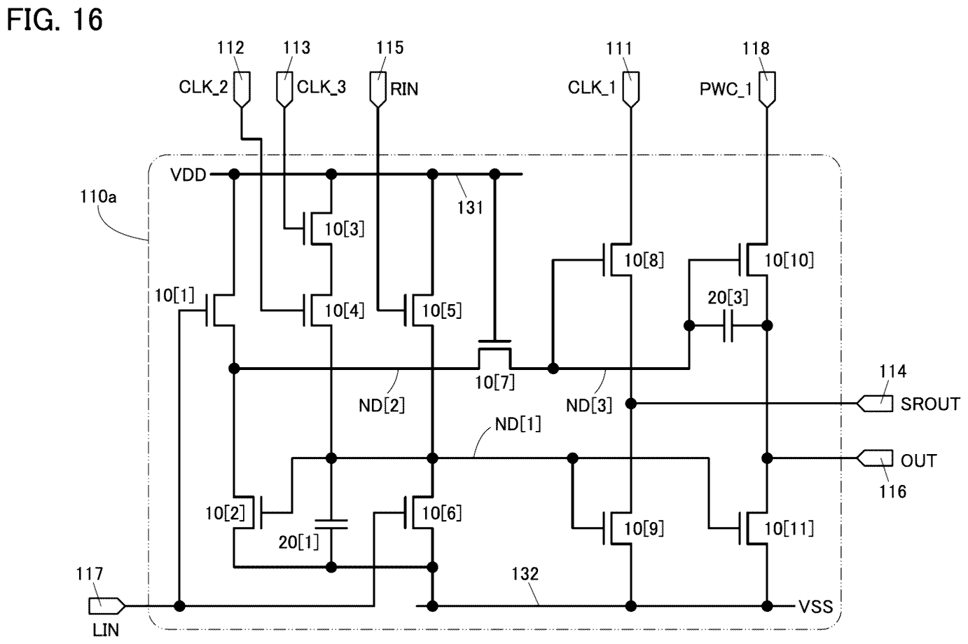

For example, as illustrated in FIG. 15, the drain of the transistor 10[1] may be electrically connected to a wiring 131[1], the drain of the transistor 10[3] may be electrically connected to a wiring 131[2], the drain of the transistor 10[5] may be electrically connected to a wiring 131[3], and the gate of the transistor 10[7] may be electrically connected to a wiring 131[4]. The source of the transistor 10[6] may be electrically connected to a wiring 132[1], the source of the transistor 10[9] may be electrically connected to a wiring 132[2], and the source of the transistor 10[11] may be electrically connected to a wiring 132[3]. Note that in the case where the capacitor 20[3] can have a sufficient capacitance, the formation of the capacitor 20[2] may be omitted as illustrated in FIG. 16.

A signal RIN is supplied to the terminal 115, a signal LIN is supplied to the terminal 117, the signal SROUT is supplied to the terminal 114, and the signal OUT is supplied to the terminal 116. In the signal output circuit 110a in the first stage, the signal CLK_1 is supplied to the terminal 111, the signal CLK_2 is supplied to the terminal 112, the signal CLK_3 is supplied to the terminal 113, and the signal PWC_1 is supplied to the terminal 118.

Note that in the signal output circuit 110a in the second stage, the signal CLK_2 is supplied to the terminal 111, the signal CLK_3 is supplied to the terminal 112, the signal CLK_4 is supplied to the terminal 113, and the signal PWC_2 is supplied to the terminal 118.

### Structural Example of Transistor

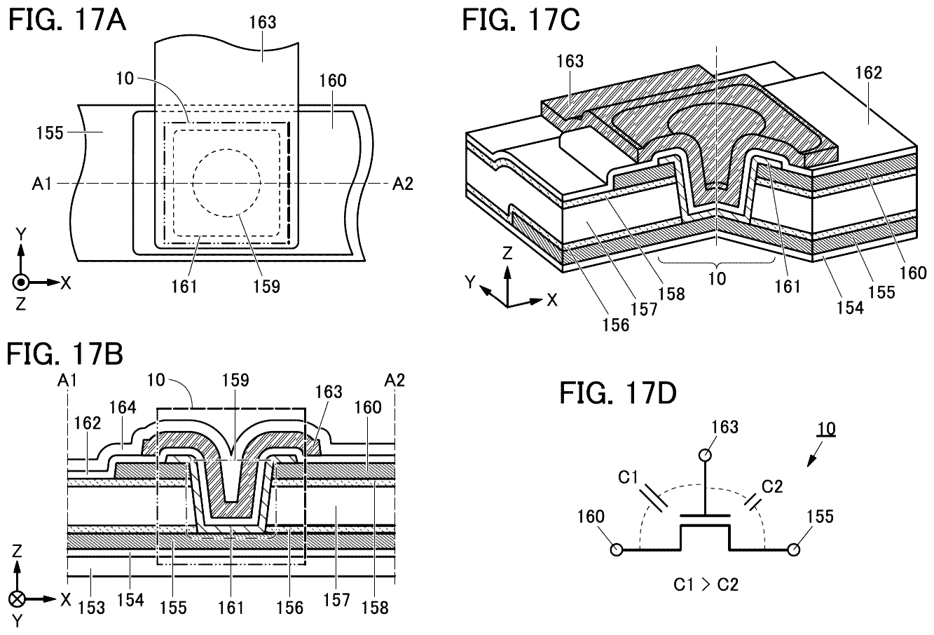

A structural example of a transistor that can be used as the transistor 10 is described here. FIG. 17A is a plan view of the transistor 10. FIG. 17B is a cross-sectional view of a portion indicated by the dashed-dotted line A1-A2 in FIG. 17A. FIG. 17C is a perspective view of the transistor 10 part of which is cut out. FIG. 17D is an equivalent circuit diagram of the transistor 10. For easy understanding of the structure of the transistor 10, some components of the transistor 10 are not illustrated in FIG. 17A or FIG. 17C. For example, an insulating layer 164 or the like illustrated in FIG. 17B is not illustrated in FIG. 17A or FIG. 17C.

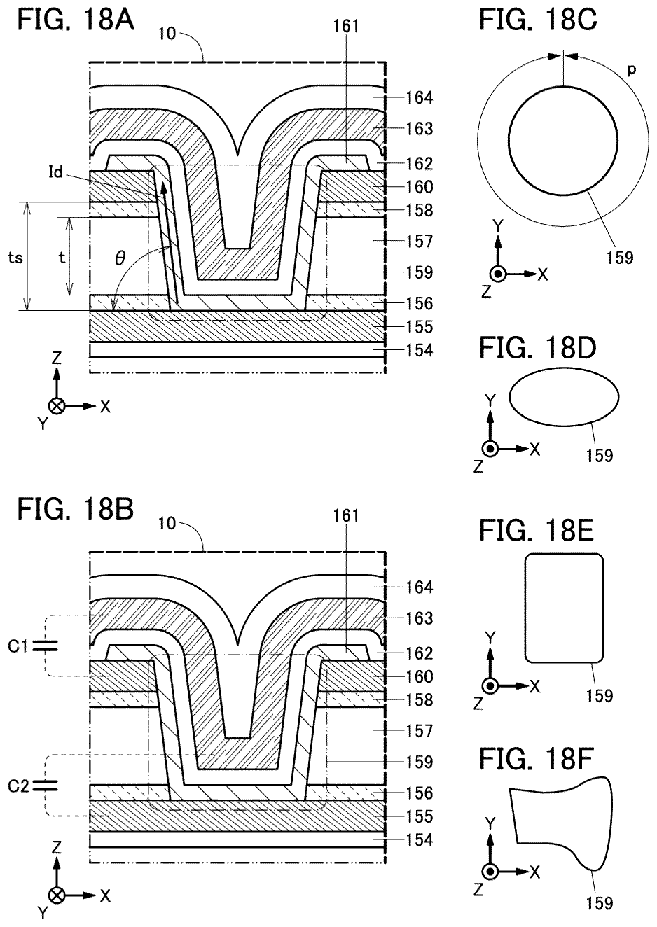

FIG. 18A and FIG. 18B are enlarged views of the transistor 10 illustrated in FIG. 17B. FIG. 18C is a view of an opening 159 seen from the Z direction.

The transistor 10 includes an insulating layer 154 over a substrate 153 and a conductive layer 155 over the insulating layer 154. An insulating layer 156 is provided over the conductive layer 155, an insulating layer 157 is provided over the insulating layer 156, and an insulating layer 158 is provided over the insulating layer 157. A conductive layer 160 is provided over the insulating layer 158.

In a region overlapping with part of the conductive layer 155, the opening 159 is provided in the conductive layer 160, the insulating layer 158, the insulating layer 157, and the insulating layer 156 (see FIG. 17B and FIG. 18A). A semiconductor layer 161 is provided in the opening 159. The semiconductor layer 161 includes a region overlapping with a bottom portion of the opening 159 and a region overlapping with a side surface of the opening 159. The semiconductor layer 161 includes a region in contact with a side surface of the insulating layer 158, a region in contact with a side surface of the insulating layer 157, and a region in contact with a side surface of the insulating layer 156. Part of the semiconductor layer 161 is electrically connected to the conductive layer 160, and the other part of the semiconductor layer 161 is electrically connected to the conductive layer 155.

An insulating layer 162 is provided over the insulating layer 158, the conductive layer 160, and the semiconductor layer 161, and a conductive layer 163 is provided over the insulating layer 162. An insulating layer 164 is provided over the insulating layer 162 and the conductive layer 163. The insulating layer 162 includes a region overlapping with the side surface of the opening 159 with the semiconductor layer 161 therebetween. The conductive layer 163 is provided to cover the semiconductor layer 161. Thus, the conductive layer 163 includes a region extending beyond an end portion of the semiconductor layer 161. The conductive layer 163 includes also a region overlapping with the side surface of the opening 159 with the insulating layer 162 and the semiconductor layer 161 therebetween.

The conductive layer 155 includes a region functioning as one of a source electrode and a drain electrode of the transistor 10. The conductive layer 160 includes a region functioning as the other of the source electrode and the drain electrode of the transistor 10. For example, in the case where the conductive layer 155 functions as the drain electrode of the transistor 10, the conductive layer 160 functions as the source electrode of the transistor 10.

The semiconductor layer 161 includes a region functioning as a semiconductor layer of the transistor 10 where a channel is formed; the insulating layer 162 includes a region functioning as a gate insulating layer; and the conductive layer 163 includes a region functioning as a gate electrode. The transistor 10 is provided in a region including the opening 159.

In the transistor 10, the source electrode and the drain electrode are placed in the Z direction. Thus, the source and the drain of the transistor 10 are placed in different positions in the Z direction. For example, with respect to the top surface of the substrate 153, the source and the drain of the transistor 10 are placed at different distances from the top surface of the substrate 153 serving as the reference. Such a transistor is also referred to as a “vertical-channel transistor”, a “vertical transistor”, or a “VFET (Vertical Field Effect Transistor)”. In the vertical-channel transistor, a Z-direction (vertical-direction) component is included in the direction in which Id flows. For example, in the transistor 10 which is a vertical-channel transistor, the angle θ (see FIG. 18A) between the direction in which Id flows and a surface on which the semiconductor layer 161 over the conductive layer 155 is formed is larger than or equal to 5° and smaller than or equal to 110°, larger than or equal to 10° and smaller than or equal to 90°, larger than or equal to 30° and smaller than or equal to 90°, or larger than or equal to 60° and smaller than or equal to 90° when a cross section passing through the center (or center of gravity) of the opening 159 seen from the Z direction is seen from the X direction or the Y direction.

As described above, the semiconductor layer 161 includes the region in contact with the side surface of the insulating layer 157. Thus, Id flows along the side surface of the insulating layer 157. Thus, the angle θ between the direction in which Id flows and the surface on which the semiconductor layer 161 over the conductive layer 155 is formed can be rephrased as the angle θ between the side surface of the insulating layer 157 and the surface on which the semiconductor layer 161 over the conductive layer 155 is formed.

Since the source electrode and the drain electrode of a vertical-channel transistor are placed in the Z direction, the area occupied by the transistor can be reduced. With the use of the vertical-channel transistor for a semiconductor device, the area occupied by the semiconductor device can be significantly reduced.

Here, examples of materials that can be used for the transistor 10 or the semiconductor device of one embodiment of the present invention are described.

### Substrate

There is no particular limitation on a material used for the substrate 153 and a substrate 148 and a substrate 152 to be described later. The material can be determined in accordance with the purpose in consideration of whether it has a light-transmitting property, heat resistance high enough to withstand heat treatment, or the like. For example, an insulating substrate such as a glass substrate of barium borosilicate glass, aluminoborosilicate glass, or the like, a ceramic substrate, a quartz substrate, or a sapphire substrate can be used. Alternatively, a semiconductor substrate, a flexible substrate, a laminate film, a base film, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. The semiconductor substrate may be a single crystal semiconductor or a polycrystalline semiconductor.

When the transistor 10 or the like of one embodiment of the present invention is used for a display apparatus, a large-sized glass substrate of the 6th generation (1500 mm×1850 mm), the 7th generation (1870 mm×2200 mm), the 8th generation (2200 mm×2400 mm), the 9th generation (2400 mm×2800 mm), or the 10th generation (2950 mm×3400 mm), for example, can be used. Thus, a large-sized display apparatus can be manufactured. With the increase in substrate size, a larger number of display apparatuses can be produced from one substrate, which can reduce production cost.

As the materials of the flexible substrate, the laminate film, the base film, and the like, for example, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide imide, polyurethane, polyvinyl chloride, polyvinylidene chloride, polypropylene, polytetrafluoroethylene (PTFE), an ABS resin, cellulose nanofiber, or the like can be used.

When the above-described material is used for the substrate, a lightweight semiconductor device including the transistor 10 can be provided. Furthermore, when the above-described material is used for the substrate, a shock-resistant semiconductor device can be provided. Moreover, when the above-described material is used for the substrate, a semiconductor device that is less likely to be broken can be provided.

The flexible substrate used as the substrate preferably has a lower coefficient of linear expansion because deformation due to an environment is inhibited. For the flexible substrate used as the substrate, for example, a material whose coefficient of linear expansion is lower than or equal to 1×10⁻³/K, lower than or equal to 5×10⁻⁵/K, or lower than or equal to 1×10⁻⁵/K is used. In particular, aramid is suitable for the flexible substrate because of its low coefficient of linear expansion.

### Conductive Layer

As a conductive material used for not only the gate electrode, the source electrode, and the drain electrode of the transistor 10 but also conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like; an alloy containing the above metal element as a component; an alloy containing the above metal elements in combination; or the like can be used. Furthermore, a semiconductor typified by poly crystalline silicon containing an impurity element such as phosphorus, or silicide such as nickel silicide may be used. There is no particular limitation on the formation method of the conductive material, and a variety of formation methods such as an evaporation method, an atomic layer deposition (ALD) method, a chemical vapor deposition (CVD) method, a sputtering method, and a spin coating method can be employed.

A Cu-X alloy (X is Mn, Ni, Cr, Fe, Co, Mo, Ta, or Ti) may be used as the conductive material. A layer formed using a Cu-X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added, can be used. Furthermore, a conductive material containing nitrogen, such as titanium nitride, tantalum nitride, or tungsten nitride, can be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above-described conductive materials may be stacked and used. The conductive layer may have a stacked-layer structure in which a material containing the above-described metal element and a conductive material containing oxygen are combined, for example. The conductive layer can also have a stacked-layer structure combining a material containing the above-described metal element and a conductive material containing nitrogen. Alternatively, a stacked-layer structure in which a material containing the above-described metal element, a conductive material containing oxygen, and a conductive material containing nitrogen are combined may be used.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

### Insulating Layer

For each of the insulating layers, a single layer or a stack layer of insulating materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used. Furthermore, two or more of an oxide material, a nitride material, an oxynitride material, and a nitride oxide material may be used.

There is no particular limitation on the formation method of the insulating material, and a variety of formation methods such as an evaporation method, an ALD method, a CVD method, a sputtering method, and a spin coating method can be employed.

Note that in this specification and the like, a nitride oxide refers to a material that contains more nitrogen than oxygen. An oxynitride refers to a material that contains more oxygen than nitrogen. Note that the content of each element can be measured by Rutherford backscattering spectrometry (RBS), for example.

For example, it is preferable that the insulating layer 154 and the insulating layer 164 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of the insulating material through which impurities are less likely to pass include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities are less likely to pass is used for the insulating layer 154, impurity diffusion from the substrate 153 side can be inhibited, and the reliability of the transistor 10 can be improved. That is, the reliability of a semiconductor device including the transistor 10 can be improved. When the insulating material through which impurities are less likely to pass is used for the insulating layer 164, impurity diffusion from above the insulating layer 164 can be inhibited, and the reliability of the transistor 10 can be improved. That is, the reliability of a semiconductor device including the transistor 10 can be improved.

As the insulating layer, an insulating layer that can function as a planarization layer may be used. Examples of materials of the insulating layer that functions as a planarization layer include an acrylic resin, polyimide, an epoxy resin, polyamide, polyimide amide, a siloxane resin, a benzocyclobutene resin, a phenol resin, and precursors of these resins. Other than the above-described organic materials, it is also possible to use a low-dielectric constant material (a low-k material), a siloxane resin, PSG (phosphosilicate glass), BPSG (borophosphosilicate glass), or the like. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. In addition, the organic group may include a fluoro group.

A surface of the insulating layer or the like may be subjected to CMP treatment. By the CMP treatment, unevenness of a surface of the insulating layer or the like can be reduced, and coverage with an insulating layer and a conductive layer that are formed later can be increased.

### Semiconductor Layer

For the semiconductor layer 161, a single crystal semiconductor, a polycrystalline semiconductor, a microcrystalline semiconductor, an amorphous semiconductor, or the like can be used alone or in combination. As a semiconductor material, a semiconductor material having a band gap (a semiconductor material that is not a zero-gap semiconductor) such as silicon or germanium can be used, for example. For example, a single element semiconductor, a compound semiconductor, or a layered substance (also referred to as an atomic layer substance, a two-dimensional material, or the like) is preferably used as a semiconductor material. As the compound semiconductor, an organic substance having semiconductor characteristics or a metal oxide having semiconductor characteristics (also referred to as an oxide semiconductor) can be used. Note that these semiconductor materials may contain an impurity as a dopant.

For example, single crystal silicon, polycrystalline silicon, microcrystalline silicon, or amorphous silicon may be used for the semiconductor layer 161. As the polycrystalline silicon, low-temperature polysilicon (LTPS) may be used, for example.

The transistor using amorphous silicon for the semiconductor layer 161 can be formed over a large-sized glass substrate, and can be manufactured at low cost. A transistor using polycrystalline silicon for the semiconductor layer 161 has high field-effect mobility and can operate at high speed. The transistor using microcrystalline silicon for the semiconductor layer 161 has higher field-effect mobility and can operate at higher speed than the transistor using amorphous silicon.

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

The semiconductor layer 161 may contain a layered substance functioning as a semiconductor. The layered substance is a general term for a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

An oxide semiconductor has a band gap of 2 eV or more; thus, a transistor using an oxide semiconductor, which is a kind of metal oxide, for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has a small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the semiconductor device including the OS transistor can operate stably and have high reliability even in a high-temperature environment.

Note that an OS transistor is preferably used as the transistor 10 in this embodiment and the like. Since an OS transistor has a high withstand voltage between the source and the drain, the channel length can be shortened. Thus, the on-state current can be increased. An OS transistor is suitably used as a vertical-channel transistor.

The channel length can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide, also referred to as AZO), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), and an indium gallium aluminum zinc oxide (In—Ga—Al—Zn oxide, also referred to as IGAZO or IAGZO) can be used. Alternatively, an indium tin oxide containing silicon, a gallium tin oxide (Ga—Sn oxide), an aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium or in addition to indium, one or more kinds of metal elements with larger period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of the metal elements among the main constituent elements contained in the metal oxide, the metal oxide has high crystallinity, so that diffusion of impurities in the metal oxide can be inhibited. Consequently, a change in electrical characteristics of the transistor is suppressed, and the reliability of the transistor can be improved.

By increasing the proportion of the element M atoms in the total number of atoms of the metal elements among the main constituent elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor depend on the composition of the metal oxide used for the semiconductor layer. Therefore, by changing the composition of the metal oxide in accordance with the electrical characteristics and reliability required for the transistor, a semiconductor device having both good electrical characteristics and high reliability can be obtained.

In the case of using In—Zn oxide for the semiconductor layer of the OS transistor, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof.

In the case of using In—Sn oxide for the semiconductor layer of the OS transistor, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof.

In the case of using In—Sn—Zn oxide for the semiconductor layer of the OS transistor, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or the neighborhood thereof.

In the case of using In—Al—Zn oxide for the semiconductor layer of the OS transistor, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn =5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, or the neighborhood thereof.

In the case of using In—Ga—Zn oxide for the semiconductor layer of the OS transistor, a metal oxide in which the proportion of the number of indium atoms in the number of atoms of the metal elements is higher than the proportion of the number of gallium atoms can be used. It is further preferable to use a metal oxide in which the atomic proportion of zinc is higher than the atomic proportion of gallium. For example, it is possible to use a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the neighborhood thereof.

In the case of using In—M—Zn oxide for the semiconductor layer of the OS transistor, a metal oxide in which the proportion of the number of indium atoms in the number of atoms of the metal elements is higher than the proportion of the number of element M atoms can be used. It is further preferable to use a metal oxide in which the atomic proportion of zinc is higher than the atomic proportion of the element M. For example, it is possible to use a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio of indium to the element M to zinc is preferably within the ranges given above.

It is preferable to use a metal oxide in which the proportion of the number of indium atoms in the total number of atoms of the metal elements among the main constituent elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, in the case of using In—M—Zn oxide for the semiconductor layer, the proportion of the number of indium atoms in the sum of the numbers of atoms of indium, the element M, and zinc is preferably within the ranges given above.

As described above, when the proportion of the number of indium atoms in the total number of atoms of the metal elements among the main constituent elements contained in the metal oxide is increased, the field-effect mobility of the transistor can be increased. With the use of such a transistor, a circuit capable of high-speed operation can be obtained. Furthermore, the area occupied by the circuit can be reduced. The application of the transistor to a large-sized display apparatus or a high-resolution display apparatus can reduce signal delay in wirings and reduce display unevenness even if the number of wirings is increased, for example. In addition, since the area occupied by the circuit can be reduced, the bezel of the display apparatus can be narrowed.

For analysis of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an ALD method is suitable for forming the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

With use of a metal oxide that does not contain gallium or has low gallium content percentage in the semiconductor layer, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be obtained.

One of the factors in change in the threshold voltage in the PBTS test is a defect state at the interface between a semiconductor layer and a gate insulating layer or in the vicinity of the interface. As the density of defect states increases, degradation in the PBTS test becomes more significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, carrier (here, electron) trap sites are probably generated easily. This might cause the change in the threshold voltage when a positive potential is supplied to the gate and carriers are trapped at the interface between the semiconductor layer and the gate insulating layer.

Specifically, in the case where an In—Ga—Zn oxide is used for the semiconductor layer, a metal oxide in which the atomic proportion of indium is higher than that of gallium can be used as the semiconductor layer. It is further preferable to use a metal oxide in which the atomic proportion of zinc is higher than the atomic proportion of gallium. In other words, a metal oxide in which the atomic ratios of metal elements satisfy In>Ga and Zn>Ga is preferably used as the semiconductor layer.

For example, it is possible to use, for the semiconductor layer of the OS transistor, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the neighborhood thereof.

It is preferable to use, for the semiconductor layer of the OS transistor, a metal oxide in which the proportion of the number of gallium atoms in the number of atoms of the metal elements contained is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the proportion of the number of gallium atoms in the number of atoms of the metal elements in the semiconductor layer enables the transistor to be highly resistant to the PBTS test. Note that an oxygen vacancy (V_{O}) is less likely to be generated in the metal oxide when the metal oxide contains gallium.

A metal oxide not containing gallium may be used for the semiconductor layer of the OS transistor. For example, an In—Zn oxide can be used for the semiconductor layer. In that case, when the proportion of the number of indium atoms in the number of atoms of the metal elements contained in the metal oxide is increased, the field-effect mobility of the transistor can be increased. By contrast, when the proportion of the number of zinc atoms in the number of atoms of the metal elements contained in the metal oxide is increased, the metal oxide has high crystallinity; thus, a change in the electrical characteristics of the transistor can be inhibited and the reliability can be improved. Alternatively, a metal oxide that contains neither gallium nor zinc, such as indium oxide, can be used for the semiconductor layer. The use of a metal oxide not containing gallium can make a change in the threshold voltage particularly in the PBTS test extremely small.

For example, an oxide containing indium and zinc can be used for the semiconductor layer. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer. Furthermore, a metal oxide in which the atomic proportion of zinc is higher than the atomic proportion of the element M is preferably used.

The use of a metal oxide having a low content percentage of the element M for the semiconductor layer enables the transistor to be highly reliable against positive bias application. The use of the transistor as a transistor that is required to have high reliability against positive bias application enables a semiconductor device to have high reliability.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in an NBTIS test, for example.

The high content percentage of the element M in the metal oxide used for the semiconductor layer enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, still further preferably greater than or equal to 3.0 eV, yet further preferably greater than or equal to 3.2 eV, yet still further preferably greater than or equal to 3.3 eV, yet still further preferably greater than or equal to 3.4 eV, yet still further preferably greater than or equal to 3.5 eV.

For example, it is possible to use, for the semiconductor layer, a metal oxide in which the atomic ratio of the metal elements is In:M:Zn=1:1:1, In:M:Zn=1:1:1.2, In:M:Zn=1:3:2, In:M:Zn=1:3:3, In:M:Zn=1:3:4, or the neighborhood thereof.

For the semiconductor layer, it is particularly preferable to use a metal oxide in which the proportion of the number of element M atoms in the number of atoms of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet further preferably higher than or equal to 50 atomic % and lower than or equal to 60 atomic %.

In the case where In—Ga—Zn oxide is used for the semiconductor layer, a metal oxide in which the proportion of the number of indium atoms in the number of atoms of the metal elements is lower than or equal to the proportion of the number of gallium atoms can be used. For example, it is possible to use a metal oxide in which the atomic ratio of the metal elements is In:Ga:Zn=1:1:1, In:Ga:Zn=1:1:1.2, In:Ga:Zn=1:3:2, In:Ga:Zn=1:3:3, In:Ga:Zn=1:3:4, or the neighborhood thereof.

For the semiconductor layer, it is particularly preferable to use a metal oxide in which the proportion of the number of gallium atoms in the number of atoms of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, still further preferably higher than or equal to 40 atomic % and lower than or equal to 60 atomic %, yet further preferably higher than or equal to 50 atomic % and lower than or equal to 60 atomic %.

The use of a metal oxide having a high content percentage of the element M for the semiconductor layer enables the transistor to be highly reliable against light. The use of the transistor as a transistor that is required to have high reliability against light enables a semiconductor device to have high reliability.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of two layers of a first metal oxide layer having a composition of In:M:Zn=1:3:4 [atomic ratio] or the neighborhood thereof and a second metal oxide layer having a composition of In:M:Zn=1:1:1 [atomic ratio] or the neighborhood thereof and overlapping with the first metal oxide layer may be employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or the neighborhood thereof and a second metal oxide layer having a composition of In:Zn=4:1 [atomic ratio] or the neighborhood thereof and being provided over the first metal oxide layer may be employed.

For example, a stacked-layer structure of three layers in which a semiconductor layer having an atomic ratio of metal elements of In:Ga:Zn=1:1:1 is the first layer, a semiconductor layer having an atomic ratio of metal elements of In:Zn=4:1 is the second layer, and a semiconductor layer having an atomic ratio of metal elements of In:Ga:Zn=1:1:1 is the third layer may be employed. Note that the band gaps of the first and third semiconductor layers are preferably larger than the band gap of the second semiconductor layer. With this structure, the main current path can be the second layer, so that what is called a buried channel structure can be obtained.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which enables the display apparatus to have high reliability.

The higher the crystallinity of the metal oxide layer used as the semiconductor layer is, the lower the density of defect states in the semiconductor layer can be. By contrast, the use of a metal oxide layer having low crystallinity enables a transistor to allow the flow of a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (hereinafter, also referred to as oxygen flow rate ratio) used in formation becomes higher.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with the use of the same sputtering target and different oxygen flow rate ratios, a stacked-layer structure of two or more metal oxide layers having different crystallinities can be formed. Note that the two or more metal oxide layers included in the semiconductor layer may have different compositions.

The channel length L of the transistor 10 described in this embodiment is determined by the thickness of the insulating layer provided between the conductive layer 160 and the conductive layer 155. Thus, a transistor with a short channel length L can be manufactured with high accuracy. Furthermore, variations in characteristics among the transistors 10 are also reduced. Accordingly, the operation of the semiconductor device including the transistor 10 can be stabilized and the reliability thereof can be improved. When the variations in characteristics are reduced, the circuit design flexibility of the semiconductor device is increased and the operation voltage can be reduced. Thus, the power consumption of the semiconductor device can be reduced.

In the case where an oxide semiconductor is used for the semiconductor layer 161, a material containing hydrogen is preferably used for the insulating layer 156 and the insulating layer 158. When the insulating layer containing hydrogen is in contact with the oxide semiconductor, a region of the oxide semiconductor that is in contact with the insulating layer becomes n-type and can function as a source region or a drain region. For this insulating layer, a material containing silicon, nitrogen, and hydrogen is used, for example. Specifically, silicon nitride containing hydrogen, silicon nitride oxide containing hydrogen, or the like is used.

In the case where an oxide semiconductor is used for the semiconductor layer 161, a conductive material that makes the oxide semiconductor have n-type conductivity is preferably used for the conductive layer 155 in contact with the semiconductor layer 161 and the conductive layer 160 in contact with the semiconductor layer 161. For example, a conductive material containing nitrogen may be used. For example, a conductive material containing nitrogen and titanium or tantalum is used. Another conductive material may be provided so as to overlap with the conductive material containing nitrogen.

In contrast, for the insulating layer 157, a material which contains oxygen and in which the amount of hydrogen is reduced is preferably used. For example, a material containing silicon and oxygen is used. Specifically, silicon oxide, silicon oxynitride, or the like is used. Since hydrogen is an impurity element in an oxide semiconductor, when the semiconductor layer 161 which is an oxide semiconductor and the insulating layer 157 in which the amount of hydrogen is reduced are in contact with each other, the semiconductor layer 161 is less likely to become n-type. Furthermore, when the semiconductor layer 161 which is an oxide semiconductor and the insulating layer 157 containing oxygen are in contact with each other, oxygen vacancies in the semiconductor layer 161 are reduced and the transistor 10 has stable characteristics, improving the reliability.

When an oxide semiconductor is used for the semiconductor layer 161, the insulating layer 157 preferably contains excess oxygen. In this specification and the like, “excess oxygen” refers to oxygen that is released by heating. In the case where a material containing excess oxygen is used for the insulating layer 157, a material through which oxygen is less likely to pass is preferably used for the insulating layer 156 and the insulating layer 158. Examples of the material through which oxygen is less likely to pass include a nitride of silicon and an oxide containing aluminum and/or hafnium. With the use of the material through which oxygen is less likely to pass for the insulating layer 156 and the insulating layer 158, excess oxygen contained in the insulating layer 157 is less likely to be released to a lower layer or an upper layer. Thus, sufficient oxygen can be supplied to the oxide semiconductor. For example, an insulating layer containing silicon and oxygen (the insulating layer 157) can be provided between two insulating layers containing silicon and nitrogen (the insulating layer 156 and the insulating layer 158).

In the case where an oxide semiconductor is used for the semiconductor layer 161 and a material containing hydrogen is used for the insulating layer 156 and the insulating layer 158, a region of the semiconductor layer 161 in contact with the conductive layer 160 and a region of the semiconductor layer 161 in contact with the insulating layer 158 serve as one of a source (a source region) and a drain (a drain region). A region of the semiconductor layer 161 in contact with the conductive layer 155 and a region of the semiconductor layer 161 in contact with the insulating layer 156 serve as the other of the source (the source region) and the drain (the drain region). Thus, a thickness t of the insulating layer 157 determines the channel length L of the transistor 10 (see FIG. 18A).

A material that contains no hydrogen or an extremely small amount of hydrogen may be used for the insulating layer 156 and the insulating layer 158. For example, silicon nitride that contains an extremely small amount of hydrogen or silicon nitride oxide that contains an extremely small amount of hydrogen may be used. In that case, the region of the semiconductor layer 161 in contact with the insulating layer 156 and the region of the semiconductor layer 161 in contact with the insulating layer 158 do not become n-type. Thus, the region of the semiconductor layer 161 in contact with the conductive layer 160 serves as one of a source (a source region) and a drain (a drain region). The region of the semiconductor layer 161 in contact with the conductive layer 155 serves as the other of the source (the source region) and the drain (the drain region). In that case, a thickness ts obtained by combining the thicknesses of the insulating layer 156, the insulating layer 157, and the insulating layer 158 corresponds to the channel length L of the transistor 10 (see FIG. 18A).

The channel length L can be controlled by adjusting the thicknesses of the insulating layer 156, the insulating layer 157, and the insulating layer 158. The channel length L can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

Although an example in which three insulating layers (the insulating layer 156, the insulating layer 157, and the insulating layer 158) are provided between the conductive layer 155 and the conductive layer 160 is shown in this embodiment, the number of insulating layers between the conductive layer 155 and the conductive layer 160 is not limited thereto. The number of insulating layers between the conductive layer 155 and the conductive layer 160 can be one, two, four, or more.

Since the semiconductor layer 161 is provided in the opening 159, a length p of the perimeter of the opening 159 corresponds to the channel width W of the transistor 10 (see FIG. 18C). The length p of the perimeter is obtained at a position corresponding to the half (t/2) of the thickness t of the insulating layer 157 or the half (ts/2) of the thickness ts, for example. Note that the length of the perimeter of the opening 159 at an arbitrary position may be regarded as the channel width W as necessary. For example, the length p of the perimeter at the lowermost portion of the opening 159 may be regarded as the channel width W, or the length p of the perimeter at the uppermost portion of the opening 159 may be regarded as the channel width W.

The outline (the planar shape) of the opening 159 seen from the Z direction is illustrated as being circular in FIG. 18C but is not limited to this. For example, the outline of the opening 159 seen from the Z direction can be elliptical (see FIG. 18D) or rectangular (see FIG. 18E). Note that FIG. 18E illustrates a rectangle having rounded corner portions. For example, the outline of the opening 159 seen from the Z direction may have a shape including a straight portion and/or a curved portion (see FIG. 18F).

In the transistor 10 of one embodiment of the present invention, the capacitance value of parasitic capacitance generated between the gate and the source and the capacitance value of parasitic capacitance generated between the gate and the drain are different from each other. Specifically, in a capacitor C1 generated in a region where the conductive layer 160 and the conductive layer 163 overlap with each other over the insulating layer 154 and a capacitor C2 generated in a region where the conductive layer 155 and the conductive layer 163 overlap with each other in the opening 159, the capacitance value of the capacitor Cl is higher than the capacitance value of the capacitor C2 (see FIG. 17D and FIG. 18B).

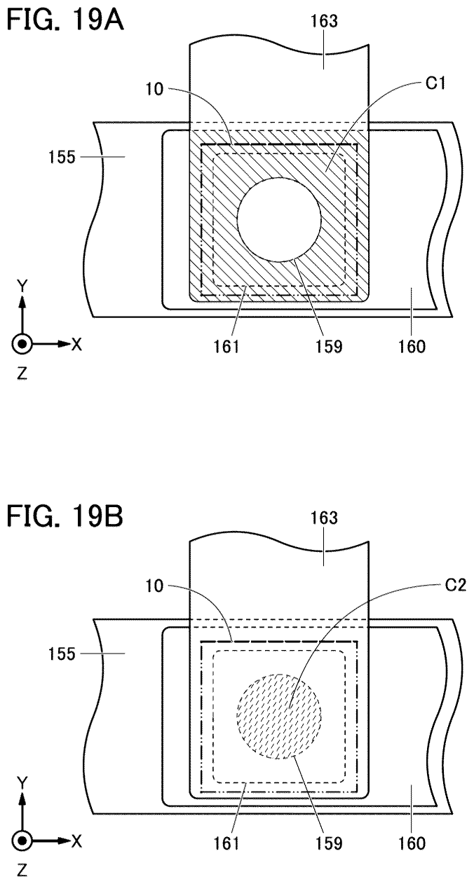

FIG. 19A and FIG. 19B illustrate plan views similar to FIG. 17A. When the transistor 10 of one embodiment of the present invention is seen from the Z direction, the conductive layer 163 overlaps with the conductive layer 160 in the periphery of the opening 159 to surround the opening 159, and overlaps with the conductive layer 160 in the bottom portion of the opening 159.

In FIG. 19A, a region functioning as the capacitor C1 when seen from the Z direction is shown with a hatching pattern. A region where the conductive layer 160 and the conductive layer 163 overlap with each other with the semiconductor layer 161 and the insulating layer 162 interposed therebetween over the insulating layer 154 functions as the capacitor C1 (see FIG. 18B and FIG. 19A). Note that the insulating layer 154 and the insulating layer 162 are not illustrated in FIG. 19A.

In FIG. 19B, a region functioning as the capacitor C2 when seen from the Z direction is shown with a hatching pattern. In the bottom portion of the opening 159, a region where the conductive layer 155 and the conductive layer 163 overlap with each other with the semiconductor layer 161 and the insulating layer 162 interposed therebetween functions as the capacitor C2 (see FIG. 18B and FIG. 19B). Note that the insulating layer 154 and the insulating layer 162 are not illustrated in FIG. 19B.

According to FIG. 19A and FIG. 19B, the region functioning as the capacitor Cl has a larger area than the region functioning as the capacitor C2. When the area of the region functioning as the capacitor C1 is larger than the area of the region functioning as the capacitor C2, the capacitance value of the capacitor Cl is larger than that of the capacitor C2.

When the area where the conductive layer 155 and the conductive layer 163 overlap with each other is changed in order to change the capacitance value of the capacitor C2, the shape of the opening 159 is changed; that is, the length p of the perimeter of the opening 159 is changed. Since the change in the length p of the perimeter directly influences the electrical characteristics of the transistor 10, the capacitance value of the capacitor C2 is difficult to control.

In contrast, the area where the conductive layer 163 and the conductive layer 160 overlap with each other is easy to control and less likely to influence the electrical characteristics of the transistor 10. For example, by increasing the area where the conductive layer 163 and the conductive layer 160 overlap with each other, the capacitance value of the capacitor C1 can be increased.

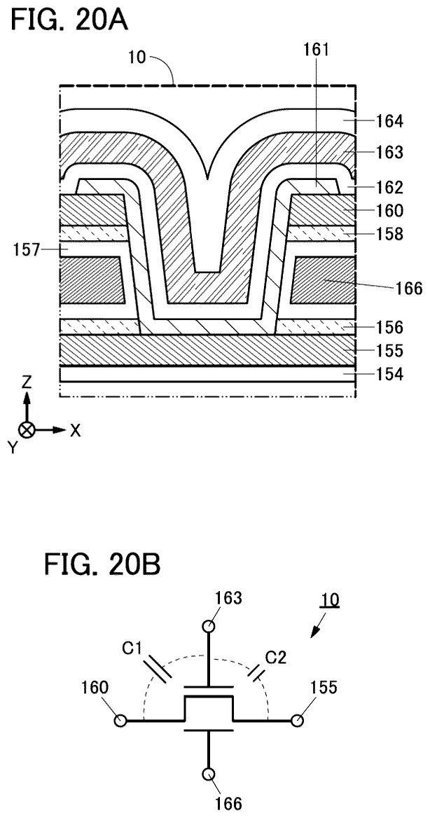

As illustrated in a cross-sectional view in FIG. 20A, a conductive layer 166 which is close to the semiconductor layer 161 may be provided in the insulating layer 157. The conductive layer 166 is provided not to be in contact with the semiconductor layer 161. The conductive layer 166 is preferably provided to surround the semiconductor layer 161. The conductive layer 166 can function as a back gate electrode of the transistor 10 when provided close to the semiconductor layer 161 without being in contact with the semiconductor layer 161. Thus, the transistor 10 illustrated in FIG. 20A functions as a transistor having a back gate (a back gate electrode). Note that FIG. 20B is an equivalent circuit diagram of the transistor 10 illustrated in FIG. 20A.

Here, a back gate electrode is described. In general, a back gate electrode is formed using a conductive layer and positioned so that a channel formation region in a semiconductor layer is sandwiched between the gate electrode and the back gate electrode. Thus, the back gate electrode can function in a manner similar to that of the gate electrode. The potential of the back gate electrode may be equal to the potential of the gate electrode or may be a GND potential or a given potential. When the gate electrode and the back gate electrode are electrically connected to each other, the on-state current of the transistor can be increased. When the potential of the back gate electrode is not equal to and is changed independently of the potential of the gate electrode, the threshold voltage of the transistor can be changed.

In addition, the gate electrode and the back gate electrode are formed using conductive layers and thus each have a function of preventing an electric field generated outside the transistor from affecting the channel formation region in the semiconductor layer (in particular, an electric field blocking function against static electricity and the like). As a result, variations in characteristics among transistors are reduced. Furthermore, degradation of transistor characteristics due to the GBTS test is inhibited. For example, with the back gate electrode, a change in threshold voltage in the GBTS test can be inhibited. The transistor including the back gate electrode has a smaller amount of change in threshold voltage in the GBTS test than a transistor including no back gate electrode.

Note that the GBTS (NBTS and PBTS) test is a kind of accelerated test and can evaluate, in a short time, a change by long-term use (i.e., a change over time) in characteristics of a transistor. In particular, the amount of change in the threshold voltage of the transistor in the GBTS test is an important indicator for examination of the reliability. The smaller the amount of change in the threshold voltage in the GBTS test is, the higher the reliability of the transistor becomes.

In the case where light enters from the back gate electrode side, when the back gate electrode is formed using a light-blocking conductive film, the light can be prevented from entering the semiconductor layer from the back gate electrode side. Similarly, when the gate electrode is formed using a light-blocking conductive film, light can be prevented from entering the semiconductor layer from the gate electrode side. When one or both of the gate electrode and the back gate electrode is/are formed using a light-blocking conductive film, photodegradation of the semiconductor layer can be prevented and degradation in electrical characteristics of the transistor, such as a shift of the threshold voltage, can be prevented.

In addition, the gate electrode and the back gate electrode can block an electric field generated from the drain electrode so that the electric field do not influence the semiconductor layer. Thus, a change in the current onset voltage due to a change in drain voltage can be inhibited. Note that this effect is significant when a potential is supplied to each of the gate electrode and the back gate electrode.

When a plurality of transistors 10 are connected in parallel, an apparent channel width W of the transistor 10 can be increased. A larger channel width W of the transistor 10 leads to a smaller resistance value between the source and the drain in an on state and thus Id in the on state can be increased.

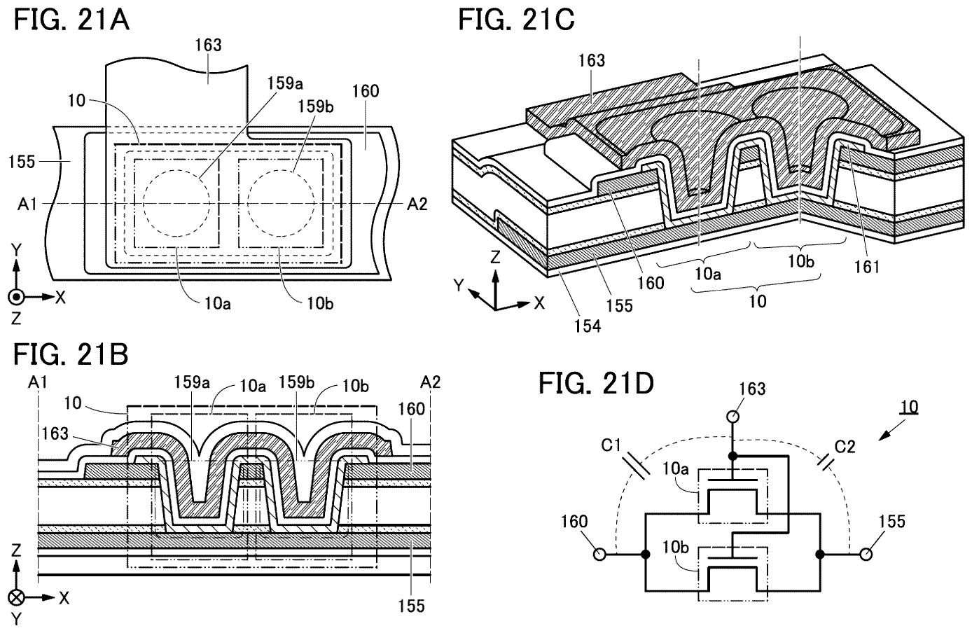

FIG. 21A is a plan view of a transistor 10 including a transistor 10a and a transistor 10b. FIG. 21B is a cross-sectional view of a portion indicated by the dashed-dotted line A1-A2 in FIG. 21A. FIG. 21C is a perspective view of the transistor 10 including the transistor 10a and the transistor 10b part of which is cut out. FIG. 21D is an equivalent circuit diagram of the transistor 10 including the transistor 10a and the transistor 10b. For easy understanding of the structure of the transistor 10, some components of the transistor 10 are not illustrated in FIG. 21A or FIG. 21C.

Each of the transistor 10a and the transistor 10b has a structure similar to that of the transistor 10 described with reference to FIG. 17 and FIG. 18. The transistor 10a is provided in a region including an opening 159a, and the transistor 10b is provided in a region including an opening 159b. The opening 159a and the opening 159b can be formed in a manner similar to that of the opening 159.

A part of the conductive layer 155 functions as one of a source electrode and a drain electrode of the transistor 10a, and another part of the conductive layer 155 functions as one of a source electrode and a drain electrode of the transistor 10b. A part of the conductive layer 160 functions as the other of the source electrode and the drain electrode of the transistor 10a, and another part of the conductive layer 160 functions as the other of the source electrode and the drain electrode of the transistor 10b. A part of the conductive layer 163 functions as a gate electrode of the transistor 10a, and another part of the conductive layer 163 functions as a gate electrode of the transistor 10b.

As illustrated in the equivalent circuit diagram in FIG. 21D, the one of the source and the drain of the transistor 10a and the one of the source and the drain of the transistor 10b are electrically connected to each other, and the other of the source and the drain of the transistor 10a and the other of the source and the drain of the transistor 10b are electrically connected to each other. The gate of the transistor 10a and the gate of the transistor 10b are electrically connected to each other. Thus, the transistor 10a and the transistor 10b switch between on and off states at the same time and function as one transistor 10.

When a plurality of transistors 10 (here, the transistor 10a and the transistor 10b) are connected in series, an apparent channel length L of the transistor 10 can be increased. A larger channel length L leads to better saturation characteristics of the transistor 10.

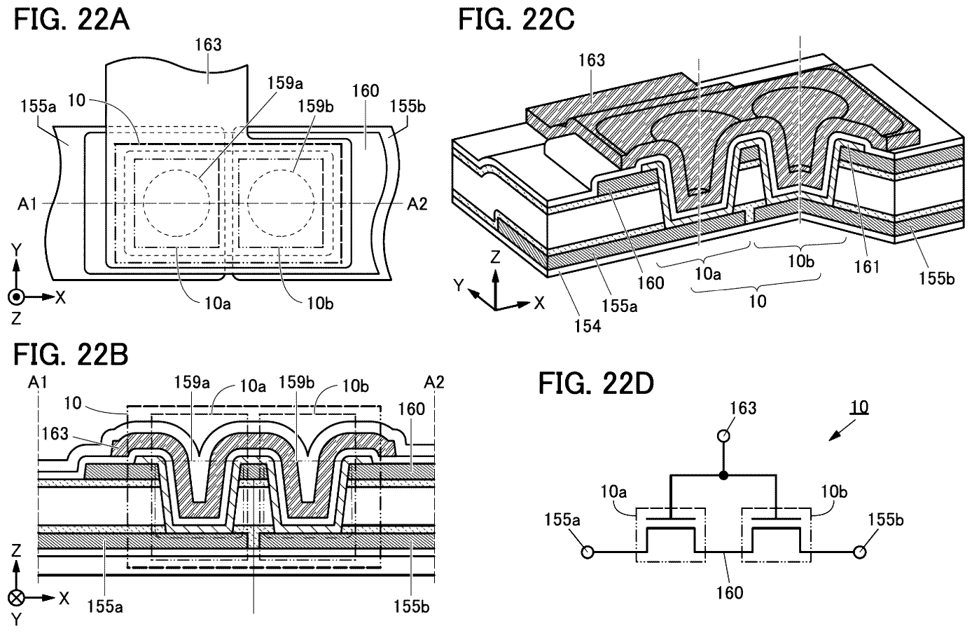

FIG. 22A is a plan view of a transistor 10 including a transistor 10a and a transistor 10b. FIG. 22B is a cross-sectional view of a portion indicated by the dashed-dotted line A1-A2 in FIG. 22A. FIG. 22C is a perspective view of the transistor 10 including the transistor 10a and the transistor 10b part of which is cut out. FIG. 22D is an equivalent circuit diagram of the transistor 10 including the transistor 10a and the transistor 10b. For easy understanding of the structure of the transistor 10, some components of the transistor 10 are not illustrated in FIG. 22A or FIG. 22C.

Each of the transistor 10a and the transistor 10b has a structure similar to that of the transistor 10 described with reference to FIG. 21, but is different in that the conductive layer 155 is divided into a conductive layer 155a and a conductive layer 155b.

The conductive layer 155a functions as one of a source electrode and a drain electrode of the transistor 10a, and a part of the conductive layer 160 functions as the other of the source electrode and the drain electrode of the transistor 10a. Another part of the conductive layer 160 functions as one of a source electrode and a drain electrode of the transistor 10b, and the conductive layer 155b functions as the other of the source electrode and the drain electrode of the transistor 10b. As in the transistor 10 described with reference to FIG. 21, a part of the conductive layer 163 functions as a gate electrode of the transistor 10a, and another part of the conductive layer 163 functions as a gate electrode of the transistor 10b.

In the equivalent circuit diagram in FIG. 22D, the other of the source and the drain of the transistor 10a and the one of the source and the drain of the transistor 10b are electrically connected to each other, and the gate of the transistor 10a and the gate of the transistor 10b are electrically connected to each other. Thus, the transistor 10a and the transistor 10b switch between on and off states at the same time and function as one transistor 10.

### Planar and Cross-Sectional Structural Examples of Signal Output Circuit 110

Next, planar and cross-sectional structural examples of the signal output circuits 110 will be described with reference to drawings. In this embodiment, planar and cross-sectional structural examples of the signal output circuit 110a illustrated in FIG. 14 among the signal output circuits 110 will be described.

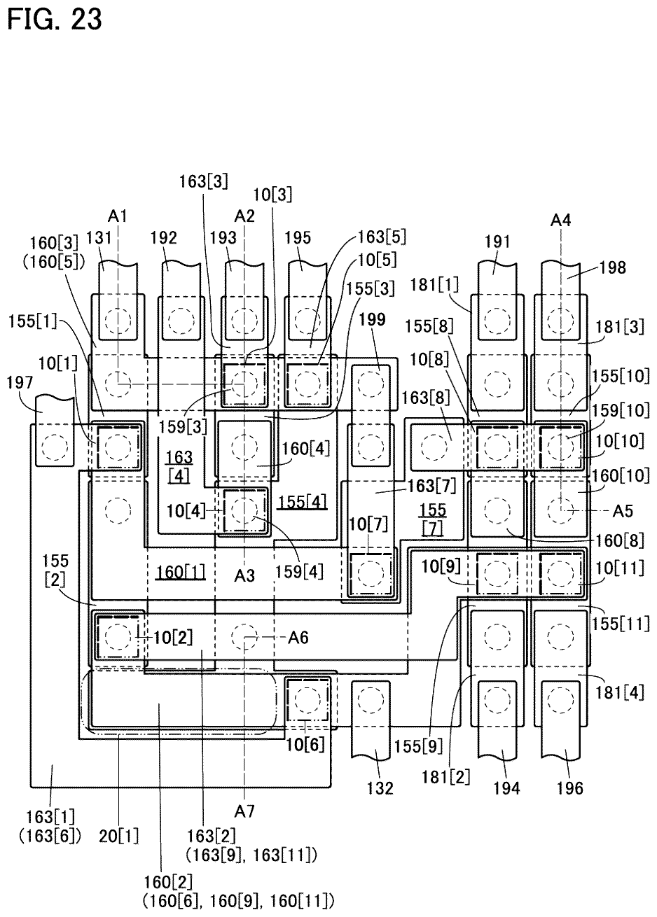

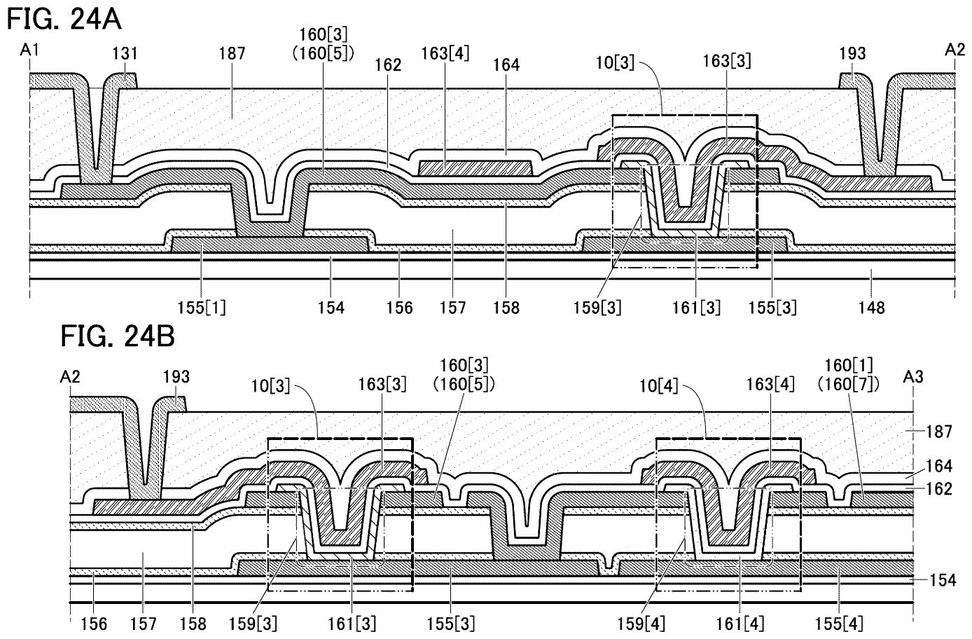

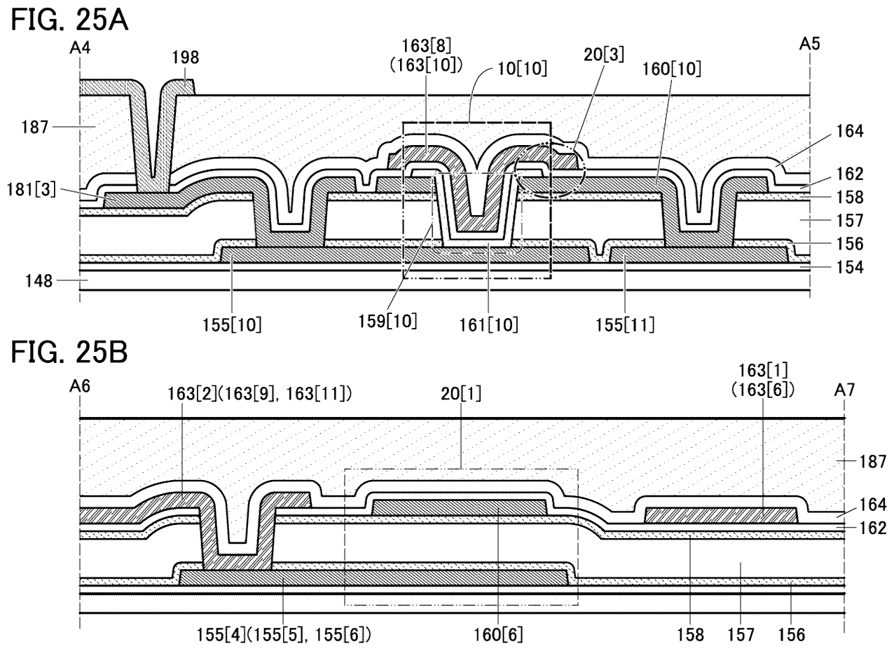

FIG. 23 is a diagram illustrating a planar structural example of the signal output circuit 110a. FIG. 24A is a diagram illustrating a cross-sectional structural example of a portion indicated by the dashed-dotted line along A1-A2 in FIG. 23. FIG. 24B is a diagram illustrating a cross-sectional structural example of a portion indicated by the dashed-dotted line along A2-A3 in FIG. 23. FIG. 25A is a diagram illustrating a cross-sectional structural example of a portion indicated by the dashed-dotted line along A4-A5 in FIG. 23. FIG. 25B is a diagram illustrating a cross-sectional structural example of a portion indicated by the dashed-dotted line along A6-A7 in FIG. 23.

In this embodiment, a structural example in which the above-described VFET is used as the transistor 10 of the signal output circuit 110a is described. The signal output circuit 110a includes the insulating layer 154 over the substrate 148 and the conductive layer 155 (e.g., a conductive layer 155[1] and a conductive layer 155[3] in FIG. 24A, a conductive layer 155[3] and a conductive layer 155[4] in FIG. 24B, and a conductive layer 155[10] and a conductive layer 155[11] in FIG. 25A) over the insulating layer 154.

Note that the stacked-layer structure of the signal output circuit 110a in which the above-described VFET is used as the transistor 10 has a portion in common with the above-described structural example of the transistor 10. Thus, a portion different from the above-described structural example of the transistor 10 will be mainly described here.

In this specification and the like, an identifying reference numeral [1] is sometimes added to a reference numeral for a component related to the transistor 10[1]. For example, the conductive layer 163 functioning as the gate electrode of the transistor 10[1] is sometimes referred to as a conductive layer 163[1]. Note that an identifying reference numeral for any of the plurality of transistors 10 is sometimes added to a reference numeral for a component commonly related to the plurality of transistors 10. For example, the conductive layer 163 functioning as the gate electrode of each of the transistor 10[2], the transistor 10[9], and the transistor 10[11] is sometimes referred to as a conductive layer 163[2].

For example, the opening 159 and the semiconductor layer 161 related to the transistor 10[3] are sometimes referred to as an opening 159[3] and a semiconductor layer 161[3]. For example, the opening 159 and the semiconductor layer 161 related to the transistor 10[4] are sometimes referred to as an opening 159[4] and a semiconductor layer 161[4]. For example, the opening 159 and the semiconductor layer 161 related to the transistor 10[7] are sometimes referred to as an opening 159[7] and a semiconductor layer 161[7]. For example, the opening 159 and the semiconductor layer 161 related to the transistor 10[8] are sometimes referred to as an opening 159[8] and a semiconductor layer 161[8]. For example, the opening 159 and the semiconductor layer 161 related to the transistor 10[10] are sometimes referred to as an opening 159[10] and a semiconductor layer 161[10].

The signal output circuit 110 a includes a conductive layer 181[1] to a conductive layer 181[4] over the insulating layer 158 (see FIG. 23 and FIG. 25A). The conductive layer 181 (the conductive layer 181[1] to the conductive layer 181[4]) can be formed using a material and a method similar to those for the conductive layer 160. The conductive layer 181 can be formed at the same time as the conductive layer 160.

The signal output circuit 110a includes an insulating layer 187 over the insulating layer 164. The insulating layer 187 preferably functions as a planarization layer for reducing a difference in level generated by a transistor, a capacitor, a wiring, or the like formed in a lower layer. An organic insulating film is suitable as a material functioning as a planarization layer. After the insulating layer 187 is formed with an inorganic material or an organic material, planarization treatment using a chemical mechanical polishing (CMP) method or the like may be performed on the insulating layer 187.

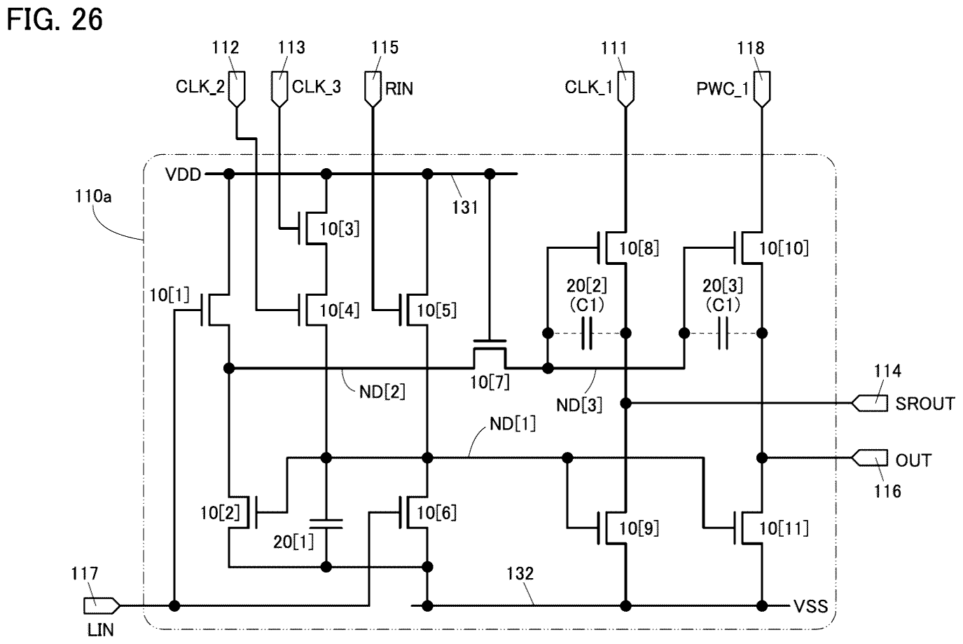

The signal output circuit 110a includes a conductive layer 191 to a conductive layer 199, the wiring 131, and the wiring 132 over the insulating layer 187 (see FIG. 23, FIG. 24A, FIG. 24B, and FIG. 25A). The conductive layer 191 to the conductive layer 199, the wiring 131, and the wiring 132 can be formed using a material and a method similar to those for other conductive layers. The conductive layer 191 functions as the terminal 111 in FIG. 26, the conductive layer 192 functions as the terminal 112 in FIG. 26, the conductive layer 193 functions as the terminal 113 in FIG. 26, the conductive layer 194 functions as the terminal 114 in FIG. 26, the conductive layer 195 functions as the terminal 115 in FIG. 26, the conductive layer 196 functions as the terminal 116 in FIG. 26, the conductive layer 197 functions as the terminal 117 in FIG. 26, and the conductive layer 198 functions as the terminal 118 in FIG. 26.

In the signal output circuit 110a, an opening that penetrates the insulating layer 162, the insulating layer 164, and the insulating layer 187 is provided over each of the conductive layer 160[2], the conductive layer 160[3], the conductive layer 181[1], the conductive layer 181[2], the conductive layer 181[3], and the conductive layer 181[4]. Through the opening provided over the conductive layer 160[2], the wiring 132 and the conductive layer 160[2] are electrically connected to each other. More specifically, the wiring 132 and the conductive layer 160[2] are electrically connected to each other in the bottom portion of the opening provided over the conductive layer 160[2].

Two openings are provided over the conductive layer 160[3]. Through one of the two openings, the wiring 131 and the conductive layer 160[3] are electrically connected to each other. Through the other of the two openings, the conductive layer 199 and the conductive layer 160[3] are electrically connected to each other.

Through the opening provided over the conductive layer 181[1], the conductive layer 191 and the conductive layer 181[1] are electrically connected to each other. Through the opening provided over the conductive layer 181[2], the conductive layer 194 and the conductive layer 181[2] are electrically connected to each other. Through the opening provided over the conductive layer 181[3], the conductive layer 198 and the conductive layer 181[3] are electrically connected to each other. Through the opening provided over the conductive layer 181[4], the conductive layer 196 and the conductive layer 181[4] are electrically connected to each other.

In the signal output circuit 110a, an opening that penetrates the insulating layer 164 and the insulating layer 187 is provided over each of the conductive layer 163[1], the conductive layer 163[3], the conductive layer 163[4], the conductive layer 163[5], and the conductive layer 163[7].

Through the opening provided over the conductive layer 163[1], the conductive layer 197 and the conductive layer 163[1] are electrically connected to each other. Through the opening provided over the conductive layer 163[3], the conductive layer 193 and the conductive layer 163[3] are electrically connected to each other. Through the opening provided over the conductive layer 163[4], the conductive layer 192 and the conductive layer 163[4] are electrically connected to each other. Through the opening provided over the conductive layer 163[5], the conductive layer 195 and the conductive layer 163[5] are electrically connected to each other. Through the opening provided over the conductive layer 163[7], the conductive layer 199 and the conductive layer 163[7] are electrically connected to each other. Note that the conductive layer 160[3] and the conductive layer 163[7] are electrically connected to each other through the conductive layer 199.

In the signal output circuit 110a, an opening that penetrates the insulating layer 156, the insulating layer 157, and the insulating layer 158 is provided over each of the conductive layer 155[1], the conductive layer 155[2], the conductive layer 155[3], the conductive layer 155[4], the conductive layer 155[8], the conductive layer 155[9], the conductive layer 155[10], and the conductive layer 155[11].

Through the opening provided over the conductive layer 155[1], the conductive layer 160[3] and the conductive layer 155[1] are electrically connected to each other. Through the opening provided over the conductive layer 155[2], the conductive layer 160[1] and the conductive layer 155[2] are electrically connected to each other. Through the opening provided over the conductive layer 155[3], the conductive layer 160[4] and the conductive layer 155[3] are electrically connected to each other. Through the opening provided over the conductive layer 155[8], the conductive layer 181[1] and the conductive layer 155[8] are electrically connected to each other. Through the opening provided over the conductive layer 155[10], the conductive layer 181[3] and the conductive layer 155[10] are electrically connected to each other.

Two openings are provided over the conductive layer 155[9]. Through one of the two openings, the conductive layer 160[8] and the conductive layer 155[9] are electrically connected to each other. Through the other of the two openings, the conductive layer 181[2] and the conductive layer 155[9] are electrically connected to each other.

Two openings are provided over the conductive layer 155[11]. Through one of the two openings, the conductive layer 160[10] and the conductive layer 155[11] are electrically connected to each other. Through the other of the two openings, the conductive layer 181[4] and the conductive layer 155[11] are electrically connected to each other.

In the signal output circuit 110a, an opening that penetrates the insulating layer 156, the insulating layer 157, and the insulating layer 158 is provided over each of the conductive layer 155[4] and the conductive layer 155[7].

Through the opening provided over the conductive layer 155[4], the conductive layer 163[2] and the conductive layer 155[4] are electrically connected to each other (see FIG. 25B). Through the opening provided over the conductive layer 155[7], the conductive layer 163[8] and the conductive layer 155[7] are electrically connected to each other.

Note that the conductive layer 155[4] functions also as the conductive layer 155[5] and the conductive layer 155[6]. The conductive layer 160[1] functions also as the conductive layer 160[7]. The conductive layer 160[2] functions also as the conductive layer 160[6], the conductive layer 160[9], and the conductive layer 160[11]. The conductive layer 160[3] functions also as the conductive layer 160[5]. The conductive layer 163[1] functions also as the conductive layer 163[6]. The conductive layer 163[2] functions also as the conductive layer 163[9] and the conductive layer 163[11]. The conductive layer 163[8] functions also as the conductive layer 163[10].

A region where the conductive layer 155[4] and the conductive layer 160[6] overlap with each other with the insulating layer 156, the insulating layer 157, and the insulating layer 158 therebetween functions as the capacitor 20[1].

The electrical connection between the conductive layer 160[8] and the conductive layer 155[9] enables the capacitor C1 of the transistor 10[8] to be used as the capacitor 20[2]. With the use of the capacitor C1 of the transistor 10[8] as the capacitor 20[2], the capacitor 20[2] does not need to be additionally provided, so that a semiconductor device occupying a smaller area can be obtained (see FIG. 23). Thus, the VFET of one embodiment of the present invention is preferably used as the transistor 10[8].

The electrical connection between the conductive layer 160[10] and the conductive layer 155[11] enables the capacitor C1 of the transistor 10[10] to be used as the capacitor 20[3]. With the use of the capacitor C1 of the transistor 10[10] as the capacitor 20[3], the capacitor 20[3] does not need to be additionally provided, so that a semiconductor device occupying a smaller area can be obtained (see FIG. 23 and FIG. 25A). Thus, the VFET of one embodiment of the present invention is preferably used as the transistor 10[10].

FIG. 26 illustrates a circuit diagram of the signal output circuit 110a of the case where the capacitor C1 of the transistor 10[8] is used as the capacitor 20[2] and the capacitor C1 of the transistor 10[10] is used as the capacitor 20[3].

Transistors other than the VFET may be used as the transistor 10[10] and a transistor other than the transistor 10[10]. However, a large number of the transistors of one embodiment of the present invention are preferably used for the signal output circuit 110a in order to obtain a semiconductor device occupying a small area. Therefore, all the transistors included in the signal output circuit 110a are preferably the transistors of one embodiment of the present invention.

### Example of Operation of Signal Output Circuit

Next, an example of operation of the signal output circuit 110 will be described with reference to drawings. In this embodiment, an example of operation of the signal output circuit 110a illustrated in FIG. 14 among the signal output circuits 110 will be described.

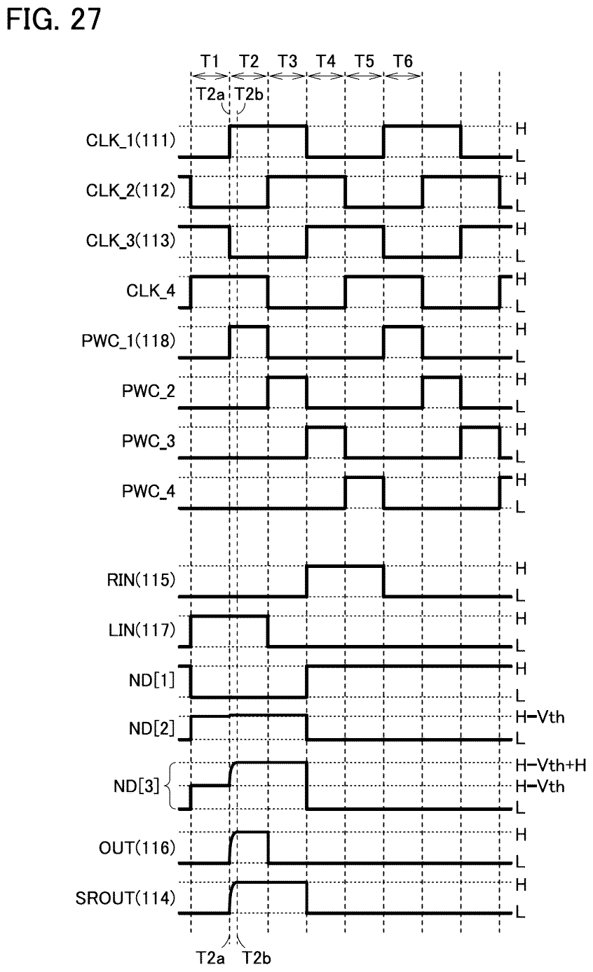

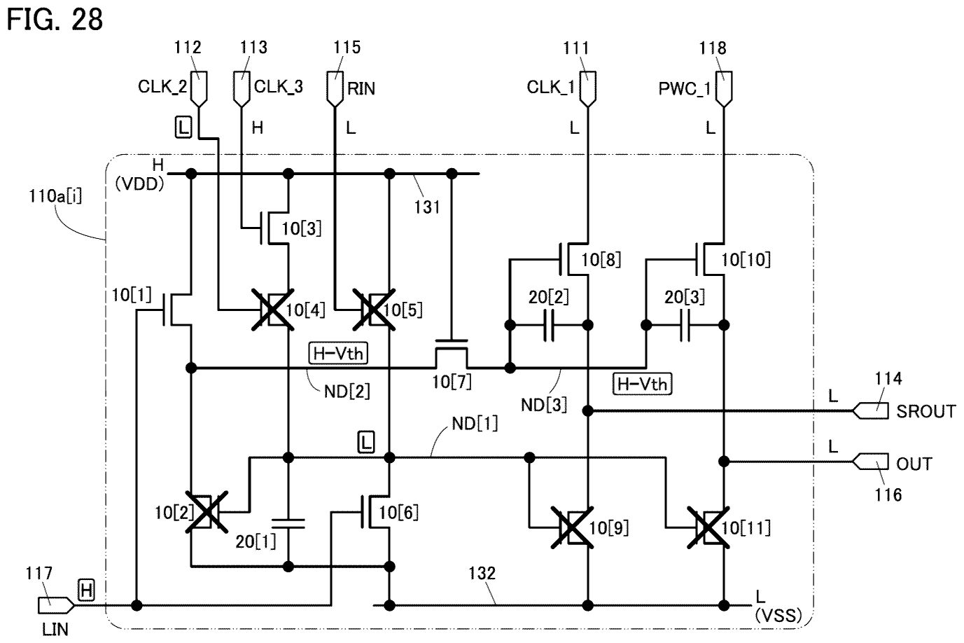

FIG. 27 is a timing chart for explaining an example of operation of a signal output circuit 110a[i]. FIG. 28 to FIG. 34 are circuit diagrams for explaining the example of operation of the signal output circuit 110a[i].

In the drawings and the like, for showing the potential of a wiring or the like, “H” representing a potential H or “L” representing a potential L is sometimes written near the wiring or the like. In addition, enclosed “H” or “L” is sometimes written near an electrode or the like whose potential changes. Moreover, in the case where a transistor is in an off state, a symbol “×” is sometimes written on the transistor.

The potential H (VDD) is supplied to the wiring 131, and the potential L (VSS) is supplied to the wiring 132. The signal CLK_1 is supplied to the terminal 111, the signal CLK_2 is supplied to the terminal 112, the signal CLK_3 is supplied to the terminal 113, and the signal PWC_1 is supplied to the terminal 118.

In a state shortly before a period T1, the signal CLK_1 is set to a potential L; the signal CLK_2, a potential H; the signal CLK_3, a potential H; the signal PWC_1, a potential L; and the signal LIN, a potential L. The transistor 10[2], the transistor 10[3], the transistor 10[4], the transistor 10[9], and the transistor 10[11] are in an on state. The transistor 10[1], the transistor 10[5], the transistor 10[6], the transistor 10[7], the transistor 10[8], and the transistor 10[10] are in an off state.

The signal CLK_4 and the signal PWC_2 to the signal PWC_4 are each set to a potential L. Note that the signal CLK_4 and the signal PWC_2 to the signal PWC_4 are not related to the operation of the signal output circuit 110a[i] explained here and are thus not used in the explanation of operation of the signal output circuit 110a[i].

In the period T1, the signal CLK_2 becomes a potential L and the signal LIN becomes a potential H (see FIG. 27 and FIG. 28). Then, the transistor 10[1] and the transistor 10[6] are turned on. Then, the potential of the node ND[1] becomes the potential L, and the transistor 10[2], the transistor 10[9], and the transistor 10[11] are turned off.

The potentials of the node ND[2] and the node ND[3] each become a potential lower than the potential H by Vth of the transistor 10[1] (the potential H−Vth). Here, the value of the potential H−Vth is higher than or equal to Vth of the transistor. Thus, the transistor 10[8] and the transistor 10[10] are turned on. The potential L is output as the signal OUT from the terminal 116, and the potential L is output as the signal SROUT from the terminal 114.

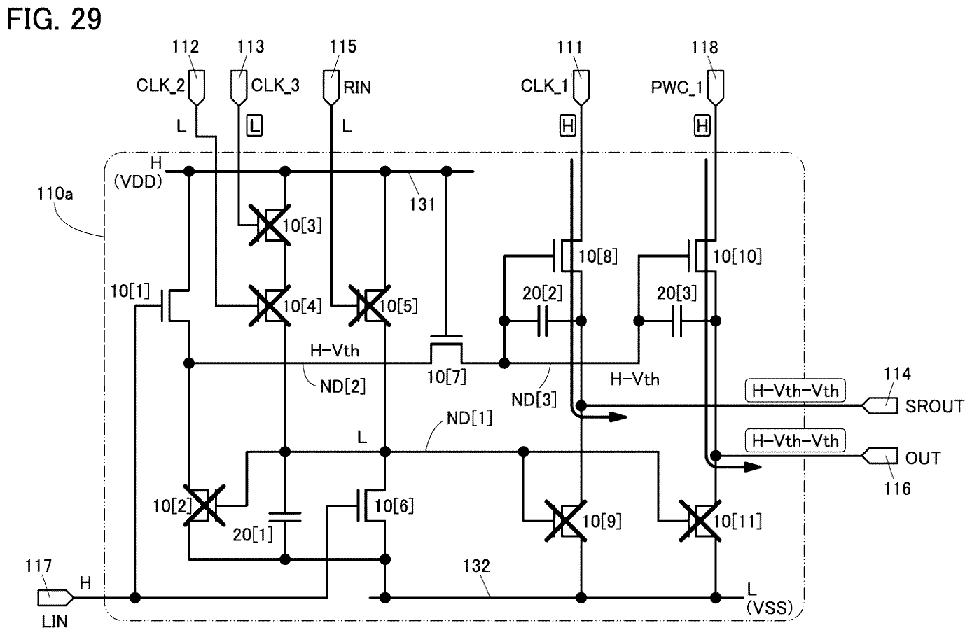

In a period T2, the signal CLK_1 becomes a potential H, the signal CLK_3 becomes a potential L, and the signal PWC_1 becomes a potential H (see FIG. 27). Then, the transistor 10[3] is turned off. At a time T2 a (see FIG. 29) at the start of the period T2, the potential of the node ND[3] is the potential H−Vth; thus, the potential of the terminal 114 becomes the potential H−Vth−Vth and the potential of the terminal 116 becomes the potential H−Vth−Vth.

Meanwhile, the terminal 114 and the node ND[3] are connected (capacitively coupled) to each other through the capacitor 20[2]. The terminal 116 and the node ND[3] are connected to each other through the capacitor 20[3]. The capacitor 20[2] and the capacitor 20[3] function as bootstrap capacitors. Thus, the potential of the node ND[3] increases with increasing potentials of the terminal 114 and the terminal 116.

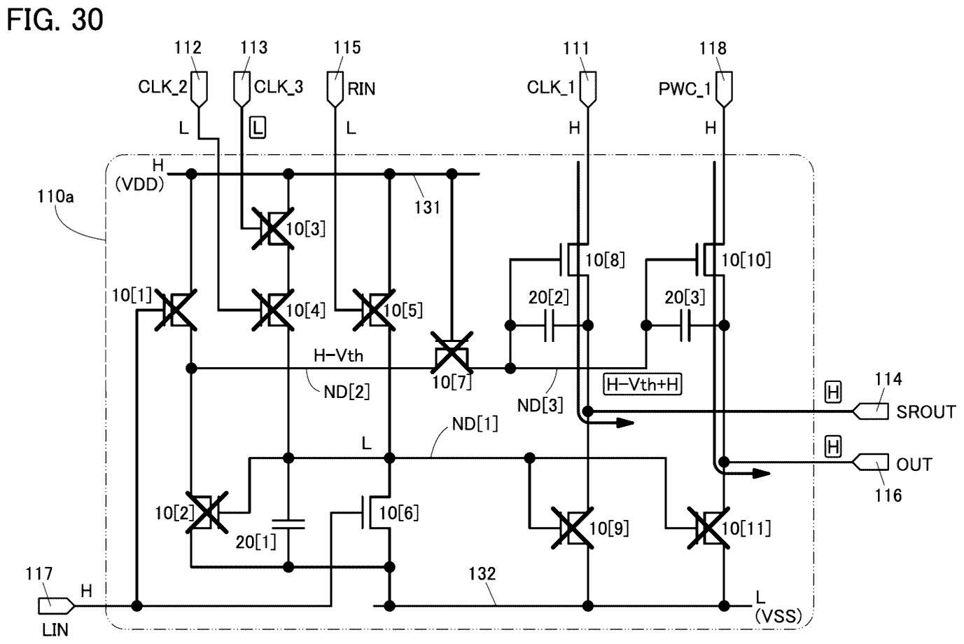

At this time, the potential of the node ND[2] also increases. At the moment when the potential of the node ND[2] exceeds the potential H−Vth, the transistor 10[1] and the transistor 10[7] are turned off, and the node ND[2] and the node ND[3] are brought into a floating state. The potential of the node ND[3] increases to the potential H−Vth+the potential H (2×the potential H−Vth) (at a time T2b, see FIG. 27 and FIG. 30). Since this potential is higher than the potential H+Vth, the potentials of the terminal 114 and the terminal 116 can each be set to the potential H.

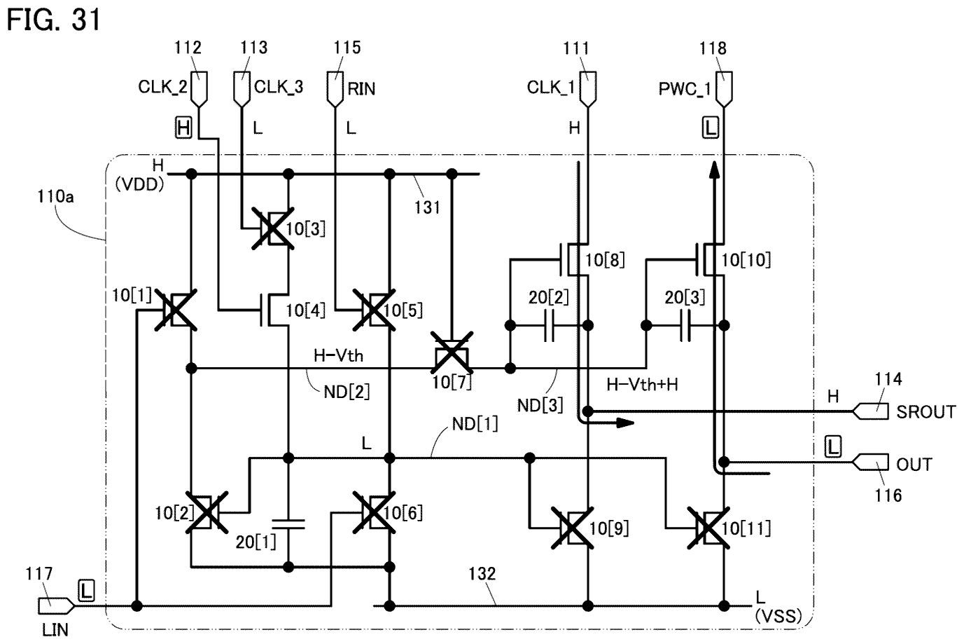

In a period T3, the signal CLK_2 becomes the potential H, the signal PWC_1 becomes the potential L, and the signal LIN becomes the potential L (see FIG. 27 and FIG. 31). Then, the transistor 10[4] is turned on. The potential of the terminal 116 becomes the potential L. The transistor 10[6] is turned off, and the node ND[1] and the node ND[2] are brought into a floating state.

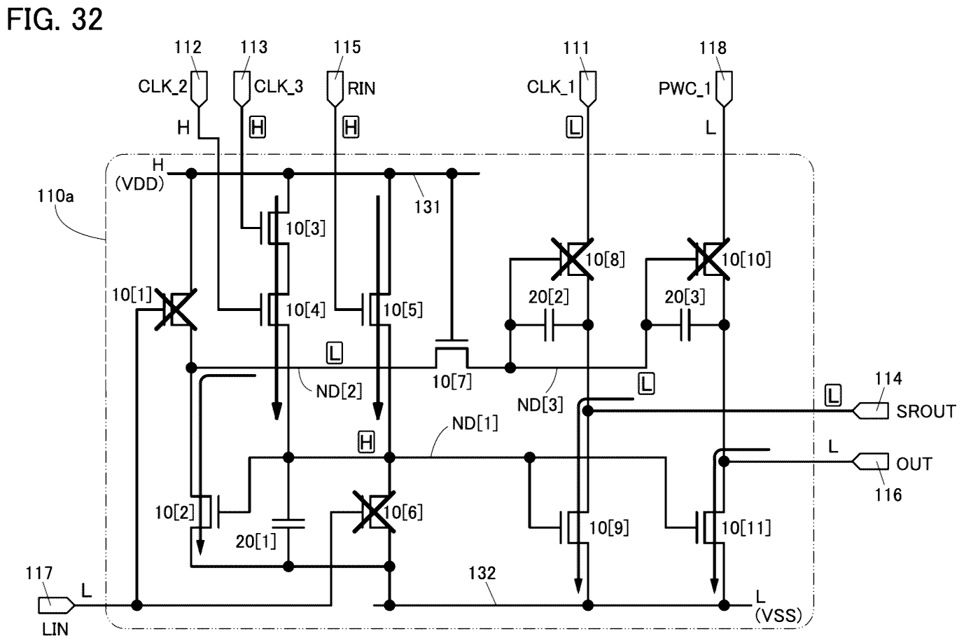

In a period T4, the signal CLK_1 becomes the potential L, the signal CLK_3 becomes the potential H, and the signal RIN becomes a potential H (see FIG. 27 and FIG. 32). Then, the transistor 10[3] and the transistor 10[5] are turned on, and the potential of the node ND[1] becomes the potential H. When the potential of the node ND[1] becomes the potential H, the transistor 10[2], the transistor 10[9], and the transistor 10[11] are turned on.

When the transistor 10[2] is turned on, the potential of the node ND[2] becomes the potential L. Then, the transistor 10[7] is turned on, and the potential of the node ND[3] also becomes the potential L. Thus, the transistor 10[8] and the transistor 10[10] are turned off. When the transistor 10[9] and the transistor 10[11] are turned on, the potential L is supplied to the terminal 114 and the potential of the terminal 116 (the potential L) is maintained.

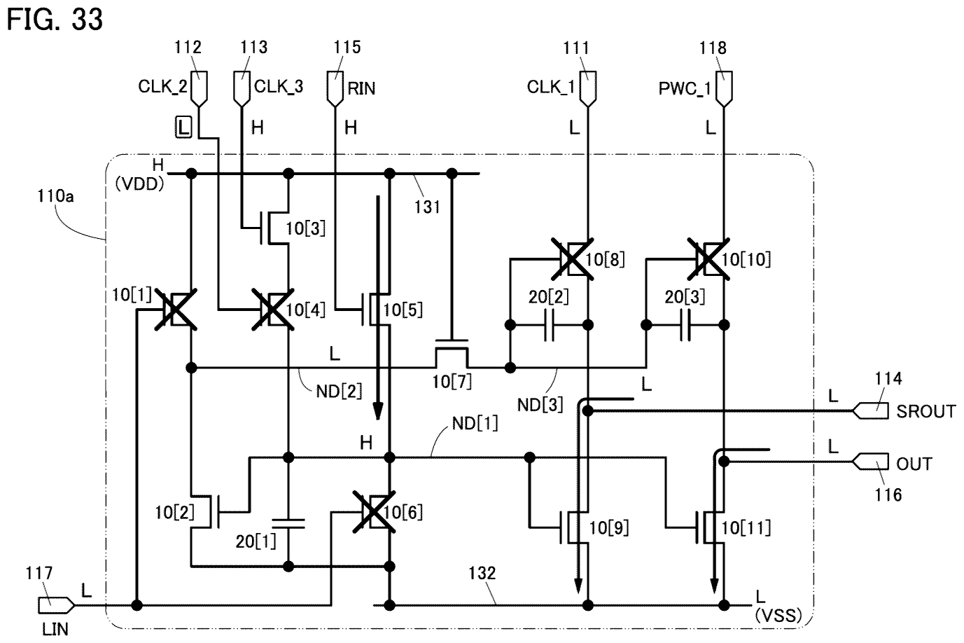

In a period T5, the signal CLK_2 becomes the potential L (see FIG. 27 and FIG. 33). Then, the transistor 10[4] is turned off.

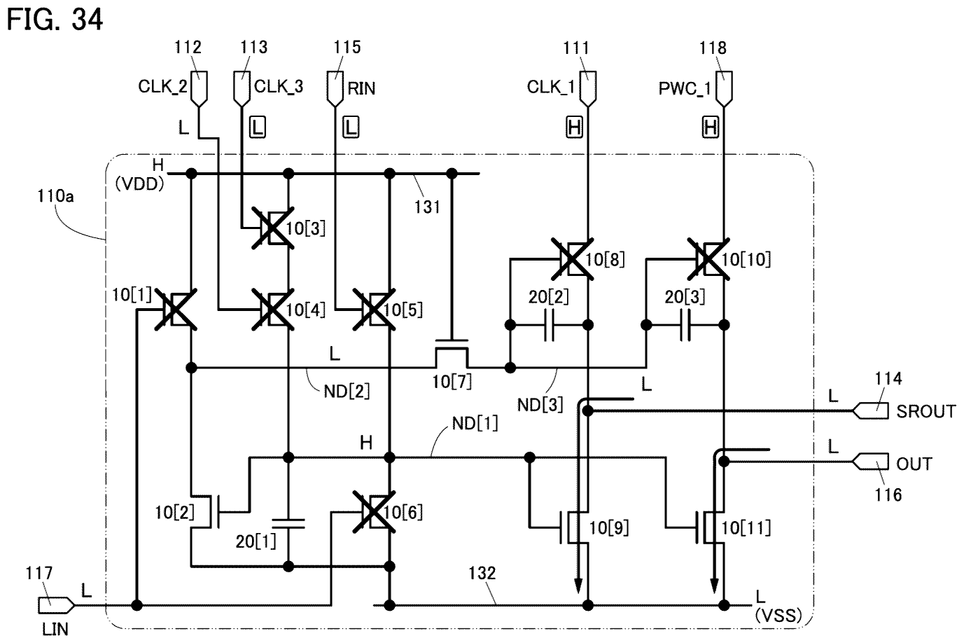

In a period T6, the signal CLK_3 and the signal RIN each become the potential L (see FIG. 27 and FIG. 34). Then, the transistor 10[3] and the transistor 10[5] are turned off. When the transistor 10[5] is turned off, the node ND[1] is brought into a floating state.

After that, the potential L is supplied to each of the terminal 114 and the terminal 116 until the potential H is supplied as the signal LIN to the terminal 117. That is, the potential L is output as each of the signal OUT and the signal SROUT until the potential H is supplied as the signal LIN to the terminal 117.

In this manner, the signal output circuit [i] can output pulse signals from the terminal 114 and the terminal 116 in synchronization with a combination of specific signals. Note that the pulse width (the time during which the potential H is output) of the signal SROUT, which is a pulse signal output from the terminal 114, changes with the signals CLK. The pulse width (the time during which the potential H is output) of the signal OUT, which is a pulse signal output from the terminal 116, changes with the signals PWC.

The signal output circuit [i] of one embodiment of the present invention includes the capacitor elements functioning as bootstrap capacitors and thus can surely output a power supply potential (the potential H) from each of the terminal 114 and the terminal 116. Thus, the signal output circuit [i] of one embodiment of the present invention has a low output impedance and can surely supply the potential H to a load such as a circuit connected to the terminal 114 or the terminal 116. Thus, the operation of the semiconductor device including the signal output circuit [i] of one embodiment of the present invention can be stabilized, and the reliability of the semiconductor device can be improved.

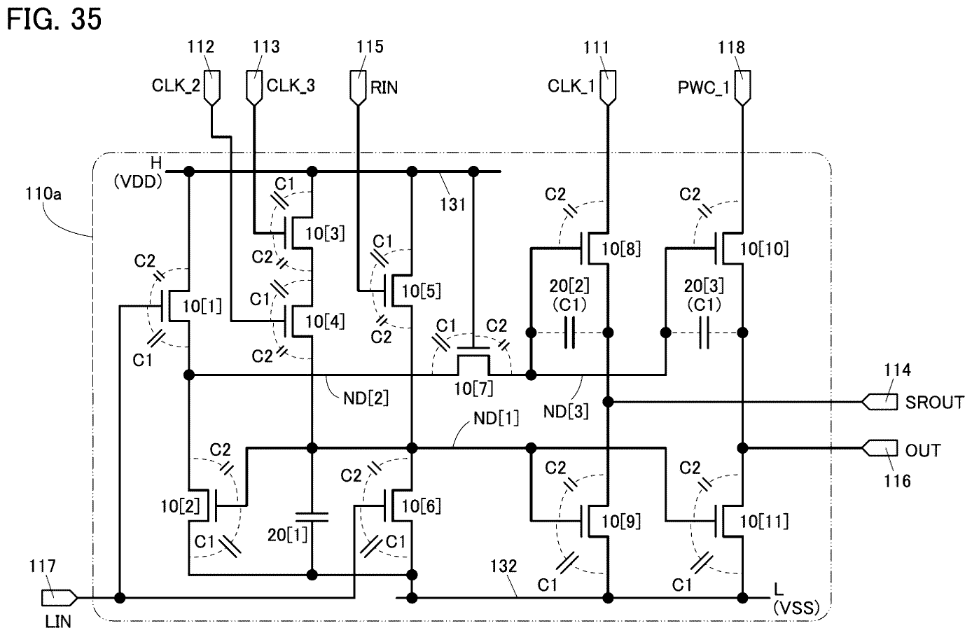

The capacitor C1 of the transistor 10[1] is preferably formed between the node ND[1] and the gate of the transistor 10[1]. The capacitor C2 of the transistor 10[1] is preferably formed between the wiring 131 to which the power supply potential is supplied and the gate of the transistor 10[1] (see FIG. 35).

The node ND[1] is in a floating state in a period other than a period in which each of the signal CLK_2 and the signal CLK_3 is the potential H. In order to inhibit a potential change of the node ND[1] in this period and operate the signal output circuit [i] of one embodiment of the present invention more stably, it is preferable that the capacitor C1 of each of the transistor 10[2], the transistor 10[6], the transistor 10[9], and the transistor 10[11] be formed between the gate and the wiring 132 to which a power supply potential is supplied. Specifically, it is preferable that the conductive layer 160[2] be electrically connected to the wiring 132 (see FIG. 23). The conductive layer 160[2] functions as the source electrode of each of the transistor 10[2], the transistor 10[6], the transistor 10[9], and the transistor 10[11].

When the capacitor C1 of each of the transistor 10[2], the transistor 10[9], and the transistor 10[11] is formed between the gate and the wiring 132, each capacitor Cl is connected in parallel with the capacitor 20[1]. Thus, the effect of inhibiting a potential change of the node ND[1] can be enhanced (see FIG. 35).

In the case where the capacitor C2 of the transistor 10[6] is formed between the node ND[1] and the gate of the transistor 10[6], the influence of a potential change of the signal input to the gate of the transistor 10[6] on the node ND[1] can be reduced as compared with the case where the capacitor Cl is formed between the node ND[1] and the gate of the transistor 10[6].

In order to inhibit a potential change of the node ND[1] and operate the signal output circuit [i] of one embodiment of the present invention more stably, the capacitor C2 of each of the transistor 10[4] and the transistor 10[5] is preferably formed between the gate and the node ND[1]. The capacitor Cl of the transistor 10[5] is preferably formed between the gate and the wiring 131 to which the power supply potential is supplied. Specifically, it is preferable that the conductive layer 160[3] be electrically connected to the wiring 131 (see FIG. 23). The conductive layer 160[3] functions as the drain electrode of the transistor 10[5].

The capacitor Cl of the transistor 10[4] is preferably formed between the drain and the gate of the transistor 10[4]. The capacitor C1 of the transistor 10[3] is preferably formed between the wiring 131 and the gate of the transistor 10[3]. Specifically, it is preferable that the conductive layer 160[3] be electrically connected to the wiring 131 (see FIG. 23). The conductive layer 160[3] functions as the drain electrode of the transistor 10[3]. The capacitor C2 of the transistor 10[3] is preferably formed between the source and the gate of the transistor 10[3].

In order to operate the signal output circuit [i] of one embodiment of the present invention more stably, the capacitance value of parasitic capacitance generated between the node ND[3] and the gate of the transistor 10[7] is preferably smaller than the capacitance value of each of the capacitor 20[2] and the capacitor 20[3]. Thus, in the transistor 10[7], the capacitor Cl is preferably generated between the gate and one of the source and the drain of the transistor 10[7], and the capacitor C2 is preferably generated between the gate and the other of the source and the drain of the transistor 10[7] (see FIG. 35).

### Example of Operation of Shift Register 100

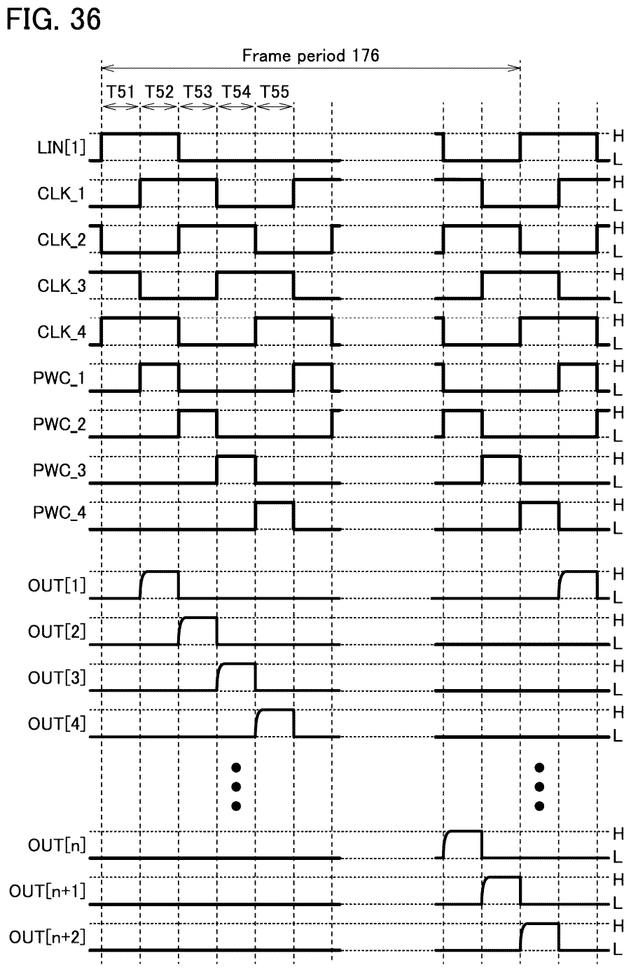

Next, an example of operation of the shift register 100 illustrated in FIG. 13A will be described with reference to FIG. 36. FIG. 36 is a timing chart for explaining the example of operation of the shift register 100. FIG. 36 shows potential changes of the signal CLK_1 to the signal CLK_4, which are clock signals; the signal PWC_1 to the signal PWC_4, which determine the pulse width of the signal OUT; the signal LIN[1], which is input to the signal output circuit 110[1]; the signal OUT[1] to the signal OUT[4], which are output from the signal output circuit 110[1] to the signal output circuit 110[4]; the signal OUT[n], which is output from the signal output circuit 110[n]; the signal OUT[n+1], which is output from the signal output circuit 110[n+1]; and the signal OUT[n+2], which is output from the signal output circuit 110[n+2].

First, in a period T51, the signal LIN[1] of a potential H is supplied to the signal output circuit 110[1]. In a period T52, a potential H is output as the signal OUT[1] in synchronization with the signal LIN[1], the signal CLK_1, the signal CLK_4, and the signal PWC_1.

Next, in a period T53, a potential L is output as the signal OUT[1]. A potential H is output as the signal OUT[2] in synchronization with the signal CLK_1, the signal CLK_2, and the signal PWC_2.

Next, in a period T54, a potential L is output as the signal OUT[2]. A potential H is output as the signal OUT[3] in synchronization with the signal CLK_3, the signal CLK_4, and the signal PWC_3.

Next, in a period T55, a potential L is output as the signal OUT[3]. A potential H is output as the signal OUT[4] in synchronization with the signal CLK_3, the signal CLK_4, and the signal PWC_4. In this manner, the potential H is output as the signal OUT sequentially from the first stage to the n+2-th stage.

After that, the potential H is supplied again as the signal LIN[1] to the signal output circuit 110[1], so that the shift register 100 can perform the above operation repeatedly. Note that a period from the input of the potential H as the signal LIN[1] to the signal output circuit 110[1] to the input of the potential H again as the signal LIN[1] is sometimes referred to as a frame period 176. The signal LIN input to the signal output circuit 110[1] is sometimes referred to as a “start pulse SP”.

Note that a transistor having a structure other than the VFET, such as a planar or staggered transistor, may be used as a transistor used in a semiconductor device such as the signal output circuit of one embodiment of the present invention. Alternatively, a combination of the VFET and a transistor having a structure other than the VFET may be used.

The structure described in this embodiment can be used in an appropriate combination with the structures described in the other embodiments.

### Embodiment 5

In this embodiment, electronic devices of embodiments of the present invention will be described.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer, digital signage, and a large game machine such as a pachinko machine.

In particular, the display apparatus of one embodiment of the present invention can have high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display apparatus having one or both of high definition and high resolution, the electronic device can have higher realistic sensation, sense of depth, and the like in personal use such as portable use or home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, a current, a voltage, electric power, radiation, flow rate, humidity, gradient, oscillation, odor, or infrared rays).

The electronic device in this embodiment can have a variety of functions. For example, the electronic device in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

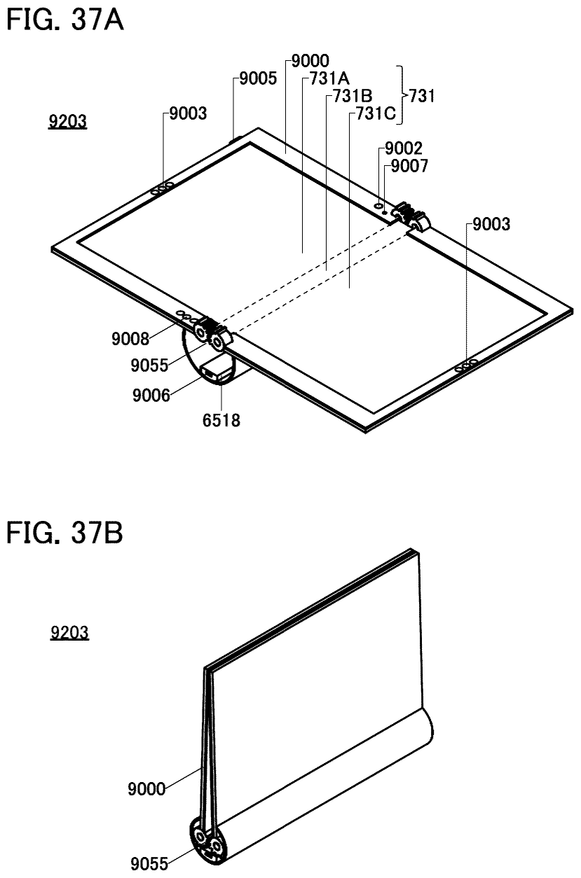

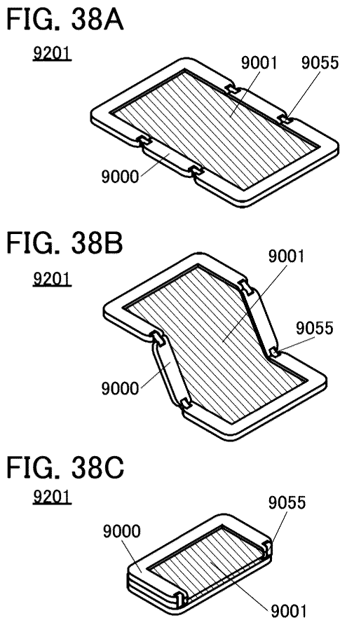

Electronic devices illustrated in FIG. 37A and FIG. 37B and FIG. 38A to FIG. 38C include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, a current, a voltage, electric power, radiation, flow rate, humidity, gradient, oscillation, odor, or infrared rays), a microphone 9008, and the like.

The electronic devices illustrated in FIG. 37A and FIG. 37B and FIG. 38A to FIG. 38C have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

FIG. 37A and FIG. 37B are perspective views illustrating an electronic device 9203. FIG. 37A is a perspective view of an opened state of the electronic device 9203 and FIG. 37B is a perspective view of a folded state thereof. The electronic device 9203 is capable of executing a variety of applications such as mobile phone calls, e-mailing, viewing and editing texts, music reproduction, Internet communication, and a computer game.

The electronic device 9203 of one embodiment of the present invention includes the display module of one embodiment of the present invention and the housing 9000 (see FIG. 37A). The housing 9000 includes a hinge 9055, and the housing 9000 can be bent with the display region 731B on the inner side (see FIG. 37B).

The electronic device 9203 includes a camera 9002, the speaker 9003, the operation key 9005, the connection terminal 9006, the sensor 9007, the microphone 9008, a battery 6518, and the like.

FIG. 38A to FIG. 38C are perspective views of a foldable portable information terminal 9201. FIG. 38A is a perspective view showing the portable information terminal 9201 that is opened. FIG. 38C is a perspective view showing the portable information terminal 9201 that is folded. FIG. 38B is a perspective view showing the portable information terminal 9201 that is shifted from one of the states in FIG. 38A and FIG. 38C to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are shown in one embodiment, the structure examples can be combined as appropriate.

### REFERENCE NUMERALS

AD41: adhesive layer, AD42: adhesive layer, ANO: wiring, CLK: signal, GAP: gap, GB: glass bead, GL: wiring, H: potential, IR: subpixel, L: potential, LIN: signal, LIQ: fluid layer, ND: node, OUT: signal, PWC: signal, RIN: signal, SL: wiring, SP: start pulse, SROUT: signal, SUP41: support, SUP42: support, T51: period, T52: period, T53: period, T54: period, T55: period, TEF: layer, VCOM: wiring, 10a: transistor, 10b: transistor, 10: transistor, 17: substrate, 18: substrate, 37b: display portion, 51A: pixel circuit, 51B: pixel circuit, 51C: pixel circuit, 51D: pixel circuit, 51E: pixel circuit, 51F: pixel circuit, 51G: pixel circuit, 51H: pixel circuit, 511: pixel circuit, 51J: pixel circuit, 51K: pixel circuit, 51L: pixel circuit, 51: pixel circuit, 52A: transistor, 52B: transistor, 52C: transistor, 52D: transistor, 52E: transistor, 52F: transistor, 53A: capacitor, 53: capacitor, 56: adhesive layer, 61: light-emitting element, 62: liquid crystal element, 63B: light-emitting device, 63G: light-emitting device, 63R: light-emitting device, 83B: light, 83G: light, 83R: light, 100: shift register, 101: wiring, 102: wiring, 103: wiring, 104: wiring, 105: wiring, 106: wiring, 107: wiring, 108: wiring, 110a: signal output circuit, 110: signal output circuit, 111: terminal, 112: terminal, 113: terminal, 114: terminal, 115: terminal, 116: terminal, 117: terminal, 118: terminal, 131: wiring, 132: wiring, 140: connection portion, 142: adhesive layer, 148: substrate, 152: substrate, 153: substrate, 154: insulating layer, 155a: conductive layer, 155b: conductive layer, 155: conductive layer, 156: insulating layer, 157: insulating layer, 158: insulating layer, 159[10]: opening, 159[3]: opening, 159[4]: opening, 159a: opening, 159b: opening, 159: opening, 160: conductive layer, 161: semiconductor layer, 162: insulating layer, 163: conductive layer, 164: insulating layer, 165: wiring, 166: conductive layer, 168: conductive layer, 171: conductive layer, 173: conductive layer, 176: frame period, 177: FPC, 178: IC, 179: FPC, 181: conductive layer, 187: insulating layer, 191: conductive layer, 192: conductive layer, 193: conductive layer, 194: conductive layer, 195: conductive layer, 196: conductive layer, 197: conductive layer, 198: conductive layer, 199: conductive layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 230a: pixel, 230b: pixel, 230c: pixel, 230d: pixel, 230e: pixel, 230: pixel, 231i: channel formation region, 231n: low-resistance region, 231: semiconductor layer, 233: peripheral driver circuit, 235: display portion, 236: wiring, 237: wiring, 240A: pixel, 240B: pixel, 240: pixel, 242: connection layer, 272: insulating layer, 273: protective layer, 512: shift register, 513: latch circuit, 514: buffer, 522: shift register, 523: buffer, 700: display apparatus, 731A: display region, 731B: display region, 731C: display region, 731: display region, 6518: battery, 9000: housing, 9001: display portion, 9002: camera, 9003: speaker, 9005: operation key, 9006: connection terminal, 9007: sensor, 9008: microphone, 9055: hinge, 9201: portable information terminal, 9203: electronic device

1. A display module comprising:
a first support;
a second support;
a first adhesive layer;
a gap;
a fluid layer; and
a display apparatus,
wherein the first support overlaps with the second support,
wherein the first support has flexibility,
wherein the second support has higher elasticity than the first support,
wherein the first adhesive layer bonds the first support and the second support to each other,
wherein the first adhesive layer forms the gap between the first support and the second support,
wherein the gap holds the fluid layer,
wherein the fluid layer has fluidity within a range of 0° C. to 80° C.,
wherein a difference in refractive index between the fluid layer and the first support is greater than 0 and less than or equal to 0.2,
wherein the display apparatus is sandwiched between the first support and the second support,
wherein the display apparatus is configured to perform display toward the first support,
wherein the display apparatus comprises a first display region, a second display region, and a third display region,
wherein the first display region is fixed between the first support and the first adhesive layer,
wherein the second display region is sandwiched between the first display region and the third display region,
wherein the second display region is capable of being bent,
wherein the second display region is inside the gap,
wherein the third display region is inside the gap, and
wherein the third display region slides inside the gap in accordance with bending of the second display region.

212. The display module according to claim 1, further comprising a second adhesive layer,
wherein the second adhesive layer bonds the first support and the first display region to each other, and
wherein a difference in refractive index between the second adhesive layer and the first support is greater than 0 and less than or equal to 0.2.

3. The display module according to claim 1, further comprising:
a third support; and
a third adhesive layer,
wherein the second support is sandwiched between the first support and the third support,
wherein the third adhesive layer bonds the second support and the third support to each other,
wherein the third support overlaps with the first display region and the second display region,
wherein the third support has flexibility, and
wherein the third support has lower elasticity than the second support.

4. The display module according to claim 3, further comprising:
a fourth support;
a fifth support;
a fourth adhesive layer; and
a fifth adhesive layer,
wherein the third support is sandwiched between the second support and the fourth support,
wherein the fourth adhesive layer bonds the third support and the fourth support to each other,
wherein the fourth support overlaps with the first display region,
wherein the fourth support has lower flexibility than the first support,
wherein the second support is sandwiched between the first support and the fifth support,
wherein the fifth adhesive layer bonds the second support and the fifth support to each other,
wherein the fifth support overlaps with the third display region, and
wherein the fifth support has lower flexibility than the first support.

5. The display module according to claim 1,
wherein the display apparatus comprises a terminal, and
wherein the terminal is adjacent to the first display region.

6. The display module according to claim 1, wherein the display apparatus has arithmetic surface roughness greater than or equal to 0.5 nm and less than or equal to 20 nm.

7. The display module according to claim 1,
wherein a surface of the display apparatus is provided with a layer, the surface facing the second support, and
wherein the layer comprises polytetrafluoroethylene.

8. The display module according to claim 1, further comprising a glass bead,
wherein the glass bead has a diameter greater than or equal to 1.0 μm and less than or equal to 50 μm, and
wherein a difference in refractive index between the glass bead and the first support is greater than 0 and less than or equal to 0.2.

9. An electronic device comprising the display module according to claim 1, and a housing,
wherein the housing comprises a hinge, and
wherein the housing is capable of being bent with the second display region on an inner side.
